(19) United States
(12) Patent Application Publication
(10) Pub. No.: US 2020/0292939 A1
(43) Pub. Date: Sep. 17, 2020

(54) PHOTOSENSITIVE RESIN COMPOSITION, PHOTOSENSITIVE DRY FILM, METHOD OF MANUFACTURING PHOTOSENSITIVE DRY FILM, METHOD OF MANUFACTURING PATTERNED RESIST FILM, METHOD OF MANUFACTURING SUBSTRATE WITH TEMPLATE AND METHOD OF MANUFACTURING PLATED ARTICLE

(71) Applicant: TOKYO OHKA KOGYO CO., LTD., Kawasaki-shi (JP)

(72) Inventors: Kazuaki EBISAWA, Kawasaki-shi (JP); Aya MOMOZAWA, Kawasaki-shi (JP); Shota KATAYAMA, Kawasaki-shi (JP); Kenta KIMURA, Kawasaki-shi (JP)

(21) Appl. No.: 16/813,062

(22) Filed: Mar. 9, 2020

(30) Foreign Application Priority Data
Mar. 13, 2019 (JP) 2019-046308

(51) Int. Cl. G03F 7/039; G03F 7/038; G03F 7/033; G03F 7/004; G03F 7/20; G03F 7/26; C08F 220/18

(52) U.S. Cl. CPC G03F 7/039; G03F 7/038; G03F 7/033; C08F 220/1808; G03F 7/20; G03F 7/26; G03F 7/0045

(57) ABSTRACT

A photosensitive resin composition; a photosensitive dry film which includes a photosensitive resin layer formed from the composition; a method of manufacturing the photosensitive dry film; a method of manufacturing a patterned resist film using the composition; a method of manufacturing a substrate with a template using the composition; and a method of manufacturing a plated article using the substrate with the template. In a photosensitive resin composition containing a resin which includes a (meth)acrylic polymer including a carboxy group, a specific amount of compound including a phenolic hydroxyl group and/or a mercapto group is contained together with a polyfunctional vinyl ether monomer.

### RELATED APPLICATIONS

This application claims priority to Japanese Patent Application No. 2019-046308, filed Mar. 13, 2019, the entire content of which is incorporated herein by reference.

### BACKGROUND OF THE INVENTION

### Field of the Invention

The present invention relates to a photosensitive resin composition, a photosensitive dry film which includes a photosensitive resin layer formed of the photosensitive resin composition, a method of manufacturing the photosensitive dry film, a method of manufacturing a patterned resist film using the photosensitive resin composition, a method of manufacturing a substrate with a template using the photosensitive resin composition and a method of manufacturing a plated article using the substrate with the template.

### Related Art

Photofabrication is presently the mainstream of a microfabrication technique. Photofabrication is a generic term for a technology used for manufacturing a wide variety of precision components such as a semiconductor package by applying a photoresist composition to the surface of an article to be processed so as to form a photoresist layer, patterning the photoresist layer by a photolithographic technique and then performing, for example, electroforming based mainly on chemical etching, electrolytic etching or electroplating using the patterned photoresist layer (photoresist pattern) as a mask.

In recent years, as electronic devices have been downsized, high density packaging technologies on semiconductor packages have progressed, and thus packaging density has been developed based on multi-pin thin film packaging in packages, reduction of package sizes, two-dimensional packaging technologies in flip chip systems and three-dimensional packaging technologies. In these types of high density packaging techniques, as connection terminals, for example, protruding electrodes (mounting terminals) such as bumps which protrude on a package, metal posts which connect rewiring extended from a peripheral terminal on a wafer and the mounting terminals and the like are highly accurately arranged on the surface of a substrate.

In the photofabrication described above, a photoresist composition is used, and as the photoresist composition, a chemically amplified photoresist composition which includes an acid generator is known (see Patent Documents 1 and 2 and the like). In the chemically amplified photoresist composition, acid is generated from the acid generator by application of radiation (exposure), the diffusion of the acid is facilitated by heating processing, an acid catalytic reaction occurs on a base resin and the like in the composition and the alkaline solubility thereof is changed.

The chemically amplified positive-type photoresist composition described above is used for, for example, the formation of plated articles such as a bump and a metal post produced in a plating step. Specifically, a photoresist pattern used as a template is formed in which the chemically amplified photoresist composition is used to form a photoresist layer having a desired film thickness on a support member such as a metal substrate, in which exposure is performed through a predetermined mask pattern, in which development is performed and in which parts where a bump and a metal post are formed are selectively removed (separated). Then, a conductor such as copper is embedded by plating in the removed parts (non-resist parts), thereafter the photoresist pattern therearound is removed and thus it is possible to form the bump and the metal post.
Patent Document 1: Japanese Unexamined Patent Application, Publication No. H09-176112
Patent Document 2: Japanese Unexamined Patent Application, Publication No. H11-52562

### SUMMARY OF THE INVENTION

In a photoresist composition which is used for the formation of a resist pattern serving as a template for forming plated articles such as a bump and a metal post, it is desired that in order to stably manufacture a plated article having a desired shape, a resist pattern can be formed whose shape is unlikely to be changed even when the resist pattern makes contact with a plating liquid under plating conditions while the occurrence of a crack is being reduced and that storage stability is provided in which thickening and gelling do not occur even in a certain degree of long-term storage at room temperature. In this way, it is possible to form accurate connection terminals such as a bump and a metal post.

However, it is likely that the conventionally known photoresist compositions disclosed in Patent Documents 1 and 2 and the like do not satisfy the above-described performance required in a photoresist composition which is used for the formation of a resist pattern serving as a template for forming plated articles such as a bump and a metal post.

The present invention is made in view of the foregoing problem, and an object thereof is to provide: a photosensitive resin composition in which a resist pattern can be formed whose shape is unlikely to be changed even when the resist pattern makes contact with a plating liquid under plating conditions while the occurrence of a crack is being reduced and which has storage stability where thickening and gelling do not occur even in a certain degree of long-term storage at room temperature; a photosensitive dry film which includes a photosensitive resin layer formed of the photosensitive resin composition; a method of manufacturing the photosensitive dry film; a method of manufacturing a patterned resist film using the photosensitive resin composition; a method of manufacturing a substrate with a template using the photosensitive resin composition; and a method of manufacturing a plated article using the substrate with the template.

As a result of thorough studies being conducted in order to achieve the above object, the present inventors have found that the above problem can be solved by including, in a photosensitive resin composition containing a resin (A) including a (meth)acrylic polymer including a carboxy group, a specific amount of compound including a phenolic hydroxyl group and/or a mercapto group together with a polyfunctional vinyl ether monomer (B), with the result that the inventors have completed the present invention. Specifically, the present invention provides followings.

A first aspect of the present invention is a photosensitive resin composition, including:

a resin (A) (wherein a compound (D) which will be described later is omitted);

a polyfunctional vinyl ether monomer (B); and

the compound (D) including a phenolic hydroxyl group and/or a mercapto group,

wherein the resin (A) includes a (meth)acrylic polymer including a carboxy group, and wherein a content of the compound (D) including the phenolic hydroxyl group and/or the mercapto group is 10 ppm by mass or more and 20% by mass or less with respect to a total mass of the resin (A).

A second aspect of the present invention is a photosensitive dry film including: a base material film; and a photosensitive resin layer being formed on a surface of the base material film, wherein the photosensitive resin layer is formed of the photosensitive resin composition according to the first aspect.

A third aspect of the present invention is a method of manufacturing a photosensitive dry film, which includes: applying, on a base material film, the photosensitive resin composition according to the first aspect so as to form a photosensitive resin layer.

A fourth aspect of the present invention is a method of manufacturing a patterned resist film, the method including:

a stacking step of stacking, on a substrate having a metal surface, a photosensitive resin layer formed of the photosensitive resin composition according to the first aspect;

an exposure step of applying an active ray or radiation to the photosensitive resin layer selectively in terms of position; and

a development step of developing the photosensitive resin layer after being exposed.

A fifth aspect of the present invention is a method of manufacturing a substrate with a template, the method including:

a stacking step of stacking, on a substrate having a metal surface, a photosensitive resin layer formed of the photosensitive resin composition according to the first aspect;

an exposure step of applying an active ray or radiation to the photosensitive resin layer; and

a development step of developing the photosensitive resin layer after being exposed so as to produce the template for formation of the plated article.

A sixth aspect of the present invention is a method of manufacturing a plated article, the method including: a step of plating the substrate with the template manufactured by the method according to the fifth aspect so as to form the plated article within the template.

According to the present invention, it is possible to provide: a photosensitive resin composition in which a resist pattern can be formed whose shape is unlikely to be changed even when the resist pattern makes contact with a plating liquid under plating conditions while the occurrence of a crack is being reduced and which has storage stability where thickening and gelling do not occur even in a certain degree of long-term storage at room temperature; a photosensitive dry film which includes a photosensitive resin layer formed of the photosensitive resin composition; a method of manufacturing the photosensitive dry film; a method of manufacturing a patterned resist film using the photosensitive resin composition; a method of manufacturing a substrate with a template using the photosensitive resin composition; and a method of manufacturing a plated article using the substrate with the template.

### DETAILED DESCRIPTION OF THE INVENTION

### <<Photosensitive Resin Composition>>

A photosensitive resin composition includes: a resin (A); a polyfunctional vinyl ether monomer (B); and a compound (D) including a phenolic hydroxyl group and/or a mercapto group. The resin (A) includes a (meth)acrylic polymer including a carboxy group. Here, a resin which applies to the compound (D) is omitted from the resin (A). A content of the compound (D) in the photosensitive resin composition is 10 ppm by mass or more and 20% by mass or less with respect to the total mass of the resin (A). In the photosensitive resin composition having the configuration described above, a resist pattern can be formed whose shape is unlikely to be changed even when the resist pattern makes contact with a plating liquid under plating conditions while the occurrence of a crack is being reduced and, storage stability is provided in which thickening, gelling and the like do not occur even in a certain degree of long-term storage at room temperature.

Although the reason thereof is not clear, it can be considered that a vinyloxy group included in the polyfunctional vinyl ether monomer (B) and the carboxy group included in the resin (A) react with each other so as to cross-link the molecular chains of the resin (A), and that thus it is possible to reduce the occurrence of a crack when the photosensitive resin composition is used to form a resist pattern and it is also possible to form the resist pattern whose shape is unlikely to be changed even when the resist pattern makes contact with a plating liquid under plating conditions. When a coating film formed of the photosensitive resin composition is heated, the compound (D) including the phenolic hydroxyl group and/or the mercapto group facilitates the cross-linking of the molecular chains of the resin (A) caused by the reaction of the vinyloxy group included in the polyfunctional vinyl ether monomer (B) and the carboxy group included in the resin (A). However, since when the photosensitive resin composition is not heated, the compound (D) including the phenolic hydroxyl group and/or the mercapto group does not facilitate the cross-linking reaction described above, and thus the photosensitive resin composition has storage stability in which thickening, gelling and the like do not occur even in a certain degree of long-term storage at room temperature.

The photosensitive resin composition may be either a positive type or a negative type.

Preferred examples of a case where the photosensitive resin composition is a negative type include a photosensitive resin composition which includes, in addition to the resin (A), the polyfunctional vinyl ether monomer (B) and the compound (D) described above, a photopolymerizable monomer such as a monofunctional or a polyfunctional (meth) acrylate monomer and a photopolymerization initiator.

When the negative-type photosensitive resin composition described above is used to form the resist pattern, the coating film formed of the photosensitive resin composition is baked, and thus the carboxy group included in the resin (A) and the vinyloxy group included in the polyfunctional vinyl ether monomer (B) react with each other so as to cross-link the molecular chains of the resin (A). Here, when the amount of carboxy group included in the resin (A) is set excessively larger than the amount of vinyloxy group included in the polyfunctional vinyl ether monomer (B), the cross-linked resin (A) includes the carboxy group. The cross-linked resin (A) includes the carboxy group so as to indicate alkali solubility. Then, when the coating film including the cross-linked resin (A) is exposed selectively in terms of position, the photopolymerizable monomer is polymerized by the action of the photopolymerization initiator, and thus the exposed part is insolubilized in an alkaline developing solution. On the other hand, since in the unexposed part, the photopolymerizable monomer is not polymerized and the cross-linked resin (A) indicates alkali solubility, the unexposed part is soluble in the alkaline developing solution. Hence, when the negative-type photosensitive resin composition which includes, in addition to the resin (A), the polyfunctional vinyl ether monomer (B) and the compound (D) described above, the photopolymerizable monomer such as a monofunctional or a polyfunctional (meth) acrylate monomer and the photopolymerization initiator is used to form the resist pattern, the coating film formed of the photosensitive resin composition is baked, thereafter the exposure selective in terms of position and the development using the alkaline developing solution are performed and thus the unexposed part soluble in the alkaline developing solution is removed, with the result that it is possible to form the resist pattern including the cross-linked resin (A) whose shape is unlikely to be changed even when the resist pattern makes contact with the plating liquid under plating conditions while the occurrence of a crack is being reduced.

Preferred examples of a case where the photosensitive resin composition is a positive type include a photosensitive resin composition which includes, in addition to the resin (A), the polyfunctional vinyl ether monomer (B) and the compound (D) described above, a photosensitizing agent which enhances, by exposure, solubility in the alkaline developing solution of the photosensitive resin composition.

When the coating film formed of the positive-type photosensitive resin composition described above is heated, the carboxy group included in the resin (A) and the vinyloxy group included in the polyfunctional vinyl ether monomer (B) react with each other so as to cross-link the molecular chains of the resin (A), and thus the solubility in the alkaline developing solution of the photosensitive resin composition is lowered. However, when the coating film after being heated is exposed selectively in terms of position, the exposed part is soluble in the alkaline developing solution by the action of the photosensitizing agent.

Hence, when the positive-type photosensitive resin composition which includes, in addition to the resin (A), the polyfunctional vinyl ether monomer (B) and the compound (D) described above, the photosensitizing agent for enhancing, by exposure, the solubility in the alkaline developing solution of the photosensitive resin composition is used to form the resist pattern, the coating film formed of the photosensitive resin composition is baked, thereafter the exposure selective in terms of position and the development using the alkaline developing solution are performed and thus the exposed part soluble in the alkaline developing solution is removed, with the result that it is possible to form the resist pattern including the cross-linked resin (A) whose shape is unlikely to be changed even when the resist pattern makes contact with the plating liquid under plating conditions while the occurrence of a crack is being reduced.

As the photosensitizing agent described above, a quinonediazide group-containing compound is preferable. Examples of the quinonediazide group-containing compound include fully esterified and partially esterified compounds of a phenol compound and a naphthoquinonediazide sulfonic acid compound. Examples of the phenol compound include: polyhydroxybenzophenone compounds such as 2,3,4-trihydroxybenzophenone and 2,3,4,4′-tetrahydroxybenzophenone; trisphenol type compounds such as tris (4-hydroxyphenyl) methane, bis (4-hydroxy-3-methylphenyl)-2-hydroxyphenylmethane, bis (4-hydroxy-2,3,5-trimethylphenyl)-2-hydroxyphenylmethane, bis (4-hydroxy-3,5-dimethylphenyl)-4-hydroxyphenylmethane, bis (4-hydroxy-3,5-dimethylphenyl)-3-hydroxyphenylmethane, bis (4-hydroxy-3,5-dimethylphenyl)-2-hydroxyphenylmethane, bis (4-hydroxy-2,5-dimethylphenyl)-4-hydroxyphenylmethane, bis (4-hydroxy-2,5-dimethylphenyl)-3-hydroxyphenylmethane, bis (4-hydroxy-2,5-dimethylphenyl)-2-hydroxyphenylmethane, bis (4-hydroxy-3,5-dimethylphenyl)-3,4-dihydroxyphenylmethane, bis (4-hydroxy-2,5-dimethylphenyl)-3,4-dihydroxyphenylmethane, bis (4-hydroxy-2,5-dimethylphenyl)-2,4-dihydroxyphenylmethane, bis (4-hydroxyphenyl)-3-methoxy-4-hydroxyphenylmethane, bis (5-cyclohexyl-4-hydroxy-2-methylphenyl)-4-hydroxyphenylmethane, bis (5-cyclohexyl-4-hydroxy-2-methylphenyl)-3-hydroxyphenylmethane, bis (5-cyclohexyl-4-hydroxy-2-methylphenyl)-2-hydroxyphenyl methane and bis (5-cyclohexyl-4-hydroxy-2-methylphenyl)-3,4-dihydroxyphenyl methane; linear trinuclear phenol compounds such as 2,4-bis (3,5-dimethyl-4-hydroxybenzyl)-5-hydroxyphenol and 2,6-bis (2,5-dimethyl-4-hydroxybenzyl)-4-methylphenol; linear tetranuclear phenol compounds such as 1,1-bis [3-(2-hydroxy-5-methylbenzyl)-4-hydroxy-5-cyclohexylphenyl] isopropane, bis [2,5-dimethyl-3-(4-hydroxy-5-methylbenzyl)-4-hydroxyphenyl] methane, bis [2,5-dimethyl-3-(4-hydroxybenzyl)-4-hydroxyphenyl] methane, bis [3-(3,5-dimethyl-4-hydroxybenzyl)-4-hydroxy-5-methylphenyl]methane, bis [3-(3,5-dimethyl-4-hydroxybenzyl)-4-hydroxy-5-ethylphenyl] methane, bis [3-(3,5-diethyl-4-hydroxybenzyl)-4-hydroxy-5-methylphenyl] methane, bis [3-(3,5-diethyl-4-hydroxybenzyl)-4-hydroxy-5-ethylphenyl] methane, bis [2-hydroxy-3-(3,5-dimethyl-4-hydroxybenzyl)-5-methylphenyl]methane, bis [2-hydroxy-3-(2-hydroxy-5-methylbenzyl)-5-methylphenyl] methane, bis [4-hydroxy-3-(2-hydroxy-5-methylbenzyl)-5-methylphenyl] methane and bis [2,5-dimethyl-3-(2-hydroxy-5-methylbenzyl)-4-hydroxyphenyl] methane; linear polyphenol compounds of linear pentanuclear phenol compounds such as 2,4-bis [2-hydroxy-3-(4-hydroxybenzyl)-5-methylbenzyl]-6-cyclohexylphenol, 2,4-bis [4-hydroxy-3-(4-hydroxybenzyl)-5-methylbenzyl]-6-cyclohexylphenol and 2,6-bis [2,5-dimethyl-3-(2-hydroxy-5-methylbenzyl)-4-hydroxybenzyl]-4-methylphenol; bisphenol type compounds such as bis (2,3,4-trihydroxyphenyl) methane, bis (2,4-dihydroxyphenyl) methane, 2,3,4-trihydroxyphenyl-4′-hydroxyphenylmethane, 2-(2,3,4-trihydroxyphenyl)-2-(2′,3′,4′-trihydroxyphenyl) propane, 2-(2,4-dihydroxyphenyl)-2-(2′,4′-dihydroxyphenyl) propane, 2-(4-hydroxyphenyl)-2-(4′-hydroxyphenyl) propane, 2-(3-fluoro-4-hydroxyphenyl)-2-(3′-fluoro-4′-hydroxyphenyl) propane, 2-(2,4-dihydroxyphenyl)-2-(4′-hydroxyphenyl) propane, 2-(2,3,4-trihydroxyphenyl)-2-(4′-hydroxyphenyl) propane and 2-(2,3,4-hydroxyphenyl)-2-(4′-hydroxy-3′,5′-dimethylphenyl) propane; polynuclear branched compounds such as 1-[1-(4-hydroxyphenyl) isopropyl]-4-[1,1-bis (4-hydroxyphenyl) ethyl] benzene and 1-[1-(3-methyl-4-hydroxyphenyl) isopropyl]-4-[1,1-bis (3-methyl-4-hydroxyphenyl) ethyl] benzene; condensed phenol compounds such as 1,1-bis (4-hydroxyphenyl) cyclohexane; and the like. One or two or more types thereof can be combined so as to be used.

Examples of the naphthoquinonediazide sulfonic acid compound include naphthoquinone-1,2-diazide-5-sulfonic acid chloride, naphthoquinone-1,2-diazide-4-sulfonic acid chloride and the like.

As other quinonediazide group-containing compounds, for example, nuclear substituted derivatives of orthobenzoquinonediazide, orthonaphthoquinonediazide, orthoanthraquinonediazide, orthonaphthoquinonediazide sulfonic acid esters and the like, furthermore, reaction products of orthoquinonediazide sulfonyl chloride and compounds having a hydroxyl group or an amino group such as phenol, p-methoxyphenol, dimethylphenol, hydroquinone, bisphenol A, naphthol, pyrocatechol, pyrogallol, pyrogallol monomethyl ether, pyrogallol-1,3-dimethyl ether, a gallic acid, gallic acids esterified and etherified except some hydroxyl groups, aniline, p-aminodiphenylamine and the like can also be used. These may be used singly or two or more types may be combined so as to be used.

These quinonediazide group-containing compounds can be manufactured by condensing and fully or partially esterifying, for example, the phenol compounds described above and naphthoquinone-1,2-diazide-5-sulfonic acid chloride or naphthoquinone-1,2-diazide-4-sulfonic acid chloride in an appropriate solvent such as dioxane under the presence of an alkali such as triethanolamine, alkali carbonate or alkali hydrogen carbonate.

The amount of photosensitizing agent used is preferably 50% by mass or less, is more preferably 40% by mass or less and is particularly preferably 30% by mass or less with respect to the total of the mass of the resin (A) and the mass of the polyfunctional vinyl ether monomer (B). For example, the lower limit of the amount of photosensitizing agent used is preferably 10% by mass or more, is more preferably 15% by mass or more and is further preferably 20% by mass or less with respect to the total of the mass of the resin (A) and the mass of the polyfunctional vinyl ether monomer (B).

As another preferred example of the positive-type photosensitive resin composition, a photosensitive resin composition is mentioned which includes, in addition to the resin (A), the polyfunctional vinyl ether monomer (B) and the compound (D) described above, an acid generator (C) which generates an acid by application of an active ray or radiation and in which the (meth)acrylic polymer included as the resin (A) is a resin whose solubility in alkali is increased by action of an acid. The positive-type photosensitive resin composition including the acid generator (C) described above is particularly preferable as the photosensitive resin composition in that the sensitivity and the resolution thereof are satisfactory.

With respect to the positive-type photosensitive resin composition which is a particularly preferable photosensitive resin composition, which includes the resin (A), the polyfunctional vinyl ether monomer (B) and the compound (D) described above and the acid generator (C) that generates an acid by application of an active ray or radiation and in which the (meth)acrylic polymer included as the resin (A) is a resin whose solubility in alkali is increased by action of an acid, essential or optional components and a method of manufacturing the positive-type photosensitive resin composition will be described below. The configuration of the resin (A) which will be described below is common to any photosensitive resin compositions according to the present invention except that the (meth)acrylic polymer essentially includes a resin whose solubility in alkali is increased by action of an acid. The configurations of the polyfunctional vinyl ether monomer (B) and the compound (D) which will be described below are common to any photosensitive resin compositions according to the present invention.

### <Resin (A)>

The resin (A) includes the (meth)acrylic polymer which includes a carboxy group. The (meth)acrylic polymer included as the resin (A) is a resin whose solubility in alkali is increased by action of an acid. The resin (A) does not include a resin which applies to the compound (D) which will be described later. The content of the (meth)acrylic polymer including the carboxy group in the resin (A) is not particularly limited as long as the object of the present invention is not disturbed. The content of the (meth)acrylic polymer including the carboxy group in the resin (A) is preferably 70% by mass or more, is more preferably 80% by mass or more, is further preferably 90% by mass or more and is particularly preferably 100% by mass with respect to the mass of the resin (A).

When the resin (A) includes a resin other than the (meth)acrylic polymer including the carboxy group, the resin does not apply to the compound (D) which will be described later, and the resin is not particularly limited as long as the resin is a resin which is conventionally mixed with various photosensitive resin compositions. Examples of the preferred resin other than the (meth)acrylic polymer including the carboxy group include a (meth)acrylic polymer which does not include the carboxy group.

Hereinafter, the (meth)acrylic polymer including the carboxy group will also be simply referred to as an “acrylic resin”.

The acrylic resin is not particularly limited as long as the solubility of the acrylic resin in alkali is increased by action of an acid and the acrylic resin is conventionally mixed with various photosensitive resin compositions. The acrylic resin preferably includes, for example, a structural unit (a-1) derived from (corresponding to) an acrylic ester which includes a —SO₂-containing cyclic group or a lactone-containing cyclic group. In such a case, when a resist pattern is formed, it is easy to reduce the occurrence of deterioration of a cross-sectional shape of the resist pattern such as footing.

### (—SO₂— Containing Cyclic Group)

Here, the “—SO₂— containing cyclic group” refers to a cyclic group which contains a ring including —SO₂— in its ring skeleton, and is specifically a cyclic group in which a sulfur atom (s) in —SO₂— forms part of the ring skeleton in the cyclic group. When the ring including —SO₂— in its ring skeleton is counted as the first ring, and only this ring is provided, the “—SO₂— containing cyclic group” is referred to as a monocyclic group whereas when another ring structure is further provided, it is referred to as a polycyclic group regardless of its structure. The —SO₂— containing cyclic group may be either monocyclic or polycyclic.

In particular, the —SO₂— containing cyclic group is preferably a cyclic group that includes —O—SO₂— in its ring skeleton, that is, a cyclic group that contains a sultone ring in which —O—S— in —O—SO₂— forms part of the ring skeleton.

The number of carbon atoms of the —SO₂— containing cyclic group is preferably 3 or more and 30 or less, is more preferably 4 or more and 20 or less, is further preferably 4 or more and 15 or less and is particularly preferably 4 or more and 12 or less. It is assumed that the number of carbon atoms described above is the number of carbon atoms which form the ring skeleton and does not include the number of carbon atoms in a substituent.

The —SO₂— containing cyclic group may be either a —SO₂— containing aliphatic cyclic group or a —SO₂— containing aromatic cyclic group. The —SO₂— containing cyclic group is preferably a —SO₂— containing aliphatic cyclic group.

Examples of the —SO₂— containing aliphatic cyclic group include a group that is obtained by removing at least one hydrogen atom from an aliphatic hydrocarbon ring in which part of carbon atoms forming its ring skeleton is substituted with —SO₂— or —O—SO₂—. More specifically, examples thereof include a group that is obtained by removing at least one hydrogen atom from an aliphatic hydrocarbon ring in which —CH₂— forming its ring skeleton is substituted with —SO₂—, a group that is obtained by removing at least one hydrogen atom from an aliphatic hydrocarbon ring in which —CH₂—CH₂— forming its ring is substituted with —O—SO₂— and the like.

The number of carbon atoms of the aliphatic hydrocarbon ring is preferably 3 or more and 20 or less and is more preferably 3 or more and 12 or less. The aliphatic hydrocarbon ring may be either polycyclic or monocyclic. As the monocyclic aliphatic hydrocarbon group, a group is preferable that is obtained by removing two hydrogen atoms from a monocycloalkane in which the number of carbon atoms is 3 or more and 6 or less. Examples of the monocycloalkane include cyclopentane, cyclohexane and the like. As the polycyclic aliphatic hydrocarbon ring, a group is preferable that is obtained by removing two hydrogen atoms from a polycycloalkane in which the number of carbon atoms is 7 or more and 12 or less, and specific examples of the polycycloalkane include adamantane, norbornane, isobornane, tricyclodecane, tetracyclododecane and the like.

The —SO₂— containing cyclic group may include a substituent. Examples of the substituent include an alkyl group, an alkoxy group, a halogen atom, a halogenated alkyl group, a hydroxyl group, an oxygen atom (═O), —COOR″, —OC(═O)R″, a hydroxyalkyl group, a cyano group and the like.

As the alkyl group serving as the substituent, an alkyl group is preferable in which the number of carbon atoms is 1 or more and 6 or less. The alkyl group described above is preferably linear or branched. Specific examples thereof include a methyl group, an ethyl group, an n-propyl group, an isopropyl group, an n-butyl group, an isobutyl group, a tert-butyl group, an n-pentyl group, an isopentyl group, a neopentyl group, an n-hexyl group and the like. Among them, a methyl group and an ethyl group are preferable, and a methyl group is particularly preferable.

As the alkoxy group serving as the substituent described above, an alkoxy group is preferable in which the number of carbon atoms is 1 or more and 6 or less. The alkoxy group described above is preferably linear or branched. Specific examples thereof include a group in which the alkyl group serving as the substituent described above is bonded to an oxygen atom (—O—).

Examples of the halogen atom serving as the substituent described above include a fluorine atom, a chlorine atom, a bromine atom, an iodine atom and the like, and a fluorine atom is preferable.

Examples of the halogenated alkyl group serving as the substituent include a group in which part or all of hydrogen atoms in the alkyl group described above are substituted with the halogen atom described above.

Examples of the halogenated alkyl group serving as the substituent described above include a group in which part or all of hydrogen atoms in the alkyl group serving as the substituent described above are substituted with the halogen atom described above. As the halogenated alkyl group described above, a fluorinated alkyl group is preferable, and a perfluoroalkyl group is particularly preferable.

R″ in each of —COOR″ and —OC(═O)R″ described above is a linear, branched or cyclic alkyl group in which the number of hydrogen atoms or carbon atoms is 1 or more and 15 or less.

When R″ is a linear or branched alkyl group, the number of carbon atoms in the chained alkyl group is preferably 1 or more and 10 or less, is more preferably 1 or more and 5 or less and is particularly preferably 1 or 2.

When R″ is a cyclic alkyl group, the number of carbon atoms in the cyclic alkyl group is preferably 3 or more and 15 or less, is more preferably 4 or more and 12 or less and is particularly preferably 5 or more and 10 or less. Specific examples thereof include a group that is obtained by removing one or more hydrogen atoms from a monocycloalkane which may or may not be substituted with a fluorine atom or a fluorinated alkyl group or a polycycloalkane such as bicycloalkane, tricycloalkane or tetracycloalkane and the like. More specific examples thereof include a group that is obtained by removing one or more hydrogen atoms from a monocycloalkane such as cyclopentane or cyclohexane or a polycycloalkane such as adamantane, norbornane, isobornane, tricyclodecane or tetracyclododecane.

As the hydroxyalkyl group serving as the substituent described above, a hydroxyalkyl group is preferable in which the number of carbon atoms is 1 or more and 6 or less. Specific examples thereof include a group in which at least one of hydrogen atoms in the alkyl group serving as the substituent described above is substituted with a hydroxyl group.

More specific examples of the —SO₂— containing cyclic group include groups represented by formulae (1-1) to (1-4) below.

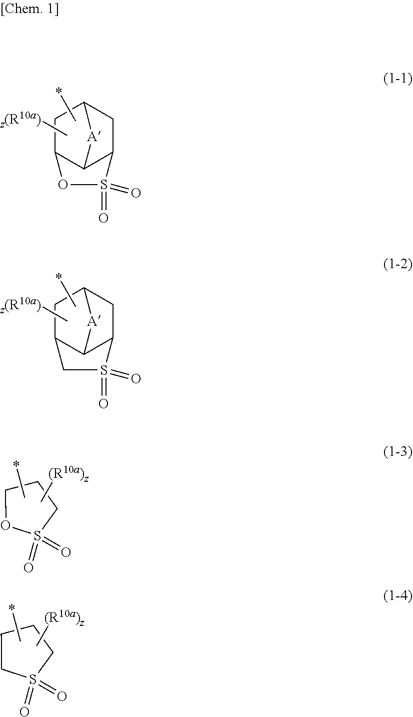

(where A′ represents an alkylene group which may include an oxygen atom or a sulfur atom and in which the number of carbon atoms is 1 or more and 5 or less, an oxygen atom or a sulfur atom, z represents an integer of 0 or more and 2 or less, R^{10a} represents an alkyl group, an alkoxy group, a halogenated alkyl group, a hydroxyl group, —COOR″, —OC(═O)R″, a hydroxyalkyl group or a cyano group and R″ represents a hydrogen atom or an alkyl group. * represents a bonding hand.)

In formulae (1-1) to (1-4) described above, A′ represents an alkylene group which may include an oxygen atom (—O—) or a sulfur atom (—S—) and in which the number of carbon atoms is 1 or more and 5 or less, an oxygen atom or a sulfur atom. As the alkylene group in A′ in which the number of carbon atoms is 1 or more and 5 or less, a linear or branched alkylene group is preferable, and examples thereof include a methylene group, an ethylene group, an n-propylene group, an isopropylene group and the like.

When the alkylene group described above includes an oxygen atom or a sulfur atom, specific examples thereof include a group in which —O— or —S— is interposed in the terminal of the alkylene group described above or between carbon atoms, and examples thereof include —O—CH₂—, —CH₂—O—CH₂—, —S—CH₂—, —CH₂—S—CH₂— and the like. As A′, an alkylene group in which the number of carbon atoms is 1 or more and 5 or less or —O— is preferable, an alkylene group in which the number of carbon atoms is 1 or more and 5 or less is more preferable and a methylene group is most preferable.

z may be either of 0.1 and 2, and 0 is most preferable. When z is 2, a plurality of R^{10a}s may be the same as or different from each other.

As the alkyl group, the alkoxy group, the halogenated alkyl group, —COOR″, —OC(═O)R″ and the hydroxyalkyl group in R^{10a}, the same ones as the alkyl group, the alkoxy group, the halogenated alkyl group, —COOR″, —OC(═O)R″ and the hydroxyalkyl group mentioned as the substituents that may be included in the —SO₂— containing cyclic group are respectively mentioned.

Specific cyclic groups represented by formulae (1-1) to (1-4) described above will be illustrated below.

“Ac” in the formulae represents an acetyl group. * represents a bonding hand.

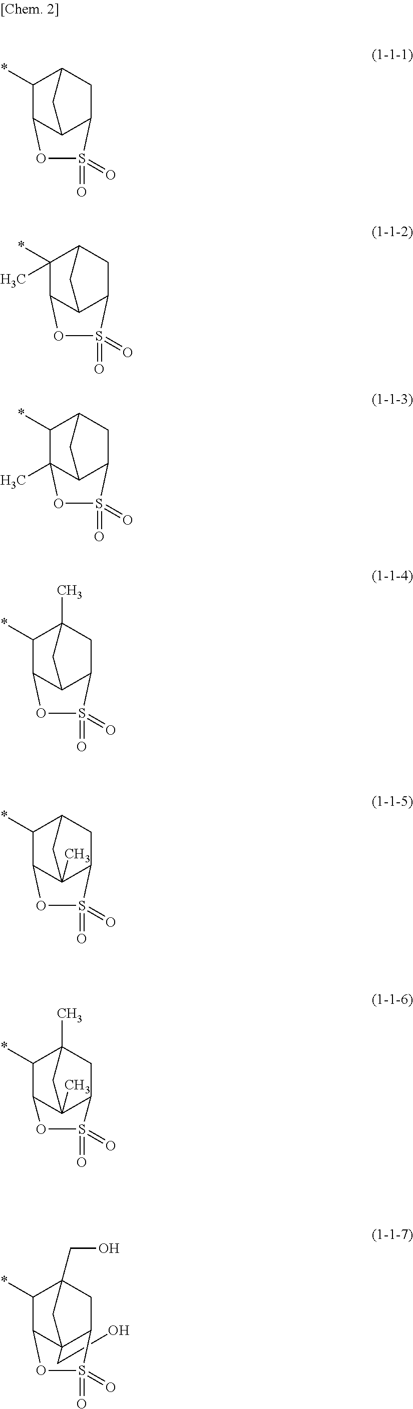

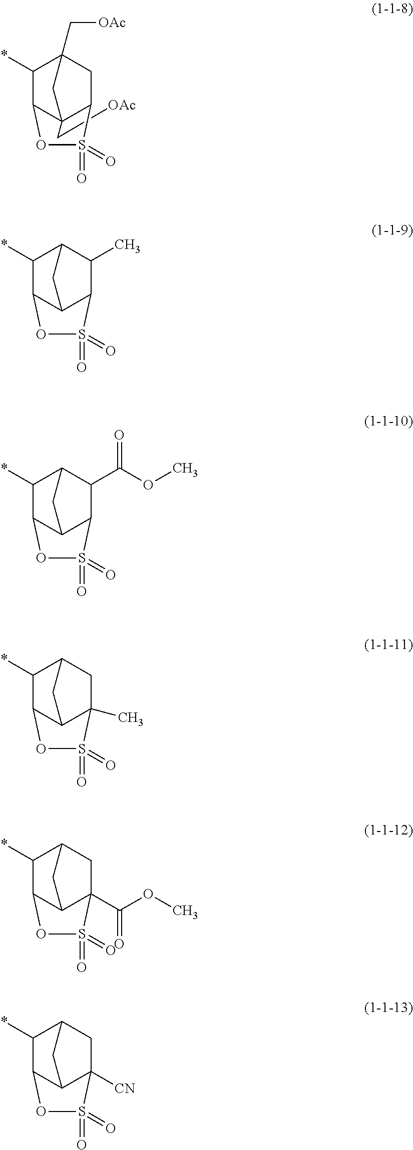 [SMILES: *C1C2OS(=O)(=O)C3CC1(COC(C)=O)CC23COC(C)=O ; *C1C2CC3C1OS(=O)(=O)C3C2C ; *C1C2CC3C1OS(=O)(=O)C3C2C(=O)OC ; *C1C2CC3C1OS(=O)(=O)C3(C)C2 ; *C1C2CC3C1OS(=O)(=O)C3(C(=O)OC)C2 ; *C1C2CC3C1OS(=O)(=O)C3(C#N)C2]

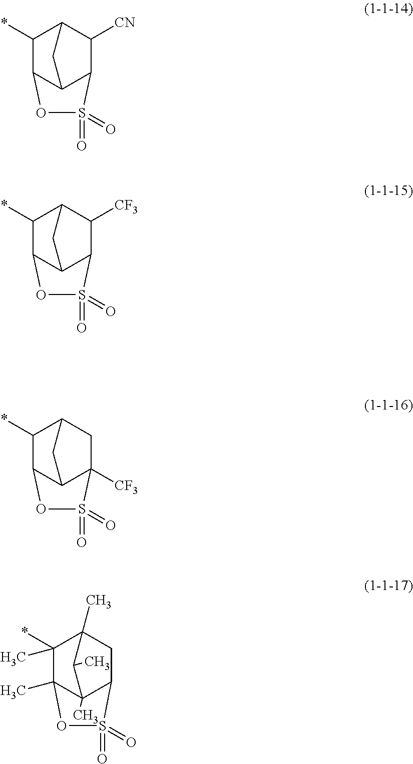 [SMILES: *C1C2CC3C1OS(=O)(=O)C3C2C#N ; *C1C2CC3C1OS(=O)(=O)C3C2C(F)(F)F ; *C1C2CC3C1OS(=O)(=O)C3(C(F)(F)F)C2 ; *C1(C)C2(C)CC3C(C)(C2C)C1(C)OS3(=O)=O]

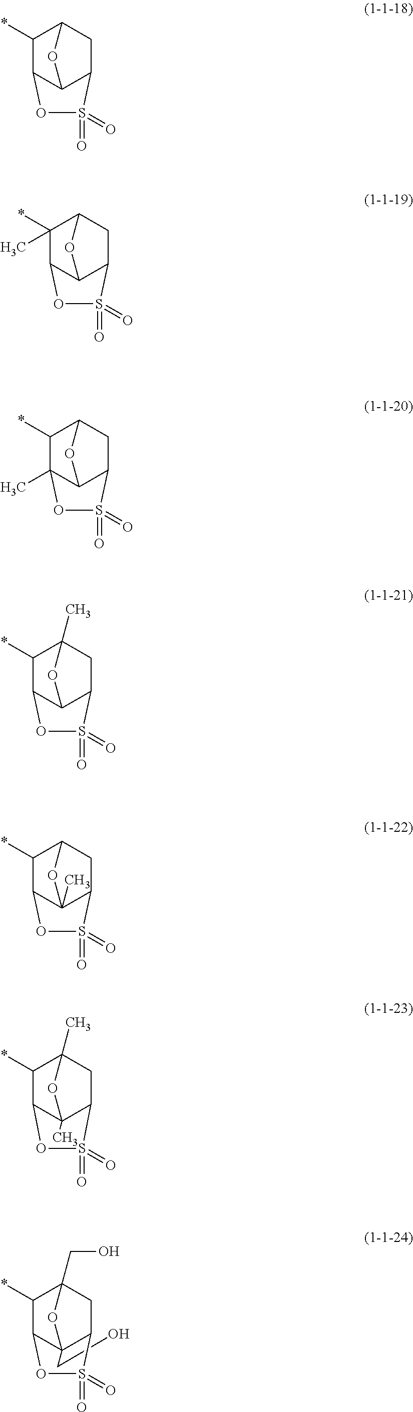

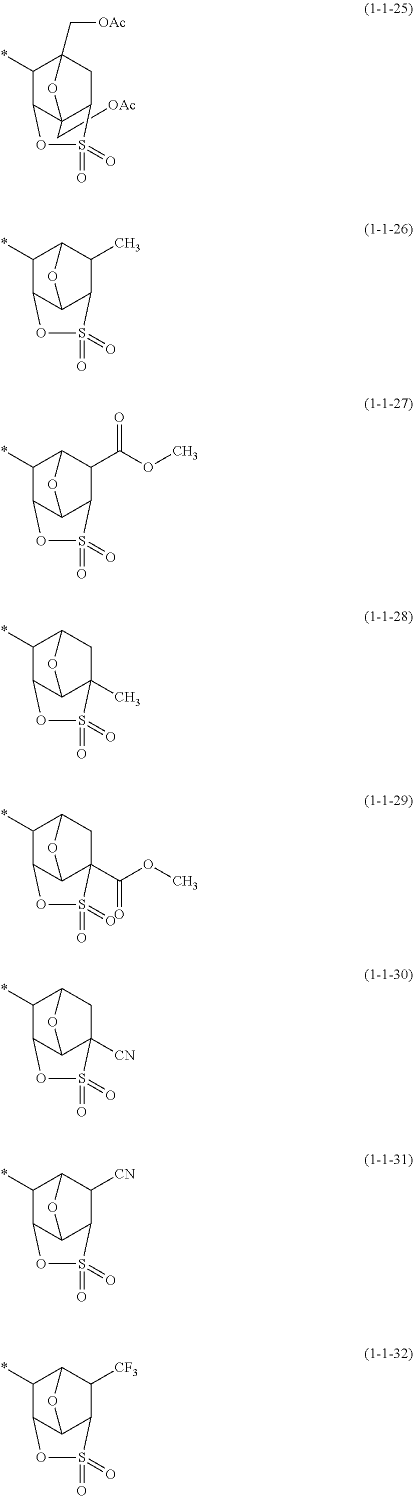

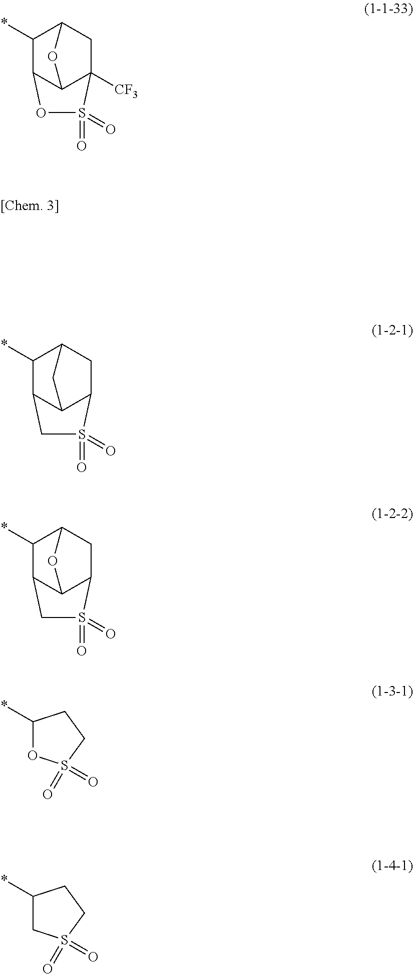 [SMILES: *C1C2CC3(C(F)(F)F)C(O2)C1OS3(=O)=O ; *C1C2CC3C1CS(=O)(=O)C3C2 ; *C1C2CC3C(O2)C1CS3(=O)=O ; *C1CCS(=O)(=O)O1 ; *C1CCS(=O)(=O)C1]

Among the —SO₂— containing cyclic groups described above, the group represented by formula (1-1) described above is preferable, at least one type selected from the group consisting of the groups represented by chemical formulae (1-1-1), (1-1-18), (1-3-1) and (1-4-1) described above is more preferable and the group represented by chemical formula (1-1-1) described above is most preferable.

### (Lactone-Containing Cyclic Group)

The “lactone-containing cyclic group” refers to a cyclic group which contains a ring (lactone ring) including —O—C(═O)-in its ring skeleton. When the lactone ring is counted as the first ring, and only this lactone ring is provided, the lactone-containing cyclic group is referred to as a monocyclic group whereas when another ring structure is further provided, it is referred to as a polycyclic group regardless of its structure. The lactone-containing cyclic group may be either monocyclic or polycyclic.

The lactone-containing cyclic group in the structural unit (a-1) is not particularly limited, and an arbitrary lactone cyclic group containing a lactone ring can be used. Specific examples of the lactone-containing monocyclic group include groups which are obtained by removing one hydrogen atom from 4 to 6 membered ring lactones, for example, a group which is obtained by removing one hydrogen atom from 3-propionolactone, a group which is obtained by removing one hydrogen atom from 7-butyrolactone and a group which is obtained by removing one hydrogen atom from 6-valero lactone. Specific examples of the lactone-containing polycyclic group include groups which are obtained by removing one hydrogen atom from bicycloalkane, tricycloalkane and tetracycloalkane including lactone rings.

In the structure of the structural unit (a-1), the structure of parts other than the —SO₂— containing cyclic group and the lactone-containing cyclic group is not particularly limited as long as the structural unit (a-1) includes the —SO₂— containing cyclic group or the lactone-containing cyclic group. As the structural unit (a-1), at least one type of structural unit is preferable that is selected from the group consisting of a structural unit (a-1-S) which is derived from an acrylic ester where a hydrogen atom bonded to the a-position carbon atom may be substituted with a substituent and which includes the —SO₂— containing cyclic group and a structural unit (a-1-L) which is derived from an acrylic ester where a hydrogen atom bonded to the a-position carbon atom may be substituted with a substituent and which includes the lactone-containing cyclic group.

[Structural Unit (a-1-S)]

More specific examples of the structural unit (a-1-S) include a structural unit represented by formula (a-S1) below.

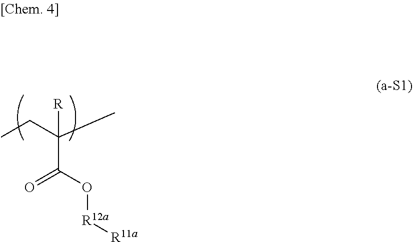

(where R represents a hydrogen atom, an alkyl group in which the number of carbon atoms is 1 or more and 5 or less or a halogenated alkyl group in which the number of carbon atoms is 1 or more and 5 or less, R^{11a} represents a —SO₂— containing cyclic group and R^{12a} represents a single bond or a divalent linking group.)

In formula (a-S1), R is the same as described above R^{11a} is the same as the —SO₂— containing cyclic group described above. R^{12a} may be either a single bond or a divalent linking group. R^{12a} is preferably a divalent linking group such that the effects of the present invention are excellent.

Although the divalent linking group in R^{12a} is not particularly limited, preferred examples thereof include a divalent hydrocarbon group which may include a substituent, a divalent linking group which includes a hetero atom and the like.

Divalent Hydrocarbon Group which May Include a Substituent

The hydrocarbon group serving as the divalent linking group may be an aliphatic hydrocarbon group or an aromatic hydrocarbon group. The aliphatic hydrocarbon group means a hydrocarbon group which does not have aromaticity. The aliphatic hydrocarbon group may be either saturated or unsaturated. In general, an unsaturated hydrocarbon group is preferable. More specific examples of the aliphatic hydrocarbon group include linear and branched aliphatic hydrocarbon groups, an aliphatic hydrocarbon group which includes a ring in its structure and the like.

The number of carbon atoms of the linear or branched aliphatic hydrocarbon group is preferably 1 or more and 10 or less, is more preferably 1 or more and 8 or less and is further preferably 1 or more and 5 or less.

As the linear aliphatic hydrocarbon group, a linear alkylene group is preferable. Specific examples thereof include a methylene group [—CH₂—], an ethylene group [—(CH₂)₂—], a trimethylene group [—(CH₂)₃—], a tetramethylene group [—(CH₂)₄—], a pentamethylene group [—(CH₂)₅-] and the like.

As the branched aliphatic hydrocarbon group, a branched alkylene group is preferable. Specific examples thereof include alkyl alkylene groups such as: alkyl methylene groups such as —CH(CH₃)—, —CH(CH₂CH₃)—, —C(CH₃)₂—, —C(CH₃) (CH₂CH₃)—, —C(CH₃) (CH₂CH₂CH₃)— and —C(CH₂CH₃)₂—; alkyl ethylene groups such as —CH(CH₃)CH₂, —CH(CH₃)CH(CH₃)—, —C(CH₃)₂CH₂—, —CH(CH₂CH₃)CH₂— and —C(CH₂CH₃)₂—CH₂—; alkyl trimethylene groups such as —CH(CH₃)CH₂CH₂— and —CH₂CH(CH₃)CH₂—; and alkyl tetramethylene groups such as —CH(CH₃)CH₂CH₂CH₂— and —CH₂CH(CH₃)CH₂CH₂— and the like. As the alkyl group in the alkyl alkylene group, a linear alkyl group is preferable in which the number of carbon atoms is 1 or more and 5 or less.

The linear or branched aliphatic hydrocarbon group described above may include or may not include a substituent (group or atom other than a hydrogen atom) which substitutes a hydrogen atom. Examples of the substituent include a fluorine atom, a fluorinated alkyl group which is substituted with a fluorine atom and in which the number of carbon atoms is 1 or more and 5 or less, an oxo group (═O) and the like.

Examples of the aliphatic hydrocarbon group which includes a ring in its structure described above include: a cyclic aliphatic hydrocarbon group which may include a substituent that includes a hetero atom in a ring structure (group obtained by removing two hydrogen atoms from an aliphatic hydrocarbon ring); a group in which the cyclic aliphatic hydrocarbon group is bonded to the terminal of a linear or branched aliphatic hydrocarbon group; a group in which the cyclic aliphatic hydrocarbon group is interposed partway in a linear or branched aliphatic hydrocarbon group; and the like. Examples of the linear or branched aliphatic hydrocarbon group described above include the same groups as described above.

The number of carbon atoms of the cyclic aliphatic hydrocarbon group is preferably 3 or more and 20 or less and is more preferably 3 or more and 12 or less.

The cyclic aliphatic hydrocarbon group may be either polycyclic or monocyclic. As the monocyclic aliphatic hydrocarbon group, a group is preferable which is obtained by removing two hydrogen atoms from a monocycloalkane. The number of carbon atoms of the monocycloalkane is preferably 3 or more and 6 or less. Specific examples thereof include cyclopentane, cyclohexane and the like. As the polycyclic aliphatic hydrocarbon group, a group is preferable which is obtained by removing two hydrogen atoms from a polycycloalkane. The number of carbon atoms of the polycycloalkane is 7 or more and 12 or less. Specific examples thereof include adamantane, norbornane, isobornane, tricyclodecane, tetracyclododecane and the like.

The cyclic aliphatic hydrocarbon group may include or may not include a substituent (group or atom other than a hydrogen atom) which substitutes a hydrogen atom. Examples of the substituent include an alkyl group, an alkoxy group, a halogen atom, a halogenated alkyl group, a hydroxyl group, an oxo group (═O) and the like.

As the alkyl group serving as the substituent, an alkyl group is preferable in which the number of carbon atoms is 1 or more and 5 or less, and a methyl group, an ethyl group, a propyl group, an n-butyl group, an isobutyl group and a tert-butyl group are more preferable.

As the alkoxy group serving as the substituent described above, an alkoxy group is preferable in which the number of carbon atoms is 1 or more and 5 or less, a methoxy group, an ethoxy group, an n-propoxy group, an iso-propoxy group, an n-butoxy group and a tert-butoxy group are more preferable and a methoxy group and an ethoxy group are particularly preferable.

Examples of the halogen atom serving as the substituent described above include a fluorine atom, a chlorine atom, a bromine atom, an iodine atom and the like, and a fluorine atom is preferable.

Examples of the halogenated alkyl group serving as the substituent described above include a group in which part or all of hydrogen atoms in the alkyl group described above are substituted with the halogen atom described above.

In the cyclic aliphatic hydrocarbon group, part of carbon atoms forming its ring structure may be substituted with —O— or —S—. As the substituent which includes the hetero atom described above, —O—, —C(═O)—O—, —S—, —S(O═)₂— or —S(O═)₂—O-are preferable.

The aromatic hydrocarbon group serving as the divalent hydrocarbon group is a divalent hydrocarbon group which includes at least one aromatic ring, and may include a substituent. The aromatic ring is not particularly limited as long as it is a cyclic conjugated system which includes (4n+2) π electrons, and the aromatic ring may be either monocyclic or polycyclic. The number of carbon atoms of the aromatic ring is preferably 5 or more and 30 or less, is more preferably 5 or more and 20 or less, is further preferably 6 or more and 15 or less and is particularly preferably 6 or more and 12 or less. However, the number of carbon atoms thereof does not include the number of carbon atoms of the substituent.

Specific examples of the aromatic ring include: aromatic hydrocarbon rings such as benzene, naphthalene, anthracene and phenanthrene; an aromatic heterocycle in which part of hydrogen atoms forming the aromatic hydrocarbon ring is substituted with a hetero atom; and the like. Examples of the hetero atom in the aromatic heterocycle include an oxygen atom, a sulfur atom, a nitrogen atom and the like. Specific examples of the aromatic heterocycle include a pyridine ring, a thiophene ring and the like.

Specific examples of the aromatic hydrocarbon group serving as the divalent hydrocarbon group include: a group which is obtained by removing two hydrogen atoms from the aromatic hydrocarbon ring or the aromatic heterocycle described above (arylene group or heteroarylene group); a group which is obtained by removing two hydrogen atoms from an aromatic compound (for example, biphenyl or fluorene) including two or more aromatic rings; a group in which one of hydrogen atoms in the group that is obtained by removing two hydrogen atoms from the aromatic hydrocarbon ring or the aromatic heterocycle described above (aryl group or heteroaryl group) is substituted with an alkylene group (for example, a group which is obtained by further removing one hydrogen atom from an aryl group in an arylalkyl group such as a benzyl group, a phenethyl group, 1-naphthylmethyl group, 2-naphthylmethyl group, 1-naphthylethyl group or 2-naphthylethyl group); and the like.

The number of carbon atoms of the alkylene group bonded to the aryl group or heteroaryl group described above is preferably 1 or more and 4 or less, is more preferably 1 or more and 2 or less and is particularly preferably 1.

In the aromatic hydrocarbon group described above, the hydrogen atom included in the aromatic hydrocarbon group described above may be substituted with a substituent. For example, the hydrogen atom bonded to the aromatic ring in the aromatic hydrocarbon group described above may be substituted with a substituent. Examples of the substituent described above include an alkyl group, an alkoxy group, a halogen atom, a halogenated alkyl group, an oxo group (═O) and the like.

As the alkyl group serving as the substituent described above, an alkyl group is preferable in which the number of carbon atoms is 1 or more and 5 or less, and a methyl group, an ethyl group, an n-propyl group, an n-butyl group and a tert-butyl group are more preferable.

As the alkoxy group serving as the substituent described above, an alkoxy group is preferable in which the number of carbon atoms is 1 or more and 5 or less, a methoxy group, an ethoxy group, an n-propoxy group, an iso-propoxy group, an n-butoxy group and a tert-butoxy group are preferable and a methoxy group and an ethoxy group are more preferable

Examples of the halogen atom serving as the substituent described above include a fluorine atom, a chlorine atom, a bromine atom, an iodine atom and the like, and a fluorine atom is preferable.

Examples of the halogenated alkyl group serving as the substituent described above include a group in which part or all of hydrogen atoms in the alkyl group described above are substituted with the halogen atom described above.

Divalent Linking Group Including Hetero Atom

The hetero atom in the divalent linking group including the hetero atom is an atom other than a carbon atom and a hydrogen atom, and examples thereof include an oxygen atom, a nitrogen atom, a sulfur atom, a halogen atom and the like.

Specific examples of the divalent linking group including the hetero atom include: non-hydrocarbon based linking groups such as —O—, —C(═O)—, —C(═O)—O—, —O—C(═O)—O—, —S—, —S(═O)₂—, —S(═O)₂—O—, —NH—, —NH—C(═O)—, —NH— C(═NH)— and ═N—; combinations of at least one type of these non-hydrocarbon based linking groups and the divalent hydrocarbon group; and the like. Examples of the divalent hydrocarbon group described above include the same group as the divalent hydrocarbon group which may include the substituent described above, and a linear or branched aliphatic hydrocarbon group is preferable.

Among those described above, —NH— in —C(═O)—NH—, —NH— and Hs in —NH— C(═NH)— may be individually substituted with a substituent such as an alkyl group or an acyl group. The number of carbon atoms of the substituent described above is preferably 1 or more and 10 or less, is more preferably 1 or more and 8 or less and is particularly preferably 1 or more and 5 or less.

As the divalent linking group in R^{12a}, a linear or branched alkylene group, a cyclic aliphatic hydrocarbon group or a divalent linking group including a hetero atom is particularly preferable.

When the divalent linking group in R^{12a} is a linear or branched alkylene group, the number of carbon atoms of the alkylene group is preferably 1 or more and 10 or less, is more preferably 1 or more and 6 or less, is particularly preferably 1 or more and 4 or less and is most preferably 1 or more and 3 or less. Specific examples thereof include the same groups as the linear alkylene group and the branched alkylene group mentioned as the linear or branched aliphatic hydrocarbon group in the description of the “divalent hydrocarbon group which may include a substituent” serving as the divalent linking group described above.

When the divalent linking group in R^{12a} is a cyclic aliphatic hydrocarbon group, examples of the cyclic aliphatic hydrocarbon group include the same group as the cyclic aliphatic hydrocarbon group mentioned as the “aliphatic hydrocarbon group which includes a ring in its structure” in the description of the “divalent hydrocarbon group which may include a substituent” serving as the divalent linking group described above.

As the cyclic aliphatic hydrocarbon group described above, a group which is obtained by removing two or more hydrogen atoms from cyclopentane, cyclohexane, norbornane, isobornane, adamantane, tricyclodecane or tetracyclododecane is particularly preferable.

When the divalent linking group in R^{12a} is a divalent linking group including a hetero atom, examples of the preferable linking group described above include —O—, —C(═O)—O—, —C(═O)—, —O—C(═O)—O—, —C(═O)—NH—, —NH— (H may be substituted with a substituent such as an alkyl group or an acyl group), —S—, —S(═O)₂—, —S(═O)₂—O—, groups which are represented by general formulae of —Y¹—O—Y²—, —[Y¹—C(═O)—O]ₘ′-Y²— and —Y¹—O—C(═O)—Y²— [where Y¹ and Y² each represent a divalent hydrocarbon group which may independently include a substituent, O represents an oxygen atom and m′ represents an integer of 0 or more and 3 or less] and the like.

When the divalent linking group in R^{12a} is —NH—, a hydrogen atom in —NH— may be substituted with a substituent such as an alkyl group or an acyl group. The number of carbon atoms of the substituent (such as an alkyl group or an acyl group) is preferably 1 or more and 10 or less, is more preferably 1 or more and 8 or less and is particularly preferably 1 or more and 5 or less.

In the formulae of —Y¹—O—Y²—, —[Y—C(═O)—O]_{m′}—Y²— and —Y¹—O—C(═O)—Y²—, Y¹ and Y² each represent a divalent hydrocarbon group which may independently include a substituent. Examples of the divalent hydrocarbon group described above include the same group as the “divalent hydrocarbon group which may include a substituent” mentioned in the description of the divalent linking group described above.

As Y¹, a linear aliphatic hydrocarbon group is preferable, a linear alkylene group is more preferable, a linear alkylene group in which the number of carbon atoms is 1 or more and 5 or less is more preferable and a methylene group and an ethylene group are particularly preferable.

As Y², a linear or branched aliphatic hydrocarbon group is preferable, and a methylene group, an ethylene group and an alkyl methylene group are more preferable. As the alkyl group in the alkyl methylene group, a linear alkyl group in which the number of carbon atoms is 1 or more and 5 or less is preferable, a linear alkyl group in which the number of carbon atoms is 1 or more and 3 or less is more preferable and a methyl group is particularly preferable.

In the group represented by the formula of —[Y¹—C(═O)—O]ₘ′-Y²—, m′ is an integer of 0 or more and 3 or less, is preferably an integer of 0 or more and 2 or less, is more preferably 0 or 1 and is particularly preferably 1. In other words, as the group represented by the formula of —[Y¹—C(═O)—O]_{m′}—Y²—, a group represented by the formula of —Y¹—C(═O)—O—Y²— is particularly preferable. Among them, a group represented by the formula of —(CH₂)ₐ′—C(═O)—O—(CH₂)_{b}′— is preferable. In the formula described above, a′ is an integer of 1 or more and 10 or less, is preferably an integer of 1 or more and 8 or less, is more preferably an integer of 1 or more and 5 or less, is further preferably 1 or 2 and is most preferably 1. b′ is an integer of 1 or more and 10 or less, is preferably an integer of 1 or more and 8 or less, is more preferably an integer of 1 or more and 5 or less, is further preferably 1 or 2 and is most preferably 1.

With respect to the divalent linking group in R^{12a}, as the divalent linking group including the hetero atom, organic groups formed by combinations of at least one type of non-hydrocarbon group and a divalent hydrocarbon group are preferable. Among them, a linear group which includes an oxygen atom as a hetero atom, for example, a group which includes an ether bond or an ester bond is preferable, a group represented by the formula of —Y¹—O—Y²—, —[Y—C(═O)—O]ₘ′-Y²— or —Y¹—O—C(═O)—Y²— is more preferable and a group represented by the formula of —[Y—C(═O)—O]ₘ—Y²— or —Y—O—C(═O)—Y²— is particularly preferable.

As the divalent linking group in R^{12a}, an alkylene group or a group including an ester bond (—C(C═O)—O—) is preferable.

As the alkylene group described above, a linear or branched alkylene group is preferable. Preferred examples of the linear aliphatic hydrocarbon group described above include a methylene group [—CH₂—], an ethylene group [—(CH₂)₂—], a trimethylene group [—(CH₂)₃—], a tetramethylene group [—(CH₂)₄—], a pentamethylene group [—(CH₂)₅-] and the like. Preferred examples of the branched alkylene group described above include alkyl alkylene groups such as: alkyl methylene groups such as —CH(CH₃)—, —CH(CH₂CH₃)—, —C(CH₃)₂—, —C(CH₃) (CH₂CH₃)—, —C(CH₃) (CH₂CH₂CH₃)— and —C(CH₂CH₃)₂—; alkyl ethylene groups such as —CH(CH₃)CH₂, —CH(CH₃)CH(CH₃)—, —C(CH₃)₂CH₂—, —CH(CH₂CH₃) CH₂— and —C(CH₂CH₃)₂—CH₂—; alkyl trimethylene groups such as —CH(CH₃)CH₂CH₂— and —CH₂CH(CH₃)CH₂-; and alkyl tetramethylene groups such as —CH(CH₃)CH₂CH₂CH₂— and —CH₂CH(CH₃)CH₂CH₂— and the like.

As the divalent linking group including the ester bond, a group represented by the formula of —R^{13a}—C(═O)—O—[where —R^{13a} represents a divalent linking group] is preferable. In other words, the structural unit (a-1-S) is preferably a structural unit which is represented by formula (a-S1-1) below.

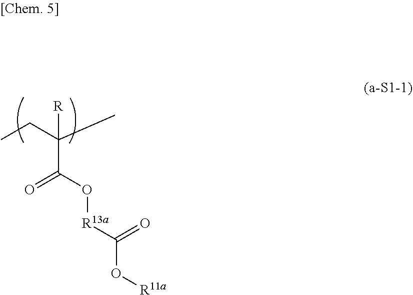

(where R and R^{11a} each are the same as described above, and R^{13a} represents a divalent linking group.)

R^{13a} is not particularly limited, and examples thereof include the same group as the divalent linking group in R^{12a} described above. As the divalent linking group in R^{13a}, a linear or branched alkylene group, an aliphatic hydrocarbon group including a ring in its structure or a divalent linking group including a hetero atom is preferable, and a linear or branched alkylene group or a divalent linking group including an oxygen atom as a hetero atom is preferable.

As the linear alkylene group, a methylene group or an ethylene group is preferable, and a methylene group is particularly preferable. As the branched alkylene group, an alkyl methylene group or an alkyl ethylene group is preferable, and —CH(CH₃)—, —CH(CH₃)₂— or C(CH₃)₂—CH₂— is particularly preferable.

As the divalent linking group including an oxygen atom, a divalent linking group including an ether bond or an ester bond is preferable, and —Y¹—O—Y²—, -[Y—C(═O)—O]_{m′}—Y²— or -yl-O—C(═O)—Y²— described above is more preferable. Y¹ and Y² each represent a divalent hydrocarbon group which may independently include a substituent, and m′ represents an integer of 0 or more and 3 or less. Among them, —Y¹—O—C(═O)—Y²— is preferable, and a group represented by —(CH₂)_{c}—O—C(═O)—(CH₂)_{d}— is particularly preferable.

c represents an integer of 1 or more and 5 or less, and preferably represents 1 or 2.
d represents an integer of 1 or more and 5 or less, and preferably represents 1 or 2.

As the structural unit (a-1-S), a structural unit represented by formula (a-S1-11) or (a-S1-12) below is particularly preferable, and a structural unit represented by formula (a-S1-12) is more preferable.

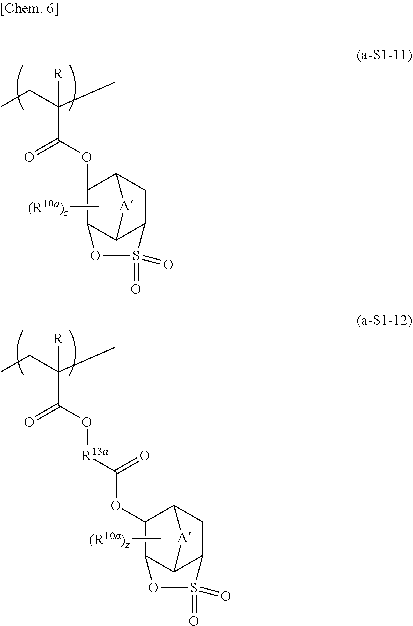

(where R, A′, R^{10a}, z and R^{13a} each represent the same ones as described above.)

In formula (a-S1-11), A′ is preferably a methylene group, an oxygen atom (—O—) or a sulfur atom (—S—).

As R^{13a}, a linear or branched alkylene group or a divalent linking group including an oxygen atom is preferable. As the linear or branched alkylene group and the divalent linking group including an oxygen atom in R^{13a}, the same groups as the linear or branched alkylene group and the divalent linking group including an oxygen atom described above are respectively mentioned.

As the structural unit represented by formula (a-S1-12), a structural unit represented by formula (a-S1-12a) or (a-S1-12b) below is particularly preferable.

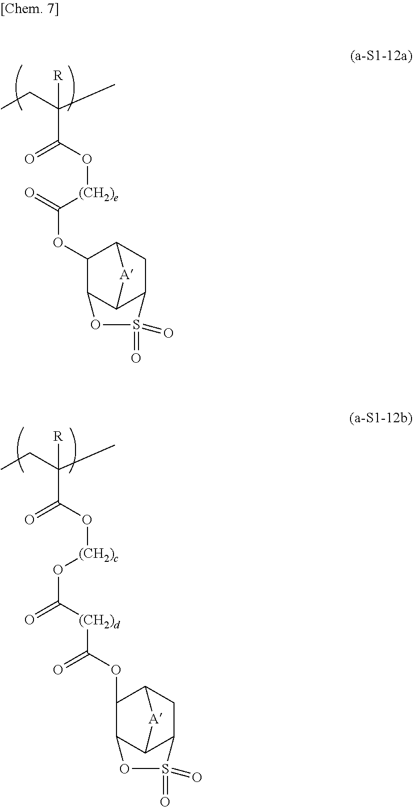

(where R and A′ each represent the same ones as described above, and c to e each independently represent an integer of 1 or more and 3 or less.)
[Structural Unit (a-1-L)]

Examples of the structural unit (a-1-L) include a structural unit in which R^{11a} in formula (a-S1) described above is substituted with a lactone-containing cyclic group More specific examples thereof include structural units represented by formulae (a-L1) to (a-L5) below.

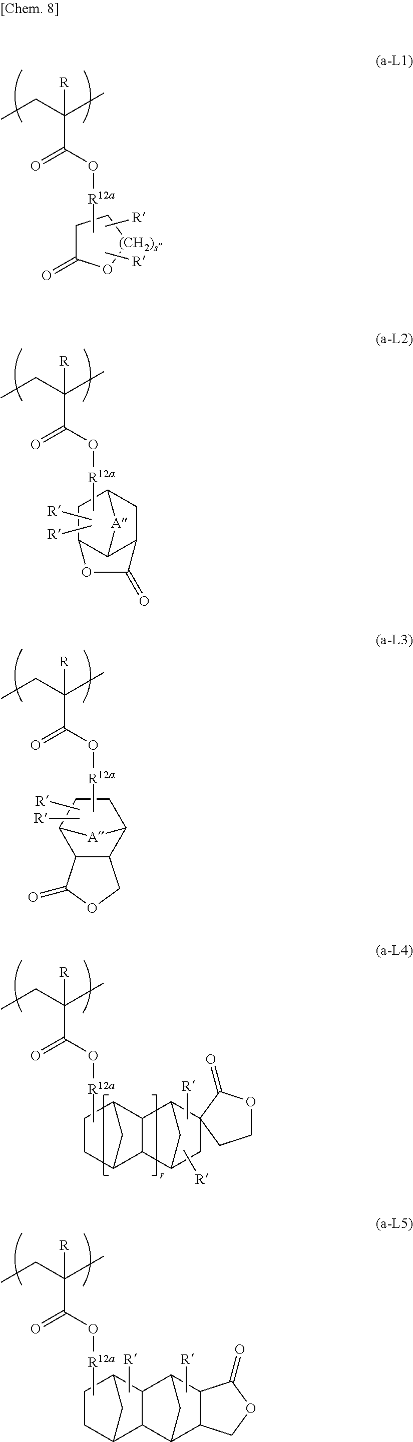

(where R represents a hydrogen atom, an alkyl group in which the number of carbon atoms is 1 or more and 5 or less or a halogenated alkyl group in which the number of carbon atoms is 1 or more and 5 or less; R's each independently represent a hydrogen atom, an alkyl group, an alkoxy group, a halogenated alkyl group, a hydroxyl group, —COOR″, —OC(═O)R″, a hydroxyalkyl group or a cyano group, and R″ represents a hydrogen atom or an alkyl group; R^{12a} represents a single bond or a divalent linking group and s″ represents an integer of 0 or more and 2 or less; A″ represents an alkylene group which may include an oxygen atom or a sulfur atom and in which the number of carbon atoms is 1 or more and 5 or less, an oxygen atom or a sulfur atom; and r represents 0 or 1.)

R in formulae (a-L1) to (a-L5) is the same as described above. As the alkyl group, the alkoxy group, the halogenated alkyl group, —COOR″, —OC(═O)R″ and the hydroxyalkyl group in R′, the same groups as the alkyl group, the alkoxy group, the halogenated alkyl group, —COOR″, —OC(═O)R″ and the hydroxyalkyl group mentioned as the substituents that may be included in the —SO₂— containing cyclic group are respectively mentioned.

With consideration given to ease of availability in industry, R′ is preferably a hydrogen atom. The alkyl group in R″ may be linear, branched or cyclic. When R″ is a linear or branched alkyl group, the number of carbon atoms is preferably 1 or more and 10 or less, and is further preferably 1 or more and 5 or less. When R″ is a cyclic alkyl group, the number of carbon atoms is preferably 3 or more and 15 or less, is further preferably 4 or more and 12 or less and is most preferably 5 or more and 10 or less. Specific examples thereof include a group that is obtained by removing one or more hydrogen atoms from a monocycloalkane which may or may not be substituted with a fluorine atom or a fluorinated alkyl group or a polycycloalkane such as bicycloalkane, tricycloalkane or tetracycloalkane and the like. Specific examples thereof include a group that is obtained by removing one or more hydrogen atoms from a monocycloalkane such as cyclopentane or cyclohexane or a polycycloalkane such as adamantane, norbornane, isobornane, tricyclodecane or tetracyclododecane and the like. Examples of A″ include the same group as A′ in formula (1-1) described above. A″ is preferably an alkylene group in which the number of carbon atoms is 1 or more and 5 or less, an oxygen atom (—O—) or a sulfur atom (—S—), and is more preferably an alkylene group in which the number of carbon atoms is 1 or more and 5 or less or —O—. As the alkylene group in which the number of carbon atoms is 1 or more and 5 or less, a methylene group or a dimethylmethylene group is more preferable, and a methylene group is most preferable.

R^{12a} is the same as R^{12a} in formula (a-S1) described above. In formula (a-L1), s″ is preferably 1 or 2. Specific examples of the structural units represented in formulae (a-L1) to (a-L3) described above will be described below. In each of the formulae below, R^{α} represents a hydrogen atom, a methyl group or a trifluoromethyl group.

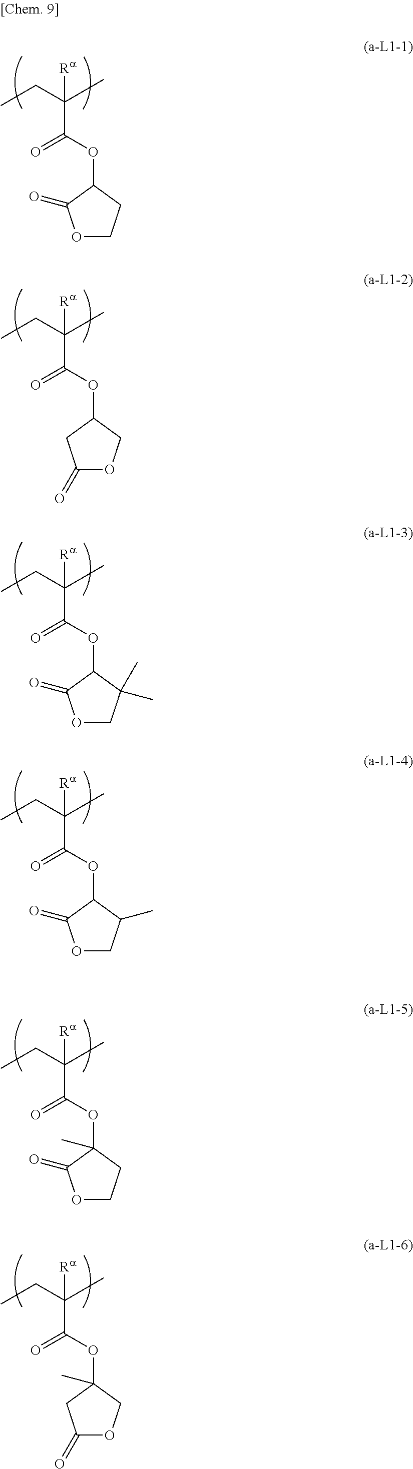

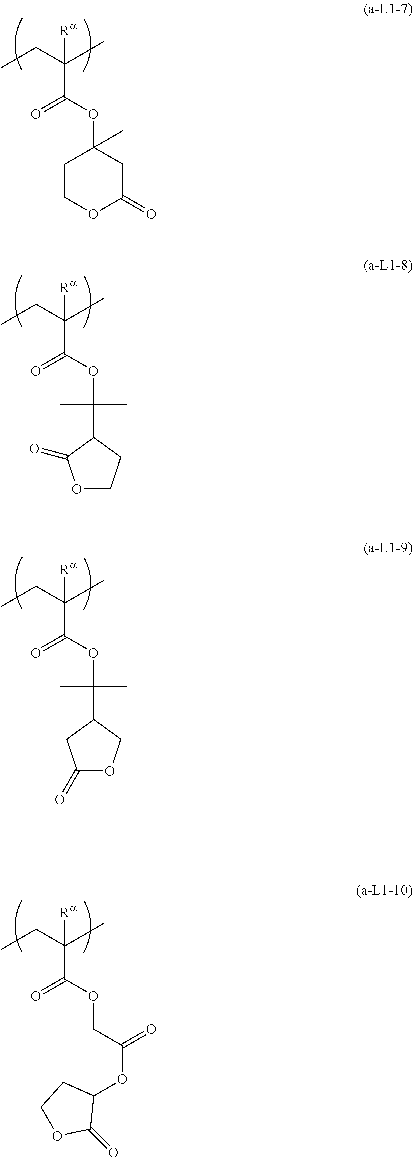

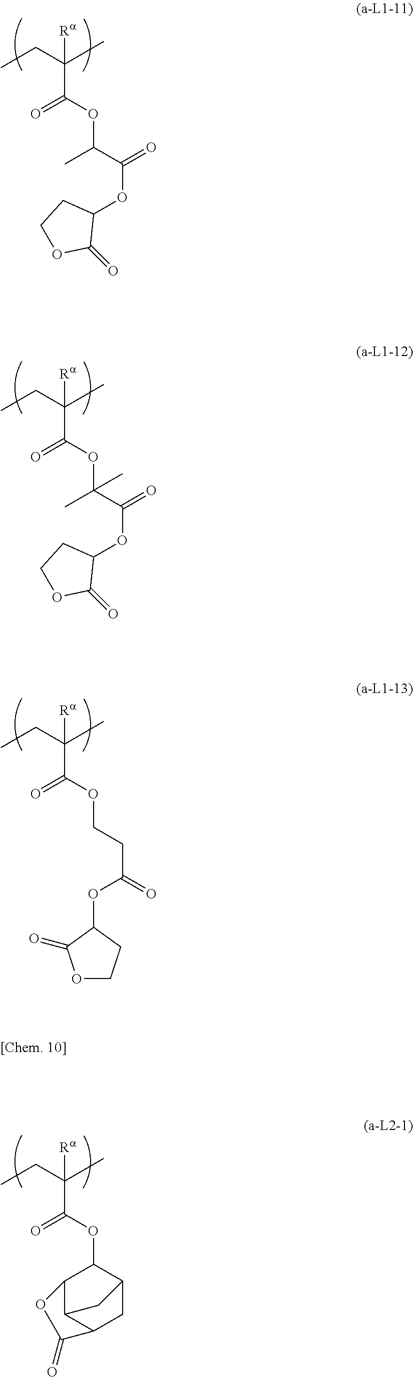

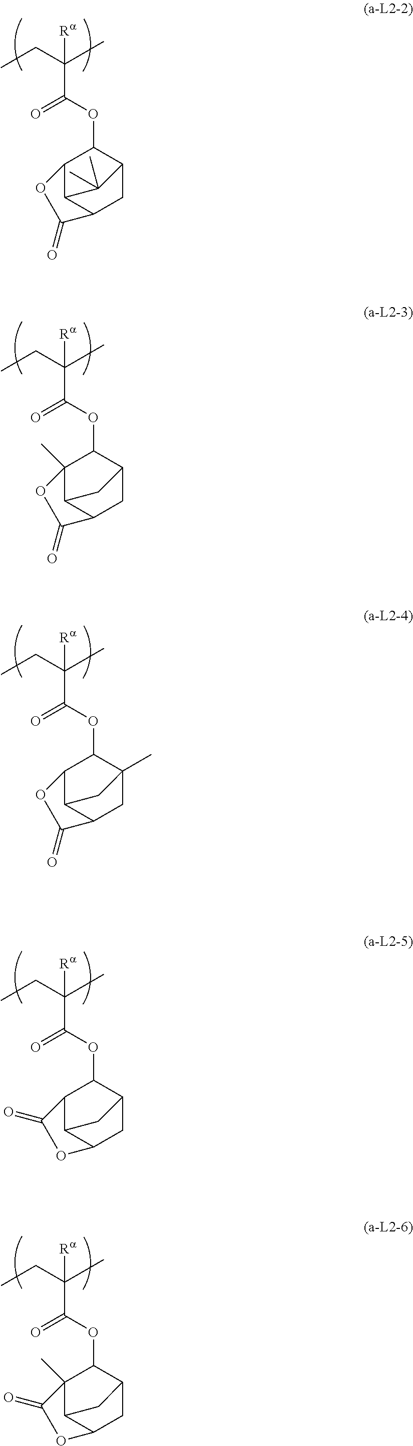

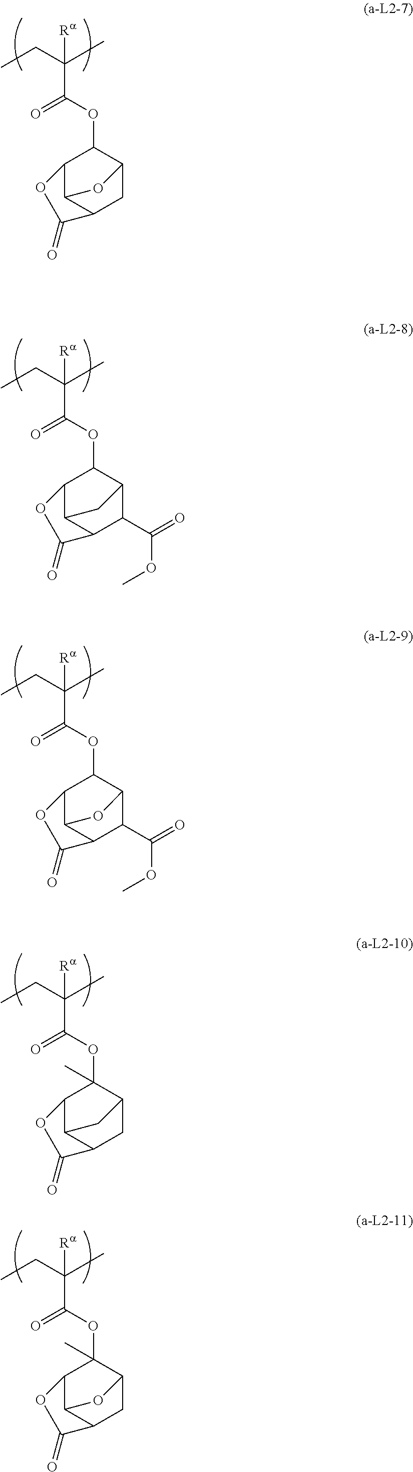

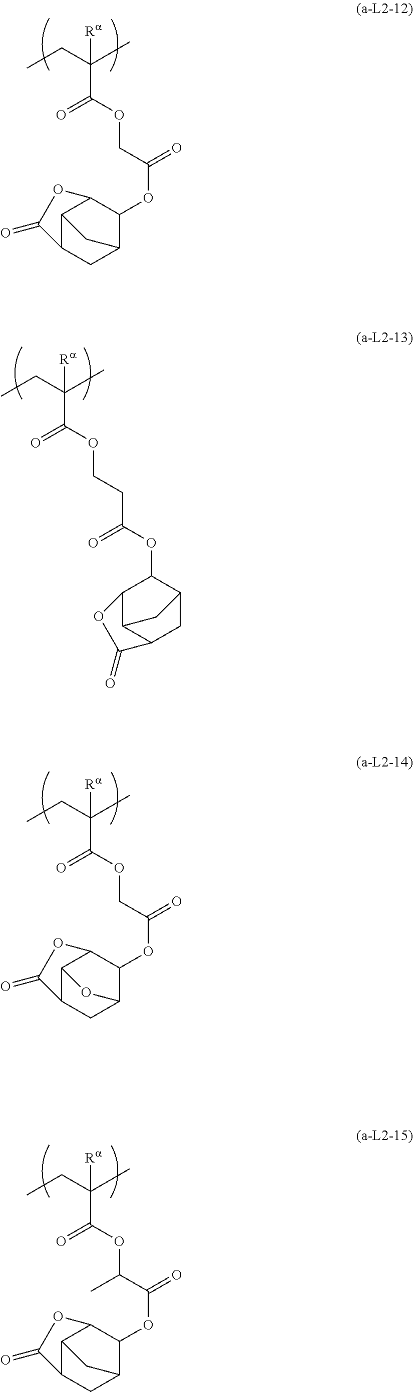

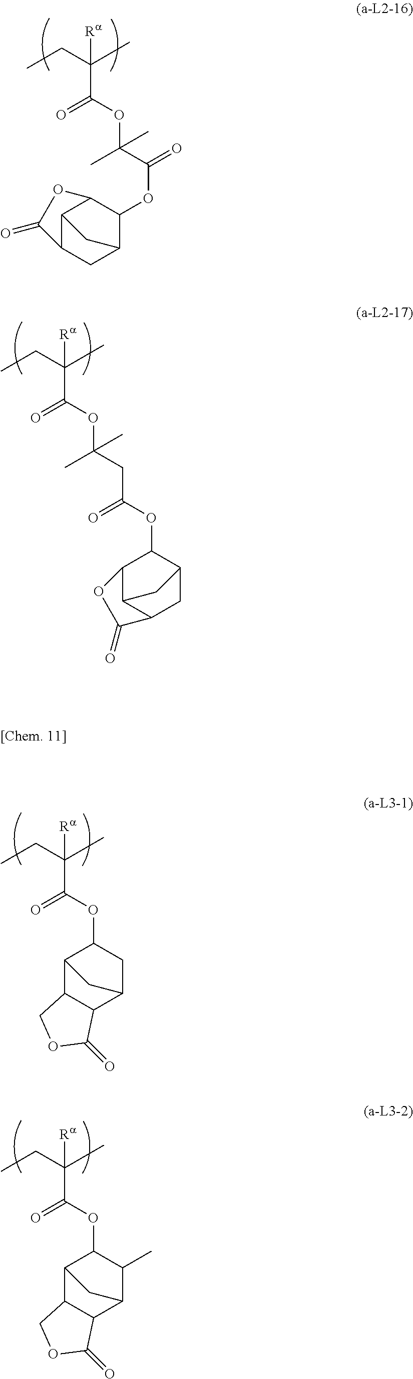

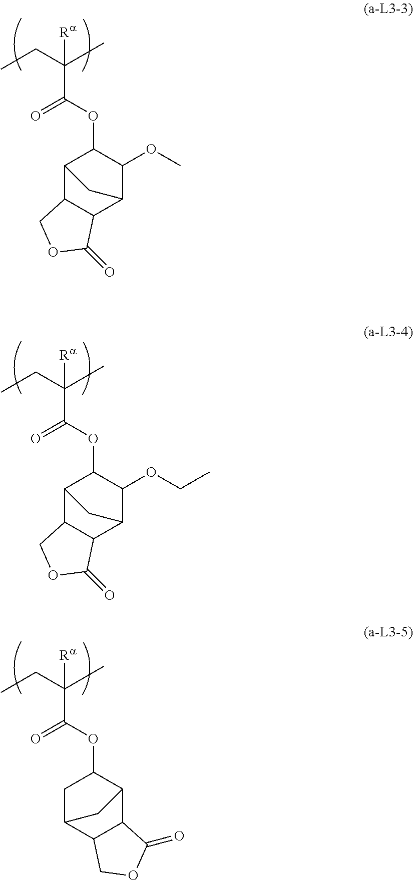

As the structural unit (a-3-L), at least one type selected from the group consisting of the structural units represented by formulae (a-L1) to (a-L5) described above is preferable, at least one type selected from the group consisting of the structural units represented by formulae (a-L1) to (a-L3) described above is more preferable and at least one type selected from the group consisting of the structural units represented by formula (a-L1) or (a-L3) described above is particularly preferable. Among them, at least one type selected from the group consisting of the structural units represented by formulae (a-L1-1), (a-L1-2), (a-L2-1), (a-L2-7), (a-L2-12), (a-L2-14), (a-L3-1) and (a-L3-5) is preferable.

As the structural unit (a-3-L), structural units represented by formulae (a-L6) and (a-L7) below are also preferable.

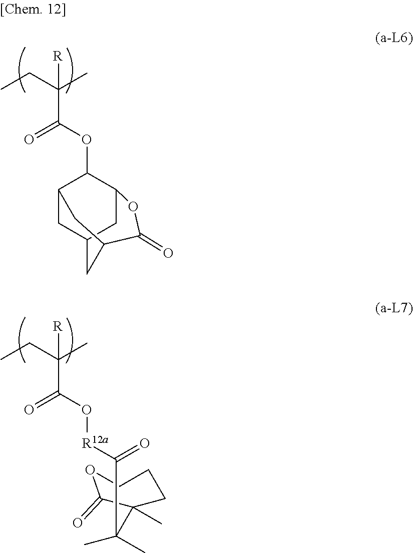

In formulae (a-L6) and (a-L7), R and R^{12a} represent the same ones as described above

The acrylic resin includes, as a structural unit for enhancing the solubility of the acrylic resin in alkali by action of an acid, structural units represented by formulae (a2) to (a4) below which include an acid dissociation group.

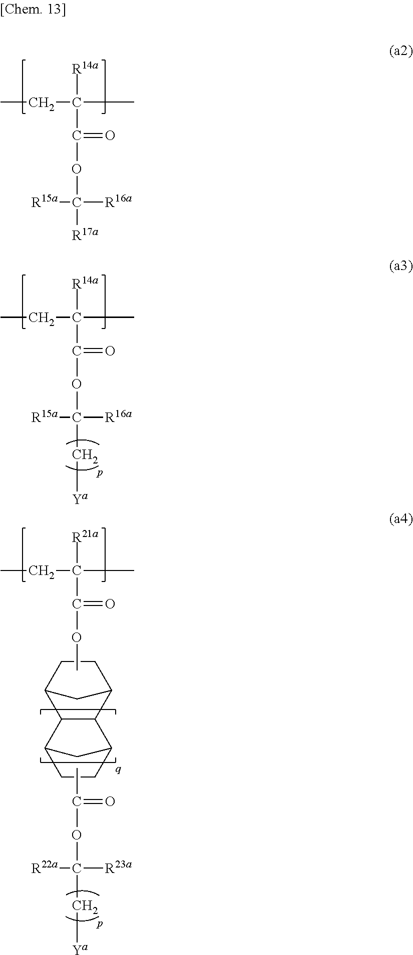

R^{14a} and R^{18a} to R^{23a} in formulae (a2) to (a4) described above each are independently a hydrogen atom, a linear or branched alkyl group having 1 or more and 6 or less carbon atoms, a fluorine atom or a linear or branched fluorinated alkyl group having 1 or more and 6 or less carbon atoms, R^{15a} to R^{17a} each are independently a linear or branched alkyl group having 1 or more and 6 or less carbon atoms, a linear or branched fluorinated alkyl group having 1 or more and 6 or less carbon atoms or an aliphatic cyclic group having 5 or more and 20 or less carbon atoms, R^{16a} and R^{17a} may be bonded to each other to form a hydrocarbon ring having 5 or more and 20 or less carbon atoms together with a carbon atom to which both are bonded, Y^{a} represents an aliphatic cyclic group or an alkyl group which may include a substituent, p represents an integer of 0 or more and 4 or less and q represents 0 or 1.

Examples of the linear or branched alkyl group include a methyl group, ethyl group, propyl group, isopropyl group, n-butyl group, isobutyl group, tert-butyl group, pentyl group, isopentyl group, neopentyl group, and the like. The fluorinated alkyl group refers to a group in which the hydrogen atoms of the alkyl group are partially or entirely substituted with fluorine atoms. Specific examples of the aliphatic cyclic group include a group in which one or more hydrogen atoms are removed from monocycloalkanes and polycycloalkanes such as bicycloalkanes, tricycloalkanes, and tetracycloalkanes. Specific examples thereof include a group in which one hydrogen atom is removed from monocycloalkanes such as cyclopentane, cyclohexane, cycloheptane, and cyclooctane, and polycycloalkanes such as adamantane, norbornane, isobornane, tricyclodecane, and tetracyclododecane. In particular, a group (which may further include a substituent) in which one hydrogen atom is removed from cyclohexane or adamantane is preferable.

In a case where R^{16a} and R^{17a} do not form a hydrocarbon ring by being bonded to each other, a linear or branched alkyl group having 2 or more and 4 or less carbon atoms is preferable as R^{15a}, R^{16a} and R^{17a} in terms of high contrast, satisfactory resolution, satisfactory focal depth-width and the like. As R^{19a}, R^{20a}, R^{22a} and R^{23a}, a hydrogen atom or a methyl group is preferable.

R^{16a} and R^{17a} may form an aliphatic cyclic group having 5 or more and 20 or less carbon atoms together with a carbon atom to which both are bonded. Specific examples of such an aliphatic cyclic group include a group in which one or more hydrogen atoms are removed from monocycloalkane and polycycloalkane such as bicycloalkane, tricycloalkane, and tetracycloalkane. Specifically, they include a group in which one or more hydrogen atoms are removed from monocycloalkane such as cyclopentane, cyclohexane, and cycloheptane; and polycycloalkane such as adamantane, norbornane, isobornane, tricyclodecane and tetracyclododecane; and the like. In particular, cyclohexane and adamantane from which one or more hydrogen atoms are removed (a substituent may be further included) are preferable.

Furthermore, in a case where an aliphatic cyclic group formed with R^{16a} and R^{17a} has a substituent on the ring skeleton thereof, examples of the substituent described above include a polar group such as a hydroxyl group, a carboxyl group, a cyano group and an oxygen atom (═O), and a linear or branched alkyl group having 1 or more and 4 or less carbon atoms. As the polar group, an oxygen atom (═O) is particularly preferable.

Y^{a} described above is an alicyclic group or an alkyl group; and examples thereof are monocycloalkanes and polycycloalkanes such as bicycloalkanes, tricycloalkanes, and tetracycloalkanes from which at least one hydrogen atom is removed. Specific examples thereof are monocycloalkanes such as cyclopentane, cyclohexane, cycloheptane, and cyclooctane, and polycycloalkanes such as adamantane, norbornane, isobornane, tricyclodecane, and tetracyclododecane, from which at least one hydrogen atom is removed. Particularly preferable is adamantane from which at least one hydrogen atom is removed (that may further include a substituent).

Furthermore, when the alicyclic group of Y^{a} described above has a substituent on the ring skeleton, examples of the substituent described above include polar groups such as a hydroxide group, a carboxyl group, a cyano group and an oxygen atom (═O) and linear or branched alkyl groups having 1 or more and 4 or less carbon atoms. The polar group is preferably an oxygen atom (═O) in particular.

Furthermore, when Y^{a} is an alkyl group, it is preferably a linear or branched alkyl group having 1 or more and 20 or less carbon atoms, and is more preferably a linear or branched alkyl group having 6 or more and 15 or less carbon atoms. Preferably, the alkyl group is an alkoxyalkyl group in particular, and examples of the alkoxyalkyl group include a 1-methoxyethyl group, 1-ethoxyethyl group, 1-n-propoxyethyl group, 1-isopropoxyethyl group, 1-n-butoxyethyl group, 1-isobutoxyethyl group, 1-tert-butoxyethyl group, 1-methoxypropyl group, 1-ethoxypropyl group, 1-methoxy-1-methylethyl group, 1-ethoxy-1-methylethyl group and the like.

Preferable specific examples of the structural unit represented by formula (a2) described above include structural units represented by formulae (a2-1) to (a2-33) below.

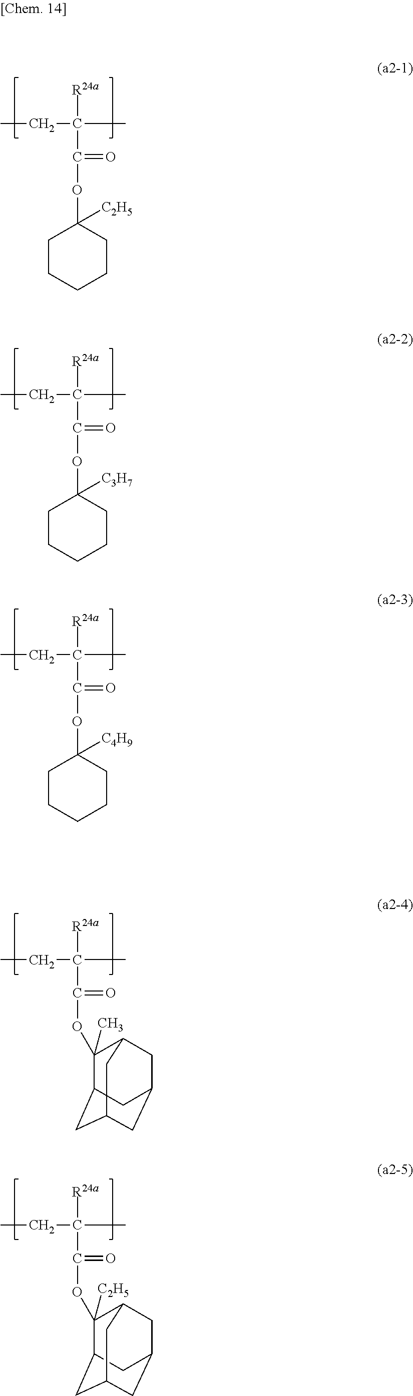

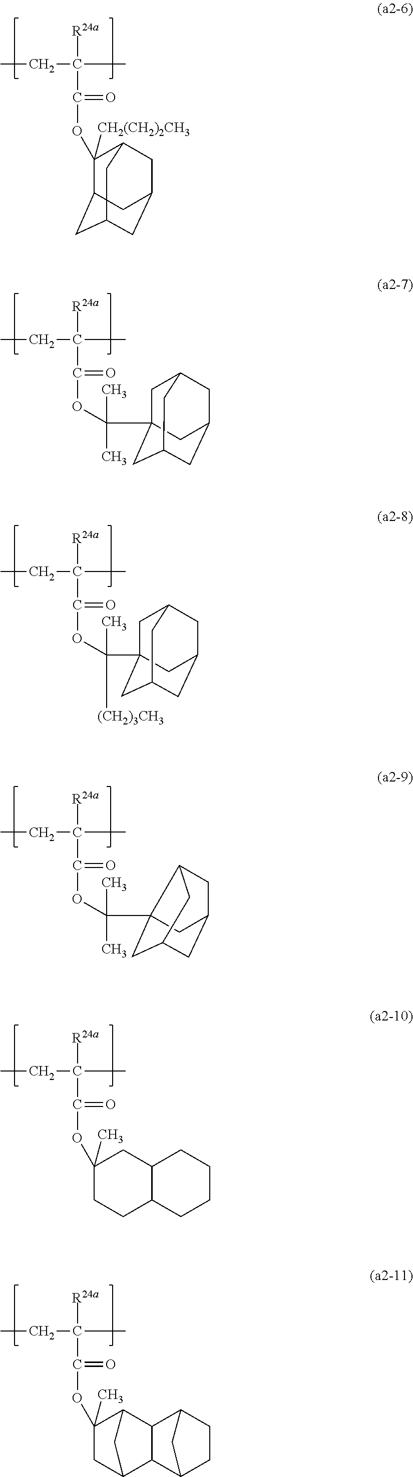

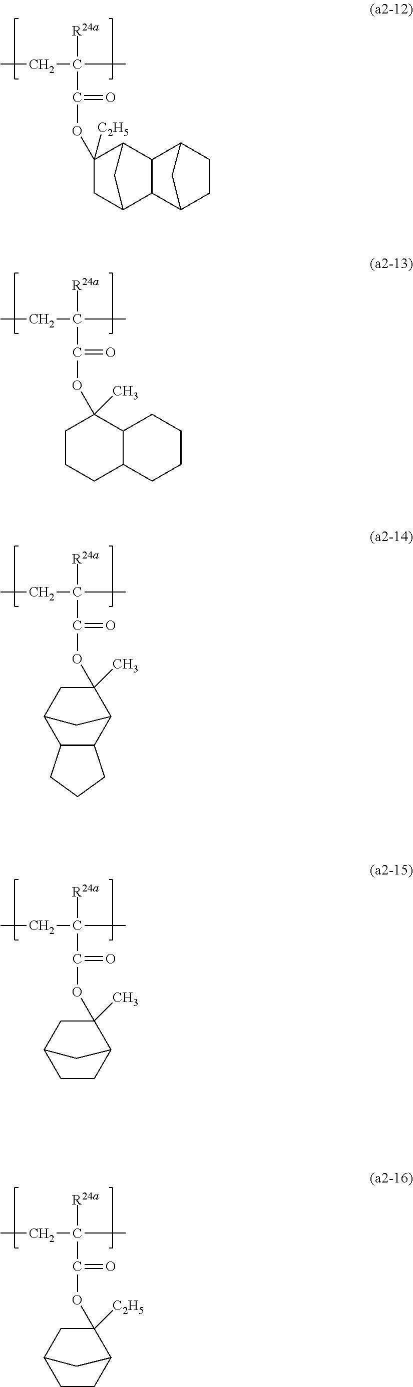

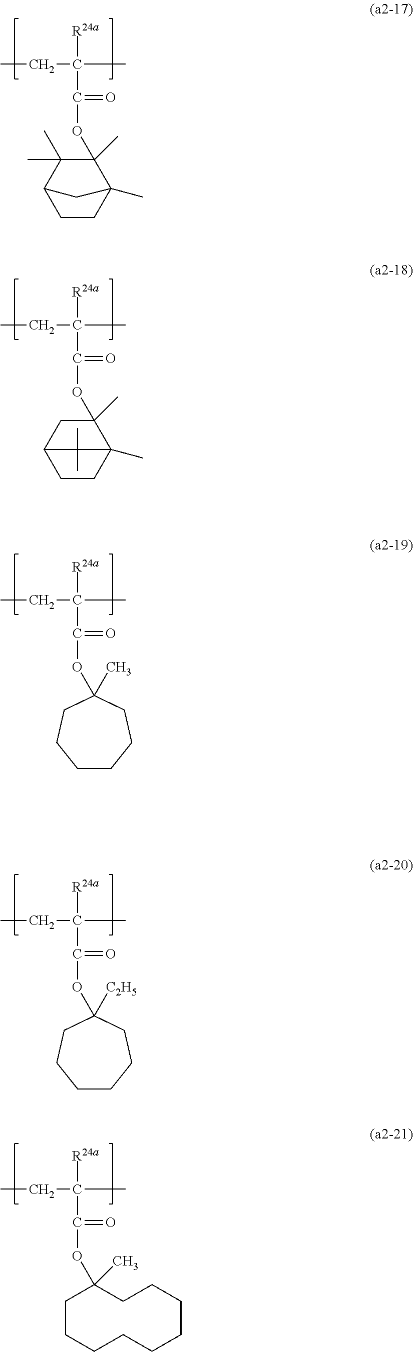

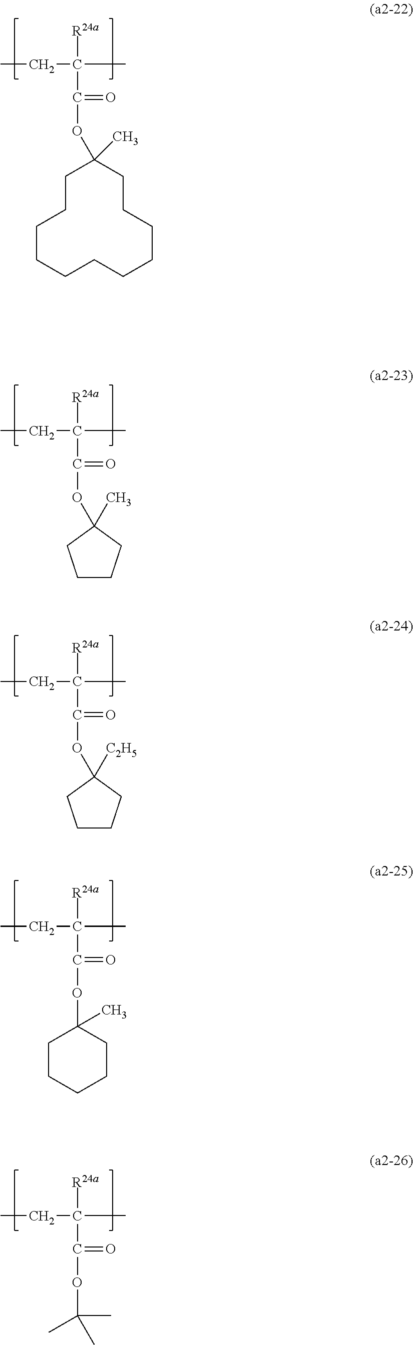

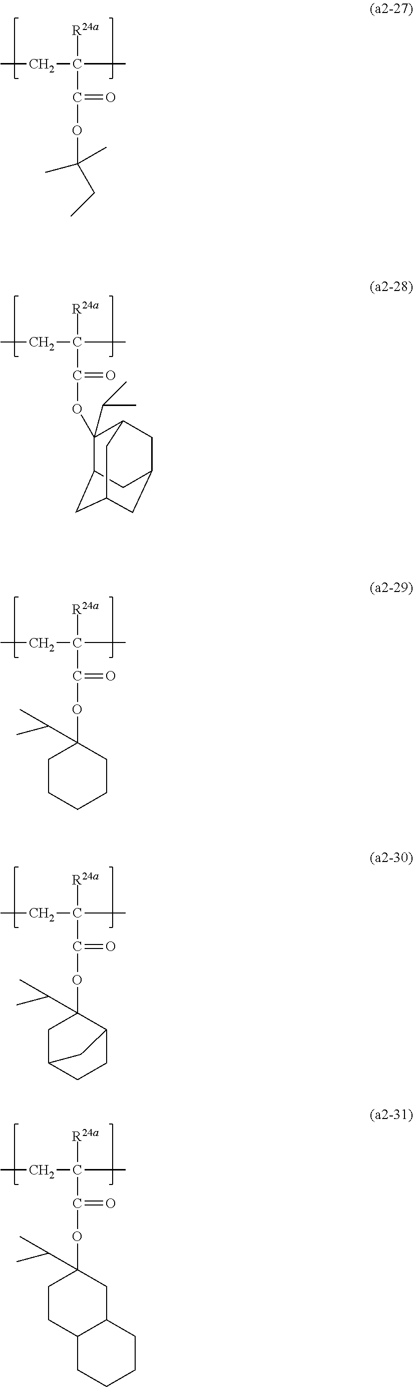

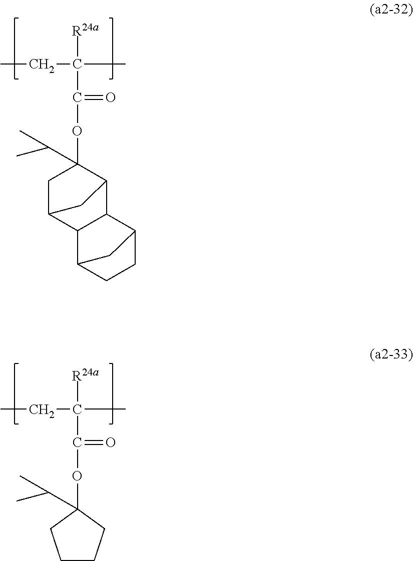

In formulae (a2-1) to (a2-33) described above, R^{24a} represents a hydrogen atom or a methyl group.

Preferable specific examples of the structural unit represented by formula (a3) described above include structural units represented by formulae (a3-1) to (a3-26) below.

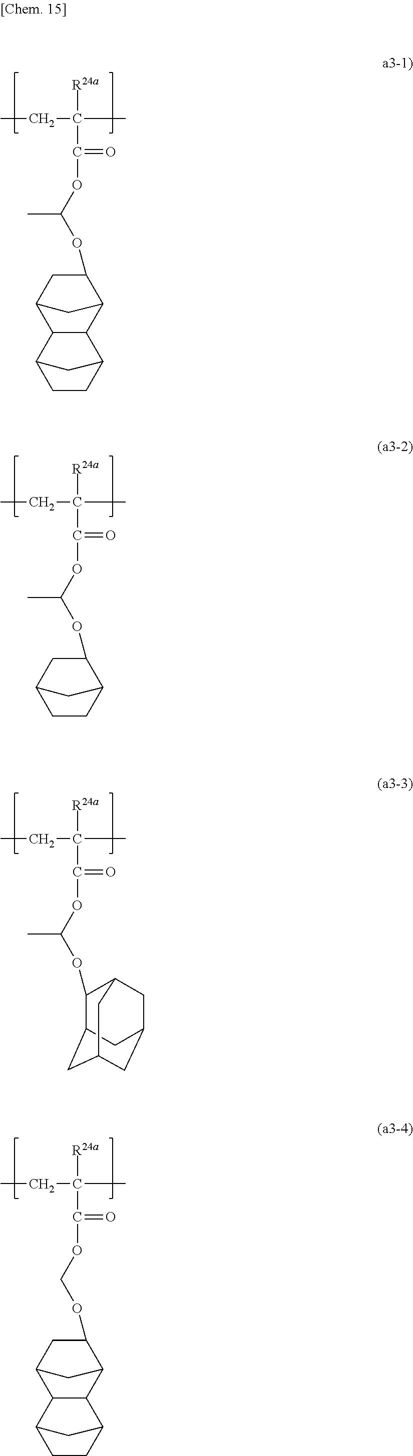

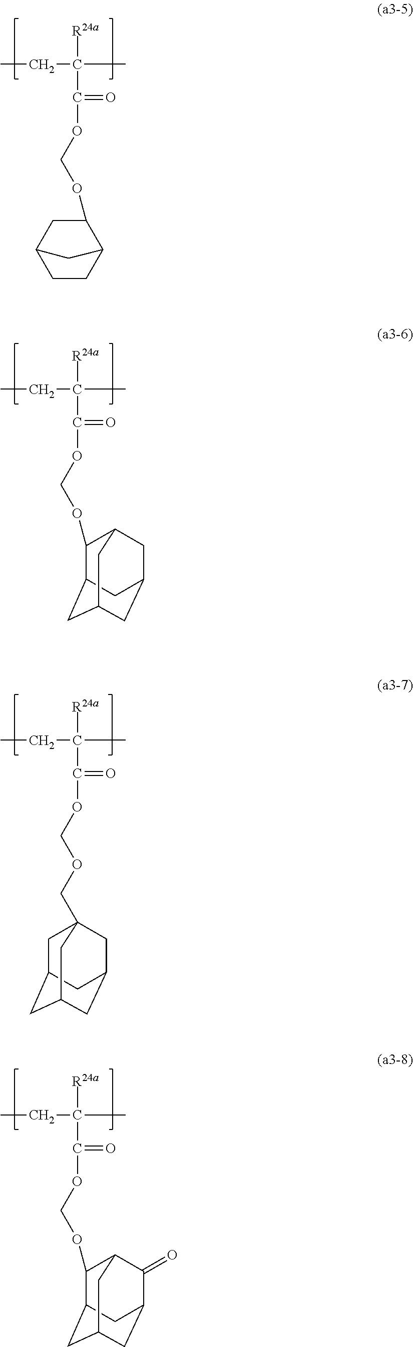

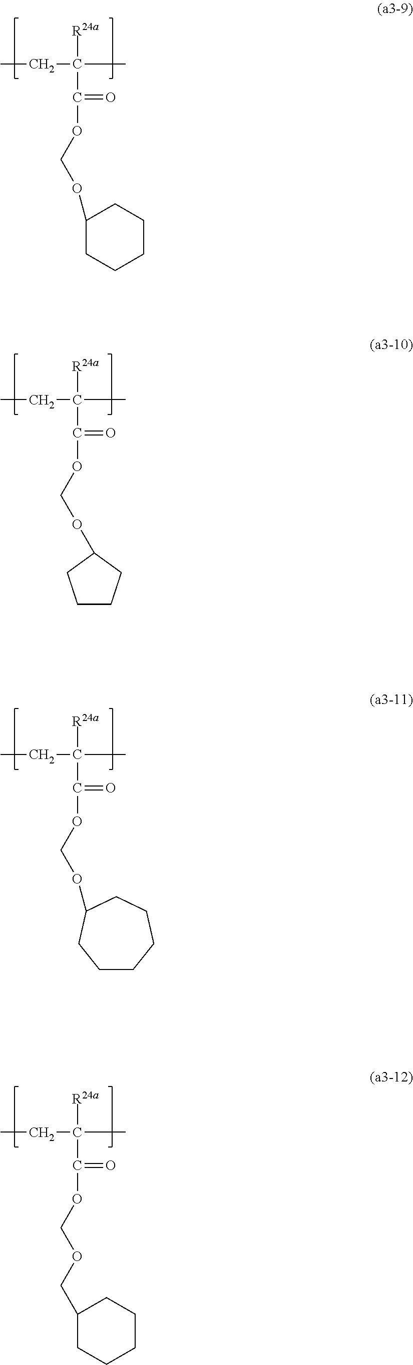

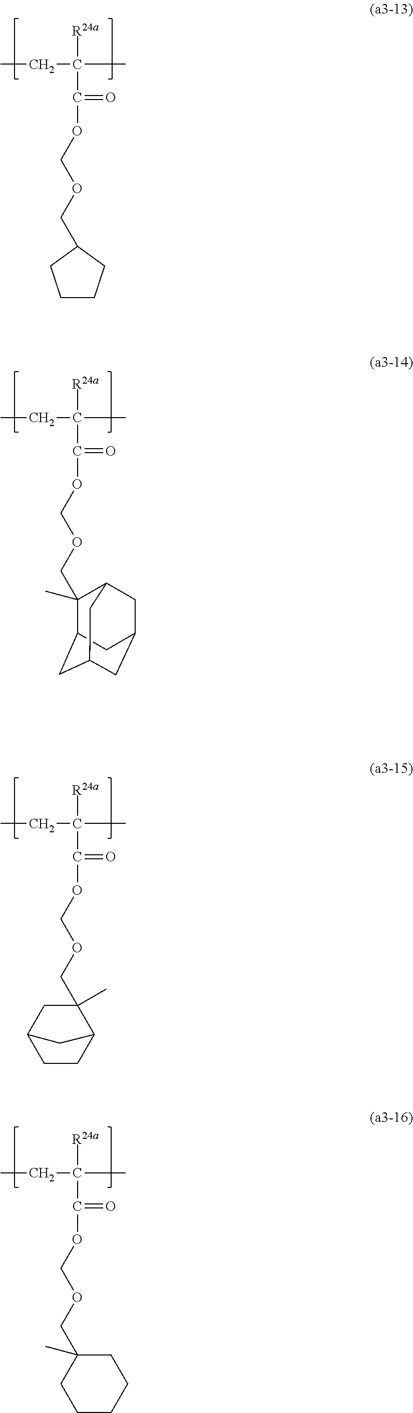

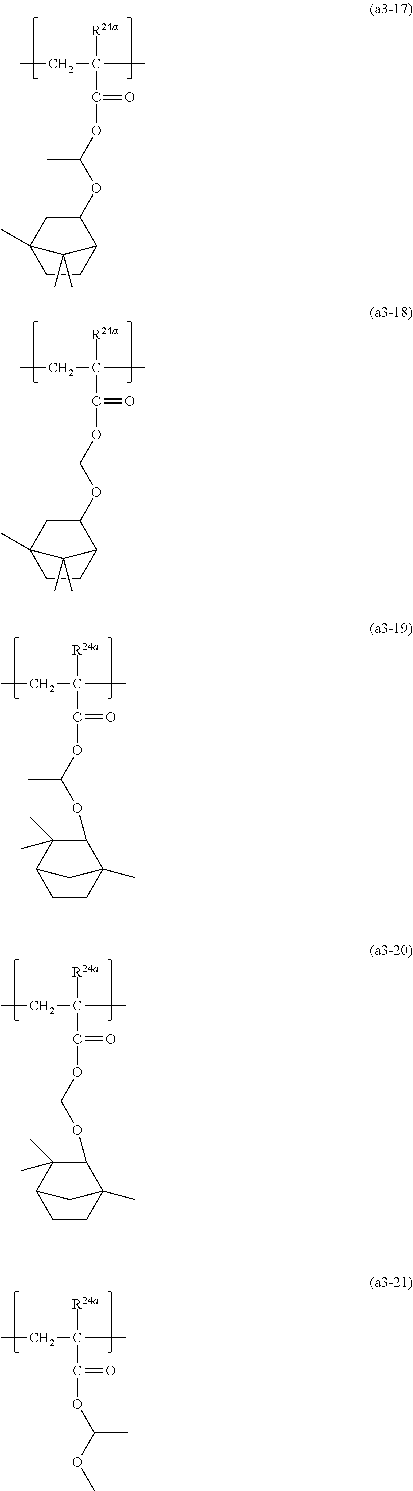

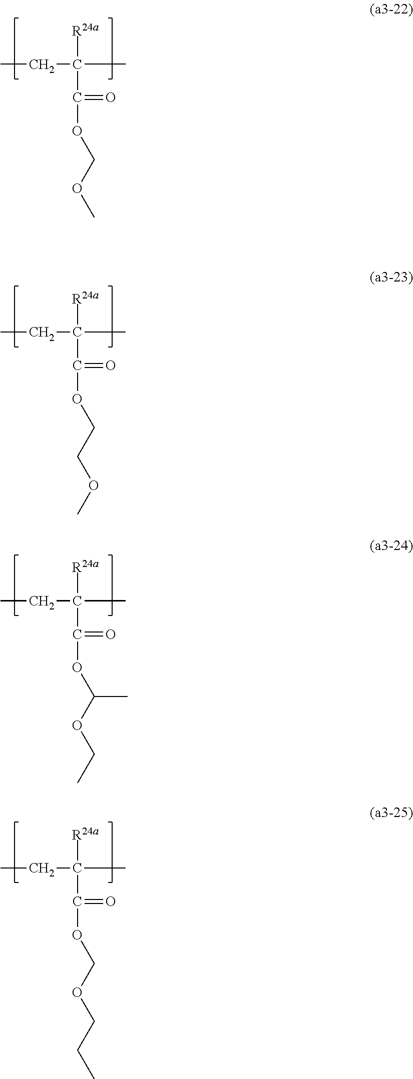

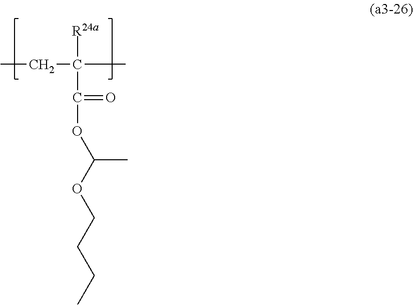

In formulae (a3-1) to (a3-26) described above, R^{24a} presents a hydrogen atom or a methyl group.

Preferable specific examples of the structural unit represented by formula (a4) described above include structural units represented by formulae (a4-1) to (a4-15) below.

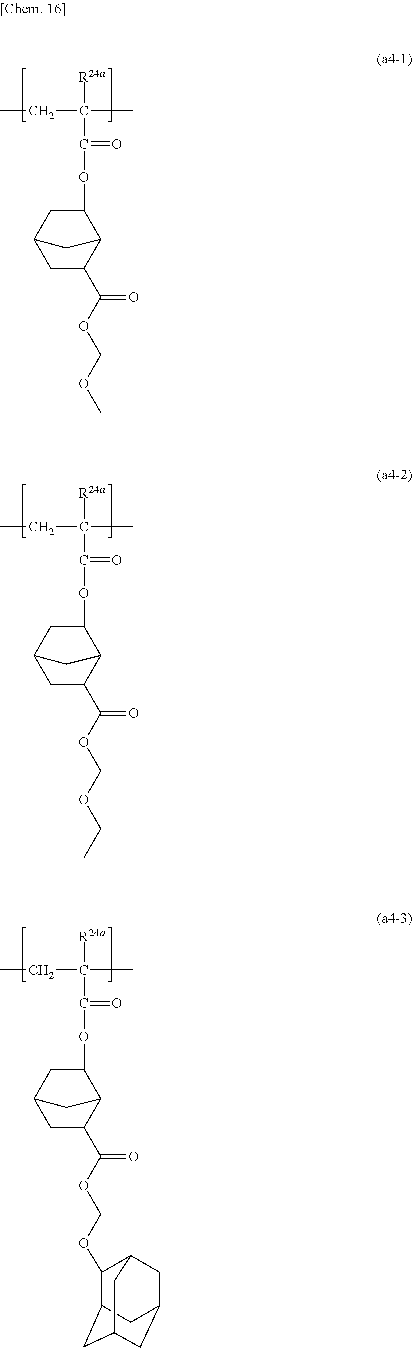

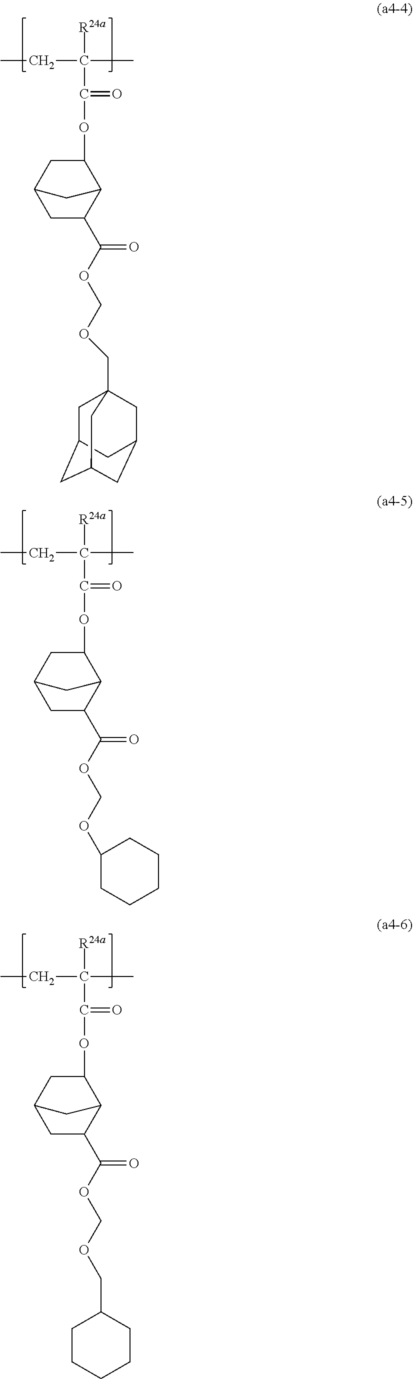

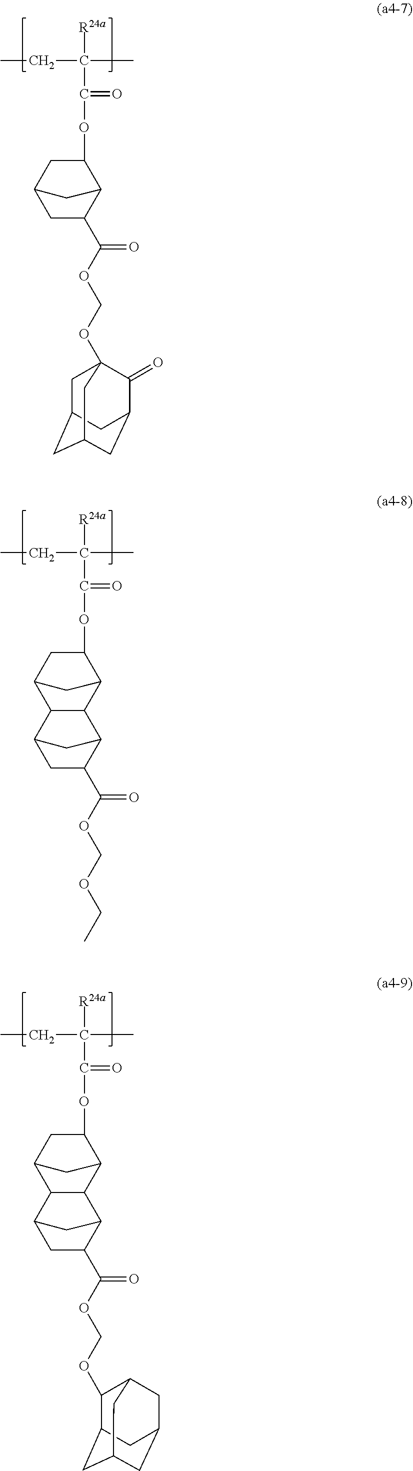

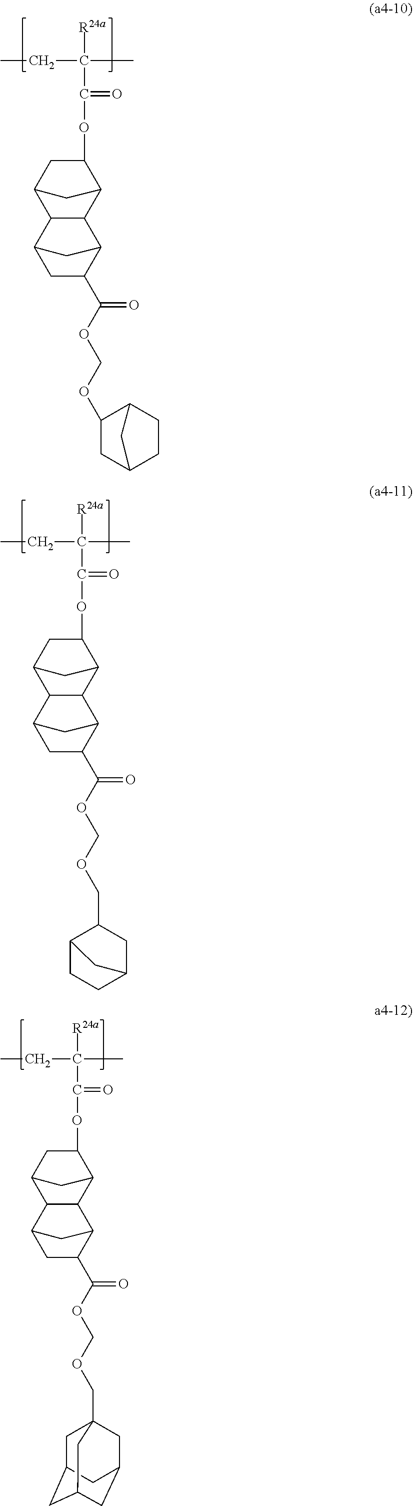

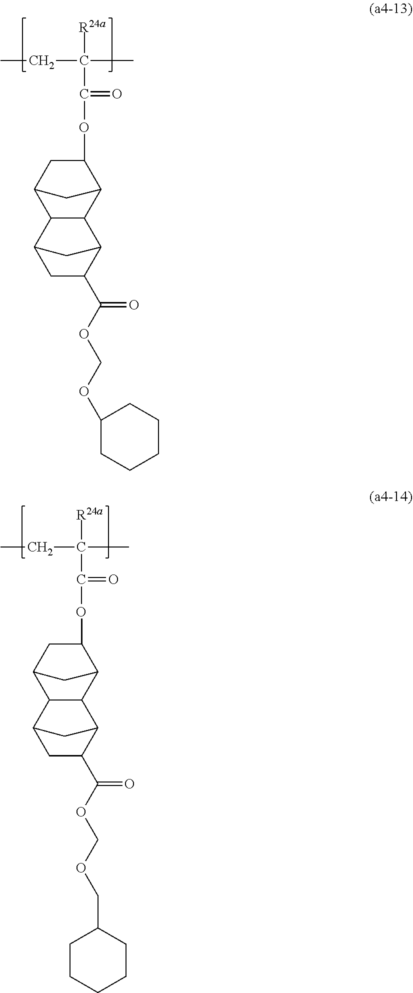

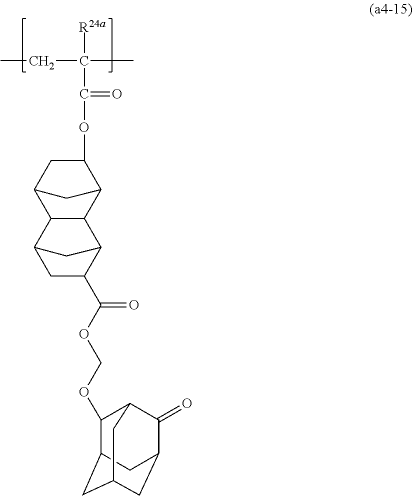

In formulae (a4-1) to (a4-15) described above, R^{24a} resents a hydrogen atom or a methyl group.

Since synthesis is easily performed and high sensitivity is relatively easily achieved, among the structural units represented by formulae (a2) to (a4) described above, the structural unit represented by formula (a3) is preferable. In the structural unit represented by formula (a3), Y^{a} is preferably an alkyl group, and one or both of R^{19b} and R^{20b} are preferably an alkyl group.

It is also preferable that the acrylic resin is formed of a copolymer including the structural units represented by formulae (a2) to (a4) described above and a structural unit derived from a polymerizable compound having an ether bond.

Illustrative examples of the polymerizable compound having an ether linkage include radical polymerizable compounds such as (meth)acrylic acid derivatives having an ether linkage and an ester linkage, and specific examples thereof include 2-methoxyethyl (meth)acrylate, 2-ethoxyethyl (meth)acrylate, methoxytriethylene glycol (meth)acrylate, 3-methoxybutyl (meth)acrylate, ethylcarbitol (meth)acrylate, phenoxypolyethylene glycol (meth)acrylate, methoxypolyethylene glycol (meth)acrylate, methoxypolypropylene glycol (meth)acrylate, tetrahydrofurfuryl (meth)acrylate and the like. The polymerizable compound having an ether linkage is preferably 2-methoxyethyl (meth)acrylate, 2-ethoxyethyl (meth)acrylate or methoxytriethylene glycol (meth)acrylate. These polymerizable compounds may be used alone or in combinations of two or more thereof.

Furthermore, the acrylic resin include another polymerizable compound as a structural unit in order to moderately control physical and chemical properties. Examples of the polymerizable compound include conventional radical polymerizable compounds and anion polymerizable compounds.

Examples of the polymerizable compound include monocarboxylic acids such as acrylic acid, methacrylic acid, and crotonic acid; dicarboxylic acids such as maleic acid, fumaric acid, and itaconic acid; methacrylic acid derivatives having a carboxyl group and an ester bond such as 2-methacryloyloxyethyl succinic acid, 2-methacryloyloxyethyl maleic acid, 2-methacryloyloxyethyl phthalic acid, and 2-methacryloyloxyethyl hexahydrophthalic acid; (meth)acrylic acid alkyl esters such as methyl(meth)acrylate, ethyl(meth)acrylate, butyl(meth)acrylate, and cyclohexyl(meth)acrylate; (meth)acrylic acid hydroxyalkyl esters such as 2-hydroxyethyl (meth)acrylate and 2-hydroxypropyl (meth)acrylate; (meth)acrylic acid aryl esters such as phenyl (meth)acrylate and benzyl (meth)acrylate; dicarboxylic acid diesters such as diethyl maleate and dibutyl fumarate; vinyl group-containing aromatic compounds such as styrene, α-methylstyrene, chlorostyrene, chloromethylstyrene, vinyltoluene, hydroxystyrene, α-methylhydroxystyrene, and α-ethylhydroxystyrene; vinyl group-containing aliphatic compounds such as vinyl acetate; conjugated diolefins such as butadiene and isoprene; nitrile group-containing polymerizable compounds such as acrylonitrile and methacrylonitrile; chlorine-containing polymerizable compounds such as vinyl chloride and vinylidene chloride; amide bond-containing polymerizable compounds such as acrylamide and methacrylamide; and the like.

As described previously, the resin (A) includes the acrylic resin which includes the carboxy group. Hence, the acrylic resin essentially includes the structural unit derived from the polymerizable compound including the carboxy group such as the monocarboxylic acids or the dicarboxylic acids described above. Specifically, a proportion of the structural unit derived from the polymerizable compound including the carboxy group in the acrylic resin is preferably 1% by mass or more and 30% by mass or less, is more preferably 3% by mass or more and 25% by mass or less and is particularly preferably 5% by mass or more and 20% by mass or less.

Furthermore, examples of the polymerizable compound include (meth)acrylic acid esters having a non-acid-dissociable aliphatic polycyclic group and vinyl group-containing aromatic compounds. As the non-acid-dissociable aliphatic polycyclic group, in particular, a tricyclodecanyl group, an adamantyl group, a tetracyclododecanyl group, an isobornyl group, a norbornyl group and the like are preferable in that, for example, they are easily industrially available. These aliphatic polycyclic groups may have a linear or branched alkyl group having 1 or more and 5 or less carbon atoms as a substituent.

Specific examples of the structural unit derived from the (meth)acrylic acid esters including a non-acid-dissociable aliphatic polycyclic group include structural units having structures of formulae (a5-1) to (a5-5) below.

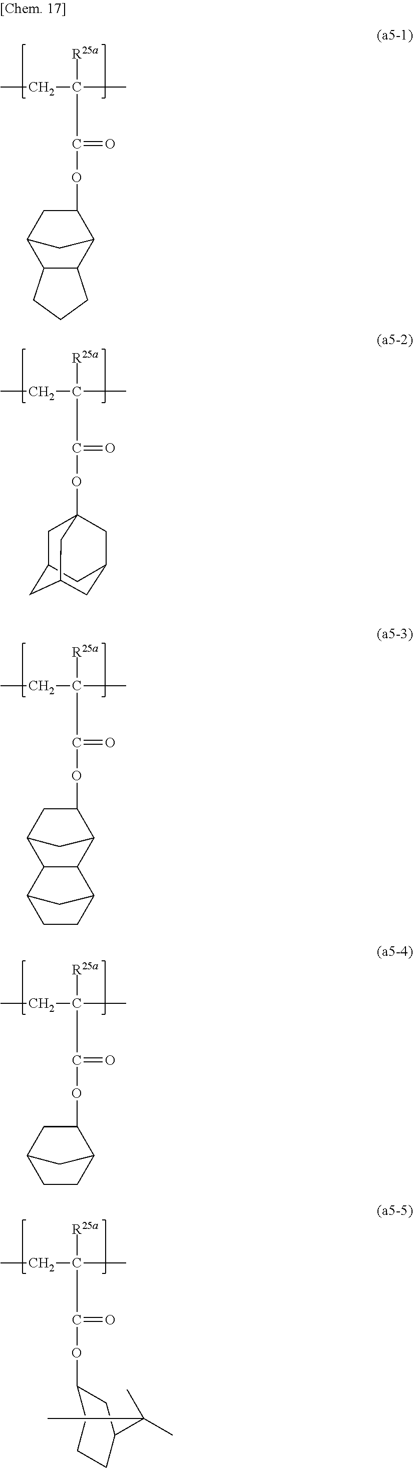

In formulae (a5-1) to (a5-5) described above, R^{25a} represents a hydrogen atom or a methyl group.

When the acrylic resin includes the structural unit (a-1) which includes the —SO₂— containing cyclic group or the lactone-containing cyclic group, the content of the structural unit (a-1) in the acrylic resin is preferably 5% by mass or more, is more preferably 10% by mass or more, is particularly preferably 10% by mass or more and 50% by mass or less and is most preferably 10% by mass or more and 30% by mass or less. When the photosensitive resin composition includes the amount of structural unit (a-1) within the above range, both satisfactory developability and a satisfactory pattern shape are easily achieved.

The acrylic resin preferably includes 5% of the structural units represented by formulae (a2) to (a4) described above by mass or more, more preferably includes 10% thereof by mass or more and particularly preferably includes 10% thereof by mass or more and 50% thereof by mass or less.

The acrylic resin preferably includes the structural unit derived from the polymerizable compound having an ether bond described above. The content of the structural unit derived from the polymerizable compound having an ether bond in the acrylic resin (B3) is preferably 0% by mass or more and 50% by mass or less, and is more preferably 5% by mass or more and 30% by mass or less.

The acrylic resin preferably includes the structural unit derived from the (meth)acrylic acid esters having the non-acid-dissociable aliphatic polycyclic group described above. The content of the structural unit derived from the (meth)acrylic acid esters having the non-acid-dissociable aliphatic polycyclic group in the acrylic resin is preferably 0% by mass or more and 50% by mass or less, and is more preferably 5% by mass or more and 30% by mass or less.

The polystyrene equivalent mass average molecular weight of the resin (A) described above is preferably 3000 or more and 100000 or less, is more preferably 4000 or more and 50000 or less and is further preferably 4000 or more and 40000 or less. By the setting of the mass average molecular weight described above, it is possible to hold sufficient strength of the photosensitive resin layer without lowering separation from a substrate and to further prevent the swelling of a profile at the time of plating and the occurrence of a crack.

The dispersivity of the resin (A) is preferably 1.05 or more. Here, the dispersivity refers to a value which is obtained by dividing a mass average molecular weight by a number average molecular weight. The dispersivity in the range described above is set, and thus it is possible to achieve desired stress resistance on plating and to avoid a problem in which a metal layer resulting from plating processing easily swells.

The resin (A) may be used alone or two or more types may be combined so as to be used. The content of the resin (A) is preferably 5% by mass or more and 60% by mass or less with respect to the total mass of the positive-type photosensitive resin composition. The content of the resin (A) is preferably 5% by mass or more and 98% by mass or less and is preferably 10% by mass or more and 95% by mass or less with respect to the total solid mass content of the positive-type photosensitive resin composition.

### <Polyfunctional Vinyl Ether Monomer (B)>

The positive-type photosensitive resin composition contains the polyfunctional vinyl ether monomer (B). When the positive-type photosensitive resin composition includes the polyfunctional vinyl ether monomer (B) together with the resin (A) described above, the coating film formed of the positive-type photosensitive resin composition is heated at the time of formation of the resist pattern, and thus the carboxy group included in the resin (A) and the polyfunctional vinyl ether monomer (B) react with each other so as to cross-link the molecular chains of the resin (A). As described previously, the molecular chains of the resin (A) are cross-linked, and thus it is possible to reduce the occurrence of a crack when the positive-type photosensitive resin composition is used to form the resist pattern and it is also possible to form the resist pattern whose shape is unlikely to be changed even when the resist pattern makes contact with the plating liquid under plating conditions.

The cross-linking reaction described above is facilitated by the compound (D) which will be described later. Hence, even when the positive-type photosensitive resin composition includes the resin (A) and the polyfunctional vinyl ether monomer (B), in the positive-type photosensitive resin composition, thickening and gelling are unlikely to occur at the time of storage at room temperature, with the result that the positive-type photosensitive resin composition is stable.

The polyfunctional vinyl ether monomer (B) is not particularly limited as long as the polyfunctional vinyl ether monomer (B) is an organic compound which includes two or more vinyloxy groups within one molecule. A divalent or polyvalent organic group that is a mother nucleus to which the vinyloxy group is bonded may be a hydrocarbon group or an organic group including a hetero atom. Examples of the hetero atom include O, S, N, P, halogen atoms and the like.

Since the divalent or higher organic group that is the mother nucleus to which the vinyloxy group is bonded in the polyfunctional vinyl ether monomer (B) is chemically stable and is satisfactory in solubility in the positive-type photosensitive resin composition, it is preferably a hydrocarbon group. The hydrocarbon group may be an aliphatic hydrocarbon group, an aromatic hydrocarbon group or a combination of an aliphatic hydrocarbon group and an aromatic hydrocarbon group, and an aliphatic hydrocarbon group is preferable.

When the divalent or higher organic group that is the mother nucleus to which the vinyloxy group is bonded in the polyfunctional vinyl ether monomer (B) is a hydrocarbon group, the number of carbon atoms in the hydrocarbon group is not particularly limited as long as the object of the present invention is not disturbed.

For example, the number of carbon atoms in the hydrocarbon group is preferably 1 or more and 40 or less, is more preferably 2 or more and 20 or less and is further preferably 2 or more and 10 or less.

The number of vinyloxy groups included in the polyfunctional vinyl ether monomer (B) is not particularly limited. The number of vinyloxy groups in one molecule is preferably 2 or more and 6 or less, is more preferably 2 or more and 4 or less and is particularly preferably 2 or 3.

Specific examples of the polyfunctional vinyl ether monomer (B) include: chain aliphatic divinyl ethers such as ethylene glycol divinyl ether, diethylene glycol divinyl ether, triethylene glycol divinyl ether, polyethylene glycol divinyl ether, propylene glycol divinyl ether, dipropylene glycol divinyl ether, tripropylene glycol divinyl ether, polypropylene glycol divinyl ether, 1,3-propanediol divinyl ether, 1,4-butanediol divinyl ether 1,5-pentanediol divinyl ether, 1,6-hexanediol divinyl ether, 1,8-octanediol divinyl ether, 1,10-decanediol divinyl ether, neopentyl glycol divinyl ether, trimethylolpropane divinyl ether and pentaerythritol divinyl ether; cycloaliphatic divinyl ethers such as 1,4-cyclohexanediol divinyl ether, 1,4-cyclohexane dimethanol divinyl ether and 2-vinyloxy-5-(vinyloxymethyl)-7-oxabicyclo [2.2.1] heptane; aromatic divinyl ethers such as 1,4-divinyloxybenzene, 1,3-divinyloxybenzene, 1,2-divinyloxybenzene, 1,4-divinyloxynaphthalene, 1,3-divinyloxynaphthalene, 1,2-divinyloxynaphthalene, 1,5-divinyloxynaphthalene, 1,6-divinyloxynaphthalene, 1,7-divinyloxynaphthalene, 1,8-divinyloxynaphthalene, 2,3-divinyloxynaphthalene, 2,6-divinyloxynaphthalene, 2,7-divinyloxynaphthalene, 4,4′-divinyloxybiphenyl, 3,3′-divinyloxybiphenyl, 2,2′-divinyloxybiphenyl, 3,4′-divinyloxybiphenyl, 2,3′-divinyloxybiphenyl, 2,4′-divinyloxybiphenyl, bisphenol A divinyl ether, 1,4-benzene dimethanol divinyl ether, 1,3-benzene dimethanol divinyl ether, 1,2-benzene dimethanol divinyl ether and naphthalene-1,4-bismehanol divinyl ether; and trivalent or higher polyvalent vinyl ethers such as trimethylolpropane trivinyl ether, pentaerythritol tetravinyl ether, sorbitol tetravinyl ether, sorbitol pentavinyl ether, dipentaerythritol pentavinyl ether and dipentaerythritol hexavinyl ether.

The content of the polyfunctional vinyl ether monomer (B) in the positive-type photosensitive resin composition is not particularly limited as long as the object of the present invention is not disturbed. Since it is particularly easy to reduce the occurrence of a crack when the resist pattern is formed and it is particularly easy to form the resist pattern whose shape is unlikely to be changed even when the resist pattern makes contact with the plating liquid under plating conditions, the content of the polyfunctional vinyl ether monomer (B) in the positive-type photosensitive resin composition is preferably 0.5 parts by mass or more and 50 parts by mass or less and is more preferably 1 part by mass or more and 30 parts by mass or less with respect to the 100 parts by mass of the resin (A).

### <Acid Generator (C) Generating Acid by Application of Active Ray or Radiation

The acid generator (C) is a compound which generates an acid by application of an active ray or radiation, and is not particularly limited as long as it is a compound which directly or indirectly generates an acid by light. As the acid generator (C), any one of the acid generators of first to fifth aspects which will be described below is preferable. Preferred aspects of the acid generator (C) suitably used in the photosensitive resin composition will be described below as the first to fifth aspects.

As the first aspect of the acid generator (C), a compound represented by formula (c1) below is mentioned

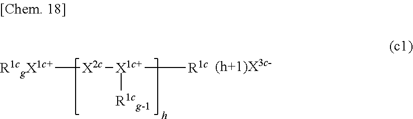

In formula (c1) described above, X^{1c} represents a sulfur atom or iodine atom having a valence of g, and g represents 1 or 2. h represents the number of repeating units in the structure within parentheses, and is an integer of 0 or more. R^{1c} represents an organic group that is bonded to X^{1c}, and represents an aryl group having 6 or more and 30 or less carbon atoms, a heterocyclic group having 4 or more and 30 or less carbon atoms, an alkyl group having 1 or more and 30 or less carbon atoms, an alkenyl group having 2 or more and 30 or less carbon atoms or an alkynyl group having 2 or more and 30 or less carbon atoms; and Rio may be substituted with at least one selected from the group consisting of an alkyl group, a hydroxyl group, an alkoxy group, an alkylcarbonyl group, an arylcarbonyl group, an alkoxycarbonyl group, an aryloxycarbonyl group, an arylthiocarbonyl group, an acyloxy group, an arylthio group, an alkylthio group, an aryl group, a heterocyclic group, an aryloxy group, an alkylsulfinyl group, an arylsulfinyl group, an alkylsulfonyl group, an arylsulfonyl group, an alkyleneoxy group, an amino group, a cyano group, a nitro group and halogen atoms. The number of R^{1c}s is g+h(g−1)+1, and the R^{1a}s may be the same as or different from each other. Furthermore, two or more R^{1c}s may be bonded to each other directly or via —O—, —S—, —SO—, —SO₂—, —NH—, —NR^{2a}—, —CO—, —COO—, —CONH—, an alkylene group having 1 or more and 3 or less carbon atoms or a phenylene group, and may form a ring structure including X^{1c}. R^{2a} represents an alkyl group having 1 or more and 5 or less carbon atoms or an aryl group having 6 or more and 10 or less carbon atoms.

X^{2c} represents a structure represented by formula (c2) below.

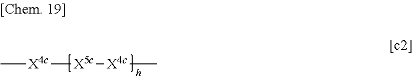

In formula (c2) described above, X^{4c} represents an alkylene group having 1 or more and 8 or less carbon atoms, an arylene group having 6 or more and 20 or less carbon atoms or a divalent group of a heterocyclic compound having 8 or more and 20 or less carbon atoms; and X^{4c} may be substituted with at least one selected from the group consisting of an alkyl group having 1 or more and 8 or less carbon atoms, an alkoxy group having 1 or more and 8 or less carbon atoms, an aryl group having 6 or more and 10 or less carbon atoms, a hydroxyl group, a cyano group, a nitro group, and halogen atoms. X^{5c} represents —O—, —S—, —SO—, —SO₂—, —NH—, —NR^{2c}—, —CO—, —COO—, —CONH—, an alkylene group having 1 or more and 3 or less carbon atoms or a phenylene group.

h represents the number of repeating units of the structure in parentheses, and is an integer of 0 or more.
(h+1) X^{4c}s and (h) X^{5c}s may be identical to or different from each other. R^{2a} has the same definition as described above.

X^{3c-} represents a counterion of an onium, and examples thereof include a fluorinated alkylfluorophosphoric acid anion represented by formula (c17) below or a borate anion represented by formula (c18) below.

[Chem. 20]

[(R^{3c})PF₆₋ⱼ]⁻ (c17)

In formula (c17) described above, R^{3c} represents an alkyl group having 80% or more of the hydrogen atoms substituted with fluorine atoms. j represents the number thereof and is an integer of 1 or more and 5 or less. j R^{3c}s may be identical to or different from each other.

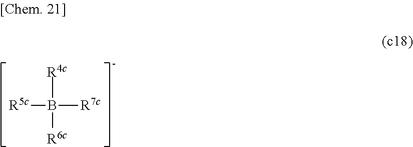

In formula (c18) described above, R^{4a} to R^{7c} each independently represent a fluorine atom or a phenyl group, and part or all of the hydrogen atoms of the phenyl group may be substituted with at least one type selected from the group consisting of a fluorine atom and a trifluoromethyl group.

Examples of the onium ion in the compound represented by formula (c1) described above include triphenylsulfonium, tri-p-tolylsulfonium, 4-(phenylthio)phenyldiphenylsulfonium, bis[4-(diphenylsulfonio)phenyl] sulfide, bis[4-{bis[4-(2-hydroxyethoxy)phenyl]sulfonio}phenyl] sulfide, bis{4-[bis(4-fluorophenyl)sulfonio]phenyl} sulfide, 4-(4-benzoyl-2-chlorophenylthio)phenylbis(4-fluorophenyl)sulfonium, 7-isopropyl-9-oxo-10-thia-9,10-dihydroanthran-2-yldi-p-tolylsulfonium, 7-isopropyl-9-oxo-10-thia-9,10-dihydroanthracen-2-yldiphenylsulfonium, 2-[(diphenyl)sulfonio]thioxanthone, 4-[4-(4-tert-butylbenzoyl)phenylthio]phenyldi-p-tolylsulfonium, 4-(4-benzoylphenylthio)phenyldiphenylsulfonium, diphenylphenacylsulfonium, 2-naphthylmethyl(1-ethoxycarbonyl)ethylsulfonium, phenyl[4-(4-biphenylthio)phenyl]-4-biphenylsulfonium, phenyl[4-(4-biphenylthio)phenyl]-3-biphenylsulfonium, [4-(4-acetophenylthio)phenyl]diphenylsulfonium, octadecylmethylphenacylsulfonium, diphenyliodonium, di-p-tolyliodonium, bis(4-dodecylphenyl)iodonium, bis(4-methoxyphenyl)iodonium, (4-octyloxyphenyl)phenyliodonium, bis(4-decyloxy)phenyliodonium, 4-(2-hydroxytetradecyloxy)phenylphenyliodonium, 4-isopropylphenyl(p-tolyl)iodonium, 4-isobutylphenyl(p-tolyl)iodonium, and the like.

Among the onium ions in the compound represented by formula (c1) described above, as a preferred onium ion, a sulfonium ion represented by formula (c19) below is mentioned.

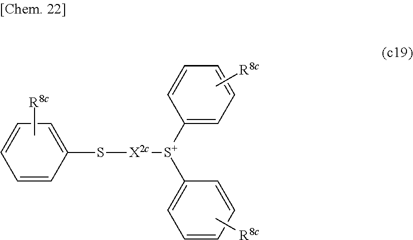

In formula (c19) described above, R^{8c}s each independently represents a group selected from the group consisting of a hydrogen atom, alkyl, hydroxyl, alkoxy, alkylcarbonyl, alkylcarbonyloxy, alkyloxycarbonyl, a halogen atom, an aryl which may include a substituent and arylcarbonyl. X^{2c} has the same meaning as X²c in formula (c1) described above.

Specific examples of the sulfonium ion represented by formula (c19) described above include 4-(phenylthio)phenyldiphenylsulfonium, 4-(4-benzoyl-2-chlorophenylthio)phenylbis(4-fluorophenyl)sulfonium, 4-(4-benzoylphenylthio)phenyldiphenylsulfonium, phenyl[4-(4-biphenylthio)phenyl]-4-biphenylsulfonium, phenyl[4-(4-biphenylthio)phenyl]-3-biphenylsulfonium, [4-(4-acetophenylthio)phenyl]diphenylsulfonium, diphenyl[4-(p-terphenylthio)phenyl]diphenylsulfonium and the like.

In the fluorinated alkylfluorophosphoric acid anion represented by formula (c17) described above, R^{3c} represents an alkyl group substituted with a fluorine atom, a preferred number of carbon atoms is 1 or more and 8 or less and a more preferred number of carbon atoms is 1 or more and 4 or less. Specific examples of the alkyl group include: linear alkyl groups such as methyl, ethyl, propyl, butyl, pentyl and octyl; branched alkyl groups such as isopropyl, isobutyl, sec-butyl and tert-butyl; and furthermore, cycloalkyl groups such as cyclopropyl, cyclobutyl, cyclopentyl and cyclohexyl, and the proportion of hydrogen atoms substituted with fluorine atoms in the alkyl groups is normally 80% or more, is preferably 90% or more and is more preferably 100%. When the substitution rate of fluorine atoms is less than 80%, the acid strength of the onium fluorinated alkylfluorophosphate represented by formula (c1) described above is lowered.

A particularly preferred example of R^{3c} is a linear or branched perfluoroalkyl group having 1 or more and 4 or less carbon atoms and a substitution ratio of fluorine atoms of 100%, and specific examples thereof include CF₃, CF₃CF₂, (CF₃)₂CF, CF₃CF₂CF₂, CF₃CF₂CF₂CF₂, (CF₃)₂CFCF₂, CF₃CF₂(CF₃)CF, and (CF₃)₃C. j which is the number of R^{3c}s represents an integer of 1 or more and 5 or less, preferably represents an integer of 2 or more and 4 or less and particularly represents 2 or 3.

Preferred specific examples of the fluorinated alkylfluorophosphoric acid anion include [(CF₃CF₂)₂PF₄]⁻, [(CF₃CF₂)₃PF₃]⁻, [((CF₃)₂CF)₂PF₄]⁻, [((CF₃)₂CF)₃PF₃]⁻, [(CF₃CF₂CF₂)₂PF₄]⁻, [(CF₃CF₂CF₂)₃PF₃]⁻, [((CF₃)₂CFCF₂)₂PF₄]⁻, [((CF₃)₂CFCF₂)₃PF₃]⁻, [(CF₃CF₂CF₂CF₂)₂PF₄]⁻ and [(CF₃CF₂CF₂)₃PF₃]⁻, and among them, [(CF₃CF₂)₃PF₃]⁻, [(CF₃CF₂CF₂)₃PF₃]⁻, [((CF₃)₂CF)₃PF₃]⁻, [((CF₃)₂CF)₂PF₄]⁻, [((CF₃)₂CFCF₂)₃PF₃]⁻, and [((CF₃)₂CFCF₂)₂PF₄] are particularly preferable.

Preferred specific examples of the borate anion represented by formula (c18) described above include tetrakis(pentafluorophenyl)borate ([B(C₆F₅)₄]⁻), tetrakis[(trifluoromethyl)phenyl]borate ([B(C₆H₄CF₃)₄]⁻), difluorobis(pentafluorophenyl)borate ([(C₆F₅)₂BF₂]⁻), trifluoro(pentafluorophenyl)borate ([(C₆F₅)BF₃]⁻), tetrakis(difluorophenyl)borate ([B(C₆H₃F₂)₄]⁻) and the like. Among these, tetrakis(pentafluorophenyl)borate ([B(C₆F₅)₄]⁻) is particularly preferable.

Examples of the second aspect of the acid generator (C) include: halogen-containing triazine compounds such as 2,4-bis(trichloromethyl)-6-piperonyl-1,3,5-triazine, 2,4-bis(trichloromethyl)-6-[2-(2-furyl)ethenyl]-s-triazine, 2,4-bis(trichloromethyl)-6-[2-(5-methyl-2-furyl)ethenyl]-s-triazine, 2,4-bis(trichloromethyl)-6-[2-(5-ethyl-2-furyl)ethenyl]-s-triazine, 2,4-bis(trichloromethyl)-6-[2-(5-propyl-2-furyl)ethenyl]-s-triazine, 2,4-bis(trichloromethyl)-6-[2-(3,5-dimethoxyphenyl)ethenyl]-s-triazine, 2,4-bis(trichloromethyl)-6-[2-(3,5-diethoxyphenyl)ethenyl]-s-triazine, 2,4-bis(trichloromethyl)-6-[2-(3,5-dipropoxyphenyl)ethenyl]-s-triazine, 2,4-bis(trichloromethyl)-6-[2-(3-methoxy-5-ethoxyphenyl)ethenyl]-s-triazine, 2,4-bis(trichloromethyl)-6-[2-(3-methoxy-5-propoxyphenyl)ethenyl]-s-triazine, 2,4-bis(trichloromethyl)-6-[2-(3,4-methylenedioxyphenyl)ethenyl]-s-triazine, 2,4-bis(trichloromethyl)-6-(3,4-methylenedioxyphenyl)-s-triazine, 2,4-bis-trichloromethyl-6-(3-bromo-4-methoxy)phenyl-s-triazine, 2,4-bis-trichloromethyl-6-(2-bromo-4-methoxy)phenyl-s-triazine, 2,4-bis-trichloromethyl-6-(2-bromo-4-methoxy)styrylphenyl-s-triazine, 2,4-bis-trichloromethyl-6-(3-bromo-4-methoxy)styrylphenyl-s-triazine, 2-(4-methoxyphenyl)-4,6-bis(trichloromethyl)-1,3,5-triazine, 2-(4-methoxynaphthyl)-4,6-bis(trichloromethyl)-1,3,5-triazine, 2-[2-(2-furyl)ethenyl]-4,6-bis(trichloromethyl)-1,3,5-triazine, 2-[2-(5-methyl-2-furyl)ethenyl]-4,6-bis(trichloromethyl)-1,3,5-triazine, 2-[2-(3,5-dimethoxyphenyl)ethenyl]-4,6-bis(trichloromethyl)-1,3,5-triazine, 2-[2-(3,4-dimethoxyphenyl)ethenyl]-4,6-bis(trichloromethyl)-1,3,5-triazine, 2-(3,4-methylenedioxyphenyl)-4,6-bis(trichloromethyl)-1,3,5-triazine, tris(1,3-dibromopropyl)-1,3,5-triazine, and tris(2,3-dibromopropyl)-1,3,5-triazine; and halogen-containing triazine compounds represented by formula (c3) below such as tris(2,3-dibromopropyl)isocyanurate.

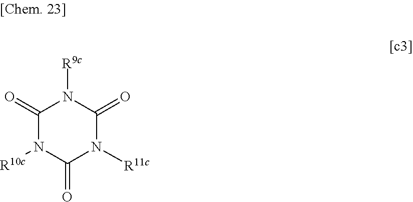

In formula (c3) described above, R^{9c}, R^{10c} and R^{11c} each independently represent a halogenated alkyl group.

Examples of the third aspect of the acid generator (C) include α-(p-toluenesulfonyloxyimino)-phenylacetonitrile, a-(benzenesulfonyloxyimino)-2,4-dichlorophenylacetonitrile, a-(benzenesulfonyloxyimino)-2,6-dichlorophenylacetonitrile, a-(2-chlorobenzenesulfonyloxyimino)-4-methoxyphenylacetonitrile, and α-(ethylsulfonyloxyimino)-1-cyclopentenylacetonitrile and compounds represented by formula (c4) below containing an oximesulfonate group.

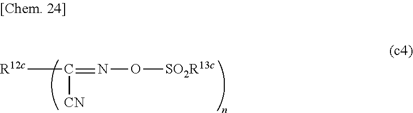

In formula (c4) described above, R^{12c} represents a monovalent, divalent or trivalent organic group, R^{13c} represents a substituted or unsubstituted saturated hydrocarbon group, an unsaturated hydrocarbon group or an aromatic compound group, and n represents the number of repeating units of the structure in the parentheses.

In formula (c4) described above, the aromatic compound group refers to a group of compounds having physical and chemical properties characteristic of aromatic compounds, and examples thereof include aryl groups such as a phenyl group and a naphthyl group and heteroaryl groups such as a furyl group and a thienyl group. These groups may have one or more appropriate substituents such as a halogen atom, an alkyl group, an alkoxy group and a nitro group on the rings. Furthermore, R^{13c} is particularly preferably an alkyl group having 1 or more and 6 or less carbon atoms, and examples thereof include a methyl group, an ethyl group, a propyl group and a butyl group. In particular, compounds in which R^{12c} is an aromatic group and in which and R^{13c} is an alkyl group having 1 or more and 4 or less carbon atoms are preferable.

Examples of the acid generator represented by formula (c4) described above include compounds in which R^{12c} is any one of a phenyl group, a methylphenyl group and a methoxyphenyl group, and in which R^{13c} is a methyl group when n=1, and specific examples thereof include a-(methylsulfonyloxyimino)-1-phenylacetonitrile, a-(methylsulfonyloxyimino)-1-(p-methylphenyl)acetonitrile, a-(methylsulfonyloxyimino)-1-(p-methoxyphenyl)acetonitrile, [2-(propylsulfonyloxyimino)-2,3-dihydroxythiophene-3-ylidene](o-tolyl)acetonitrile and the like. Specifically, when n=2, the acid generator represented by formula (c4) described above is an acid generator represented by the following formulae.

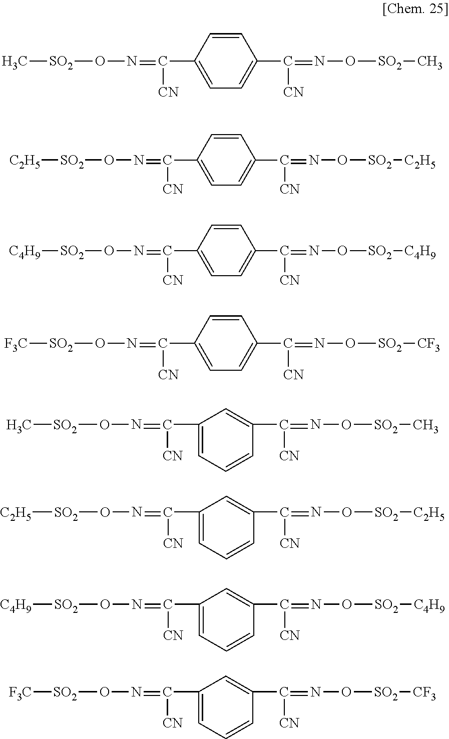

Examples of the fourth aspect of the acid generator (C) include onium salts that have a naphthalene ring at their cation moiety. The expression “have a naphthalene ring” indicates having a structure derived from naphthalene and also indicates at least two ring structures and their aromatic properties are maintained. The naphthalene ring may have a substituent such as a linear or branched alkyl group having 1 or more and 6 or less carbon atoms, a hydroxyl group or a linear or branched alkoxy group having 1 or more and 6 or less carbon atoms. The structure derived from the naphthalene ring, which may be a monovalent group (one free valence) or a divalent group (two free valences), is preferably a monovalent group (here, the number of free valences is counted except the part bonded to the substituent described above). The number of naphthalene rings is preferably 1 or more and 3 or less.

The cation moiety of the onium salt having a naphthalene ring at the cation moiety preferably has a structure represented by formula (c5) below.

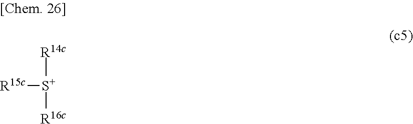

In formula (c5) described above, at least one of R^{14c}, R^{15c} and R^{16c} represents a group represented by formula (c6) below, and the remaining ones represent a linear or branched alkyl group having 1 or more and 6 or less carbon atoms, a phenyl group which may have a substituent, a hydroxyl group or a linear or branched alkoxy group having 1 or more and 6 or less carbon atoms. Alternatively, one of R^{14c}, R^{15c} and R^{16c} may be a group represented by formula (c6) below, the remaining two each may be independently a linear or branched alkylene group having 1 or more and 6 or less carbon atoms and these terminals may be bonded together to form a ring structure.

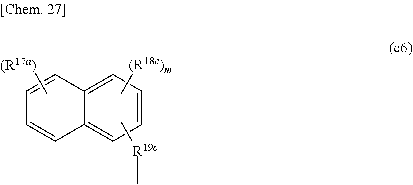

In formula (c6) described above, R^{17e} and R^{18c} each independently represent a hydroxyl group, a linear or branched alkoxy group having 1 or more and 6 or less carbon atoms or a linear or branched alkyl group having 1 or more and 6 or less carbon atoms, and R^{19c} represents a linear or branched alkylene group having 1 or more and 6 or less carbon atoms that may have a single bond or a substituent. 1 and m each independently represent an integer of 0 or more and 2 or less, and 1+m is 3 or less. Here, when a plurality of R^{17c} are present, they may be the same as or different from each other. Furthermore, when a plurality of R^{18c} are present, they may be the same as or different from each other.

Preferably, among R^{14c}, R^{15c} and R^{16c} described above, the number of groups represented by formula (c6) described above is one in terms of the stability of the compound, the remaining ones are linear or branched alkylene groups having 1 or more and 6 or less carbon atoms and these terminals may be bonded together to form a ring. In this case, the two alkylene groups described above form 3 to 9 membered rings including a sulfur atom. Preferably, the number of atoms which form the ring (including a sulfur atom) is 5 or more and 6 or less.

Examples of the substituent, which the alkylene group may have, include an oxygen atom (in this case, a carbonyl group is formed together with a carbon atom that constitutes the alkylene group), a hydroxyl group or the like.

Alternatively, examples of the substituent, which the phenyl group may include, include a linear or branched alkoxy group having 1 or more and 6 or less carbon atoms, a linear or branched alkyl group having 1 or more and 6 or less carbon atoms and the like.

Examples of suitable cations serving as these cation moieties include cations represented by formulae (c7) and (c8) below and the like, and in particular, the structure represented by formula (c8) below is preferable.

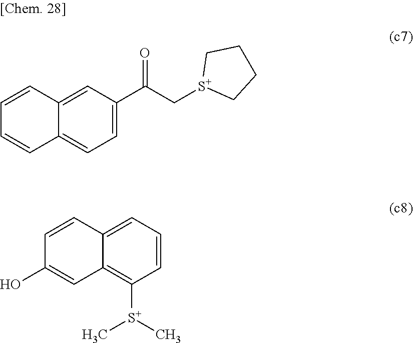 [SMILES: O=C(C[S+]1CCCC1)c1ccc2ccccc2c1 ; C[S+](C)c1cccc2ccc(O)cc12]

The cation moieties, which may be of an iodonium salt or a sulfonium salt, are desirably of a sulfonium salt in terms of acid-producing efficiency.

Hence, as a preferable anion serving as the anion moiety of the onium salt having a naphthalene ring at the cation moiety, an anion capable of forming a sulfonium salt is preferable.

The anion moiety of the acid generator as described above is a fluoroalkylsulfonic acid ion or an aryl sulfonic acid ion in which part or all of hydrogen atoms are fluorinated.

The alkyl group of the fluoroalkylsulfonic acid ion may be a linear, branched or cyclic group having 1 or more and 20 or less carbon atoms, and preferably, the number of carbon atoms is 1 or more and 10 or less in terms of bulkiness and diffusion distance of the generated acid. In particular, branched and cyclic alkyl groups are preferable because they have a shorter diffusion length. Methyl, ethyl, propyl, butyl, octyl groups and the like are also preferable because they can be inexpensively synthesized.

The aryl group of the aryl sulfonic acid ion may be an aryl group having 6 or more and 20 or less carbon atoms, and examples thereof include a phenyl group and a naphthyl group which do not need to be substituted with an alkyl group or a halogen atom. In particular, an aryl group having 6 or more and 10 or less carbon atoms is preferable because they can be inexpensively synthesized. Specific examples of the preferable aryl group include phenyl, toluenesulfonyl, ethylphenyl, naphthyl and methylnaphthyl groups and the like.

When hydrogen atoms in the fluoroalkylsulfonic acid ion or the aryl sulfonic acid ion are partially or entirely substituted with a fluorine atom, the fluorination rate is preferably 10% or more and 100% or less, and more preferably 50% or more and 100% or less. It is particularly preferable that all hydrogen atoms are each substituted with a fluorine atom in terms of higher acid strength. Specific examples thereof include trifluoromethane sulfonate, perfluorobutane sulfonate, perfluorooctane sulfonate, perfluorobenzene sulfonate, and the like.

Among these, as the preferable anion moiety, an anion moiety represented by formula (c9) below is mentioned.

[Chem. 29]

R^{20c}SO₃⁻ (c9)

In formula (c9) described above, R^{20c} is a group represented by formulae (c10), (c11) and (c12) below.

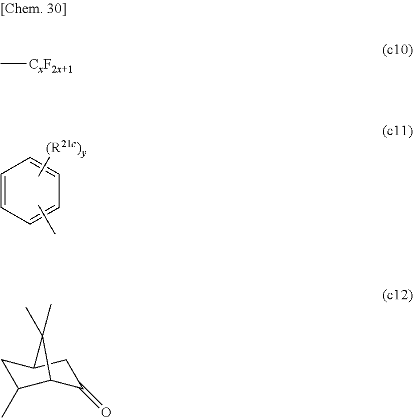

In formula (c10) described above, x represents an integer of 1 or more and 4 or less. In formula (c11) described above, R^{21c} represents a hydrogen atom, a hydroxyl group, a linear or branched alkyl group having 1 or more and 6 or less carbon atoms or a linear or branched alkoxy group having 1 or more and 6 or less carbon atoms, and y represents an integer of 1 or more and 3 or less. Among these, trifluoromethane sulfonate and perfluorobutane sulfonate are preferable in terms of safety.

A nitrogen-containing anion moiety represented by formulae (c13) and (c14) below may be also be used as the anion moiety.

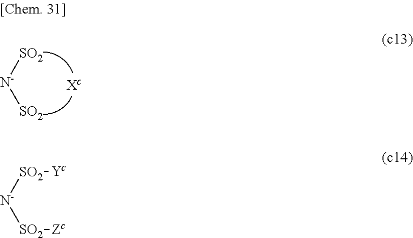

In formulae (c13) and (c14) described above, X^{c} represents a linear or branched alkylene group in which at least one hydrogen atom is substituted with a fluorine atom, and the number of carbon atoms of the alkylene group is 2 or more and 6 or less, is preferably 3 or more and 5 or less and is most preferably 3. Y^{c} and Z^{c} each independently represent a linear or branched alkyl group in which at least one hydrogen atom is substituted with a fluorine atom, and the number of carbon atoms of the alkyl group is 1 or more and 10 or less, is preferably 1 or more and 7 or less and is more preferably 1 or more and 3 or less.

A smaller number of carbon atoms in the alkylene group of X^{c} or in the alkyl group of Y^{c} or Z^{c} is preferable because the solubility in an organic solvent is satisfactory.

A larger number of hydrogen atoms each substituted with a fluorine atom in the alkylene group of X^{c} or in the alkyl group of Y^{c} or Z^{c} is preferable because the acid strength is increased. The percentage of fluorine atoms in the alkylene group or the alkyl group, that is, the fluorination rate is preferably 70% or more and 100% or less and is more preferably 90% or more and 100% or less, and a perfluoroalkylene group or a perfluoroalkyl group is most preferable in which all of the hydrogen atoms are substituted with fluorine atoms.

Examples of preferable compounds serving as onium salts having a naphthalene ring at their cation moieties include compounds represented by formulae (c15) and (c16) below.

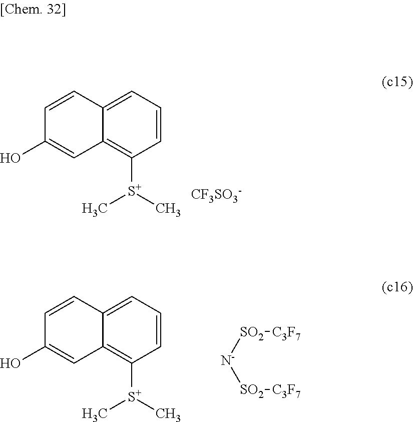

Examples of the fifth aspect of the acid generator (C) include bissulfonyldiazomethanes such as bis(p-toluenesulfonyl)diazomethane, bis(1,1-dimethyl ethylsulfonyl)diazomethane, bis(cyclohexylsulfonyl)diazomethane and bis(2,4-dimethylphenylsulfonyl)diazomethane; nitrobenzyl derivatives such as 2-nitrobenzyl p-toluenesulfonate, 2,6-dinitrobenzyl p-toluenesulfonate, nitrobenzyl tosylate, dinitrobenzyl tosylate, nitrobenzyl sulfonate, nitrobenzyl carbonate and dinitrobenzyl carbonate; sulfonates such as pyrogalloltrimesylate, pyrogalloltritosylate, benzyltosylate, benzylsulfonate, N-(methylsulfonyloxy)succinimide, N-(trichloromethylsulfonyloxy)succinimide, N-(phenylsulfonyloxy)maleimide, and N-(methylsulfonyloxy)phthalimide; trifluoromethane sulfonates such as N-(trifluoromethylsulfonyloxy)phthalimide, N-(trifluoromethylsulfonyloxy)-1,8-naphthalimide, N-(trifluoromethylsulfonyloxy)-4-butyl-1,8-naphthalimide and N-(trifluoromethylsulfonyloxy)-4-butylthio-1,8-naphthalimide; onium salts such as diphenyliodonium hexafluorophosphate, (4-methoxyphenyl)phenyliodonium trifluoromethanesulfonate, bis(p-tert-butylphenyl)iodonium trifluoromethanesulfonate, triphenylsulfonium hexafluorophosphate, (4-methoxyphenyl)diphenylsulfonium trifluoromethanesulfonate, and (p-tert-butylphenyl)diphenylsulfonium trifluoromethanesulfonate; benzointosylates such as benzointosylate and α-methylbenzointosylate; other diphenyliodonium salts, triphenylsulfonium salts, phenyldiazonium salts, benzylcarbonates; and the like.

The acid generators (C) may be used alone or two or more types may be combined so as to be used. The content of the acid generator (C) is preferably 0.1% by mass or more and 10% by mass or less and is more preferably 0.3% by mass or more and 5% by mass or less with respect to the total solid mass content of the positive-type photosensitive resin composition. The amount of acid generator (C) used is set within the range described above, and thus it is easy to prepare the photosensitive resin composition which is satisfactory in sensitivity, which is a uniform solution and whose storage stability is excellent.

<Compound (D) Including Phenolic Hydroxyl Group and/or Mercapto Group>

The photosensitive resin composition contains the phenolic hydroxyl group and/or the mercapto group described below. By the catalytic effect of the compound (D), the cross-linking between the resin (A) and the polyfunctional vinyl ether monomer (B) is facilitated.

A compound (D1) which includes the phenolic hydroxyl group and a compound (D2) which includes the carboxy group will be described below. In the present specification, for convenience, the compound which includes the phenolic hydroxyl group and the mercapto group is described as the compound (D2) including the mercapto group.

### [Compound (D1) Including Phenolic Hydroxyl Group]

The compound (D1) including the phenolic hydroxyl group is a compound which includes one or more phenolic hydroxyl groups. Examples of the compound (D1) including the phenolic hydroxyl group include phenolic hydroxyl group-containing resins such as a novolak resin and a polyhydroxystyrene resin and aromatic compounds (hereinafter also simply referred to as “phenols”) which do not apply to the phenolic hydroxyl group-containing resin and which include a phenolic hydroxyl group. The phenols, the novolak resin and the polyhydroxystyrene resin will be described below.

### [Phenols]

The phenols are not particularly limited as long as they are compounds which include a phenolic hydroxyl group. The phenols may include an aliphatic group as long as they are compounds which include a phenolic hydroxyl group. The number of phenolic hydroxyl groups included in one molecule of the phenols is not particularly limited. The number of phenolic hydroxyl groups included in one molecule of the phenols is, for example, 1 or more and 6 or less and is preferably 1 or more and 4 or less.

Preferred specific examples of the phenols include phenol, o-cresol, m-cresol, p-cresol, o-ethylphenol, m-ethylphenol, p-ethylphenol, o-butylphenol, m-butylphenol, p-butylphenol, 2,3-xylenol, 2,4-xylenol, 2,5-xylenol, 2,6-xylenol, 3,4-xylenol, 3,5-xylenol, 2,3,5-trimethyl phenol, 3,4,5-trimethyl phenol, p-phenylphenol, resorcinol, hydroquinone, hydroquinone monomethyl ether, pyrogallol, phloroglycinol, 4,4′-dihydroxybiphenyl, bisphenol A, gallic acid, gallic acid esters such as gallic acid methyl and gallic acid ethyl, a-naphthol, β-naphthol and the like.

### [Novolak Resin]

The novolak resin is obtained by subjecting, for example, the phenols described above and aldehydes to addition condensation under an acid catalyst.

Examples of the aldehydes include formaldehyde, furfural, benzaldehyde, nitrobenzaldehyde, acetaldehyde, and the like.

Although the catalyst used in the addition condensation reaction is not particularly limited, for example, for an acid catalyst, hydrochloric acid, nitric acid, sulfuric acid, formic acid, oxalic acid, acetic acid and the like are used.

### [Polyhydroxystyrene Resin]

The polyhydroxystyrene resin is a copolymer of a homopolymer of a hydroxystyrene compound or a hydroxystyrene compound and another monomer. Specific examples of the hydroxystyrene compound include p-hydroxystyrene, m-hydroxystyrene, o-hydroxystyrene, α-methylhydroxystyrene, a-ethylhydroxystyrene and the like.

As another monomer which can copolymerize the hydroxystyrene compound, a styrene compound is preferable. Specific examples of the styrene compound include styrene, chlorostyrene, chloromethylstyrene, vinyltoluene and a-methylstyrene.

### [Compound (D2) Including Mercapto Group]

Examples of the compound (D2) including the mercapto group include: thiols such as 1-butanethiol, 2-butanethiol, t-butylmercaptan, 2-methyl-1-propanethiol, 2-methyl-2-propanethiol, 1-octanethiol, 1-decanethiol, 1-dodecanethiol, 1-tetradecanethiol, n-laurylmercaptan, cyclohexanethiol, 1-mercaptoethanol, 2-mercaptoethanol, 3-mercapto-1-propanol, 3-mercapto-1,2-propanediol, triethylene glycol dimercaptan, p-mercaptophenyl methanol, 2-(p-mercaptophenyl) ethanol, p-(mercaptomethyl) phenylmethanol, 2-(p-(mercaptomethyl) phenyl) ethanol, p-mercaptophenol, p-(mercaptomethyl) phenol, p-(1-mercaptoethyl) phenol and p-(2-mercaptoethyl) phenol; thiolic acids such as 3-mercaptopropionic acid, thioglycolic acid and thiomalic acid; thiolic acid esters such as methyl thioglycolate, ethyl thioglycolate, n-butyl thioglycolate, methyl 2-mercaptopropionate, ethyl 2-mercaptopropionate, methyl 3-mercaptopropionate, ethyl 3-mercaptopropionate, 2-ethylhexyl 3-mercaptopropionate and methoxybutyl 3-mercaptopropionate; mercaptoimidazoles such as 2-mercaptoimidazole, 2-mercapto-1-methylimidazole, 2-mercaptoimidazole-1-ol and 2-mercaptobenzimidazole; mercaptotriazoles such as 3-mercapto-1,2,4-triazole, 3-mercapto-5-methyl-1,2,4-triazole and 3-mercapto-1,2,4-triazol-5-ol; mercaptopyrimidines such as 2,4-dimercaptopyrimidine, 2-mercaptopyrimidine-4-ol and 2-mercaptopyrimidine-4,6-diol; mercaptotriazines such as 2,4-dimercapto-1,3,5-triazine, 2,4,6-trimercapto-1,3,5-triazine, 2,4-dimercapto-1,3,5-triazine-6-ol and 2, -mercapto-1,3,5-triazine-4,6-diol.

The compound (D) may be used alone or two or more types may be combined so as to be used. Since the cross-linking reaction of the resin (A) and the polyfunctional vinyl ether monomer (B) is satisfactorily facilitated, the amount of compound (D) including the phenolic hydroxyl group and/or the mercapto group used is 10 ppm by mass or more (0.00001% by mass or more) and 20% by mass or less, is preferably 100 ppm by mass or more (0.0001% by mass or more) and 15% by mass or less and is particularly preferably 200 ppm by mass or more (0.0002% by mass or more) and 10% by mass or less with respect to the mass of the resin (A) described above.

### <Acid Diffusion Control Agent (E)>

In order to improve the shape of a resist pattern used as a template, the post-exposure delay stability and the like of the positive-type photosensitive resin film, it is preferable that the positive-type photosensitive resin composition further contain an acid diffusion control agent (E). The acid diffusion control agent (E) is preferably a nitrogen-containing compound (E1), and an organic carboxylic acid, an oxo acid of phosphorus or a derivative thereof (E2) may be further included as necessary.

### [Nitrogen-Containing Compound (E1)]

Examples of the nitrogen-containing compound (E1) include trimethylamine, diethylamine, triethylamine, di-n-propylamine, tri-n-propylamine, tri-n-pentylamine, tribenzylamine, diethanolamine, triethanolamine, n-hexylamine, n-heptylamine, n-octylamine, n-nonylamine, ethylenediamine, N,N,N′,N′-tetramethylethylenediamine, tetramethylenediamine, hexamethylenediamine, 4,4′-diaminodiphenylmethane, 4,4′-diaminodiphenyl ether, 4,4′-diaminobenzophenone, 4,4′-diaminodiphenylamine, formamide, N-methylformamide, N,N-dimethylformamide, acetamide, N-methylacetamide, N,N-dimethylacetamide, propionamide, benzamide, pyrrolidone, N-methylpyrrolidone, methylurea, 1,1-dimethylurea, 1,3-dimethylurea, 1,1,3,3, -tetramethylurea, 1,3-diphenylurea, imidazole, benzimidazole, 4-methylimidazole, 8-oxyquinoline, acridine, purine, pyrrolidine, piperidine, 2,4,6-tri (2-pyridyl)-S-triazine, morpholine, 4-methylmorpholine, piperazine, 1,4-dimethylpiperazine, 1,4-diazabicyclo[2.2.2]octane, pyridine, substituted pyridines such as 2,6-di-tert-butylpyridine, 2,6-diphenylpyridine and 2,4,6-triphenylpyridine and the like. As the nitrogen-containing compound (E1), hindered amine compounds can be used such as a condensate of tetrakis (1,2,2,6,6-pentamethyl-4-piperidyl) 1,2,3,4-butanetetracarboxylate, 1,2,3,4-butanetetracarboxylic acid and 1,2,2,6,6-pentamethyl-4-piperidinol and β,β,β′,β′-tetramethyl-3,9-(2,4,8,10-tetraoxaspiro [5,5] undecane)-diethanol and a polymer of dimethyl succinate and 4-hydroxy-2,2,6,6-tetramethyl-1-piperidineethanol. These may be used alone or in combinations of two or more thereof.

In general, the nitrogen-containing compound (E1) is preferably used within a range of 0 parts by mass or more and 5 parts by mass or less and is particularly preferably used within a range of 0 parts by mass or more and 3 parts by mass or less with respect to the total 100 parts by mass of the mass of the resin (A) and the mass of the polyfunctional vinyl ether monomer (B) described above.

### [Organic Carboxylic Acid or Oxo Acid of Phosphorus or Derivative Thereof (E2)]

Among the organic carboxylic acid, the oxo acid of phosphorus and the derivative thereof (E2), preferred examples of the organic carboxylic acid include malonic acid, citric acid, malic acid, succinic acid, benzoic acid, salicylic acid and the like, and salicylic acid is particularly preferable.

Examples of the oxo acid of phosphorus or derivatives thereof include phosphoric acid and derivatives such as esters thereof such as, e.g., phosphoric acid, phosphoric acid di-n-butyl ester, and phosphoric acid diphenyl ester; phosphonic acid and derivatives such as esters thereof such as, e.g., phosphonic acid, phosphonic acid dimethyl ester, phosphonic acid di-n-butyl ester, phenylphosphonic acid, phosphonic acid diphenyl ester, and phosphonic acid dibenzyl ester; and phosphinic acid and derivatives such as esters thereof such as, e.g., phosphinic acid and phenylphosphinic acid; and the like. Among these, phosphonic acid is particularly preferred. These may be used alone, or in combinations of two or more thereof.

In general, the organic carboxylic acid or the oxo acid of phosphorus or the derivative thereof (E2) is preferably used within a range of 0 parts by mass or more and 5 parts by mass or less and is particularly preferably used within a range of 0 parts by mass or more and 3 parts by mass or less with respect to the total 100 parts by mass of the mass of the resin (A) and the mass of the polyfunctional vinyl ether monomer (B) described above.

In order to form and stabilize a salt, the organic carboxylic acid or the oxo acid of phosphorous or the derivative thereof (E2) is preferably used in an amount equivalent to that of the nitrogen-containing compound (E1).

### <Organic Solvent (S)>

The positive-type photosensitive resin composition preferably contains an organic solvent (S), for example, in order to

adjust coating. The type of organic solvent (S) is not particularly limited as long as the object of the present invention is not disturbed, and the organic solvent can be appropriately selected for use from the organic solvents that have been conventionally used in positive-type photosensitive resin compositions.

Specific examples of the organic solvent (S) include ketones such as acetone, methyl ethyl ketone, cyclohexanone, methyl isoamyl ketone, and 2-heptanone; polyhydric alcohols and derivatives thereof, like monomethyl ethers, monoethyl ethers, monopropyl ethers, monobutyl ethers and monophenyl ethers, such as ethylene glycol, ethylene glycol monoacetate, diethylene glycol, diethylene glycol monoacetate, propylene glycol, propylene glycol monoacetate, dipropylene glycol and dipropylene glycol monoacetate; cyclic ethers such as dioxane; esters such as ethyl formate, methyl lactate, ethyl lactate, methyl acetate, ethyl acetate, butyl acetate, methyl pyruvate, methyl acetoacetate, ethyl acetoacetate, methyl pyruvate, ethylethoxy acetate, methyl methoxypropionate, ethyl ethoxypropionate, methyl 2-hydroxypropionate, ethyl 2-hydroxypropionate, ethyl 2-hydroxy-2-methylpropionate, methyl 2-hydroxy-3-methylbutanate, 3-methoxybutyl acetate, and 3-methyl-3-methoxybutyl acetate; aromatic hydrocarbons such as toluene and xylene; and the like. These may be used alone, or as a mixture of two or more thereof.

The content of the organic solvent (S) is not particularly limited as long as the object of the present invention is not disturbed. When the positive-type photosensitive resin composition is used such that the film thickness of a photosensitive resin layer obtained such as by a spin coat method is 10 μm or more, the organic solvent (S) is preferably used such that the solid content concentration of the positive-type photosensitive resin composition falls within a range of 20 parts by mass or more and 80% by mass or less and is more preferably used such that the solid content concentration thereof falls within a range of 30% by mass or more and 70% by mass or less.

### <Other Components>

The positive-type photosensitive resin composition may further contain a polyvinyl resin in order to enhance plasticity. Specific examples of the polyvinyl resin include polyvinyl chloride, polystyrene, polyhydroxystyrene, polyvinyl acetate, polyvinylbenzoic acid, polyvinyl methyl ether, polyvinyl ethyl ether, polyvinyl alcohol, polyvinyl pyrrolidone and copolymers thereof and the like. The polyvinyl resin is preferably polyvinyl methyl ether in terms of lower glass transition temperature.

Furthermore, the positive-type photosensitive resin composition may also contain an adhesive auxiliary agent in order to enhance the adhesiveness between a template formed with the positive-type photosensitive resin composition and a metal substrate.

The positive-type photosensitive resin composition may further contain a surfactant in order to enhance coating, defoaming, leveling and the like. As the surfactant, for example, a fluorinated surfactant and a silicone surfactant are preferably used. Specific examples of the fluorinated surfactant include commercially available fluorochemical surfactants such as BM-1000 and BM-1100 (both made by B.M-Chemie GmbH), Megafac F142D, Megafac F172, Megafac F173 and Megafac F183 (all manufactured by Dainippon Ink and Chemicals, Incorporated), Flolade FC-135, Flolade FC-170C, Flolade FC-430 and Flolade FC-431 (all manufactured by Sumitomo 3M Ltd.), Surflon S-112, Surflon S-113, Surflon S-131, Surflon S-141 and Surflon S-145 (all manufactured by Asahi Glass Co., Ltd.), SH-28PA, SH-190, SH-193, SZ-6032 and SF-8428 (all manufactured by Toray Silicone Co., Ltd.) but there is no limitation to those.

As the silicone surfactant, a non-modified silicone surfactant, a polyether modified silicone surfactant, a polyester modified silicone surfactant, an alkyl modified silicone surfactant, an aralkyl modified silicone surfactant, a reactive silicone surfactant and the like can be preferably used. As the silicone surfactant, a commercially available silicone surfactant can be used. Specific examples of the commercially available silicone surfactant include Paintad M (made by Dow Corning Toray Co., Ltd.), TOPICA K1000, TOPICA K2000 and TOPICA K5000 (all of which are made by Takachiho Sangyo Co., Ltd.), XL-121 (polyether modified silicone surfactant, made by Clariant), BYK-310 (polyester modified silicone surfactant, made by BYK-Chemie GmbH) and the like.

Additionally, in order to finely adjust the solubility in a developing solution, the positive-type photosensitive resin composition may further contain an acid, an acid anhydride, or a solvent having a high boiling point.

Specific examples of the acid and acid anhydride include monocarboxylic acids such as acetic acid, propionic acid, n-butyric acid, isobutyric acid, n-valeric acid, isovaleric acid, benzoic acid, and cinnamic acid; hydroxymonocarboxylic acids such as lactic acid, 2-hydroxybutyric acid and 3-hydroxybutyric acid; polyvalent carboxylic acids such as oxalic acid, succinic acid, glutaric acid, adipic acid, maleic acid, itaconic acid, hexahydrophthalic acid, phthalic acid, isophthalic acid, terephthalic acid, 1,2-cyclohexanedicarboxylic acid, 1,2,4-cyclohexanetricarboxylic acid, butanetetracarboxylic acid, trimellitic acid, pyromellitic acid, cyclopentanetetracarboxylic acid, butanetetracarboxylic acid, and 1,2,5,8-naphthalenetetracarboxylic acid; acid anhydrides such as itaconic anhydride, succinic anhydride, citraconic anhydride, dodecenylsuccinic anhydride, tricarbanilic anhydride, maleic anhydride, hexahydrophthalic anhydride, methyltetrahydrophthalic anhydride, Himic anhydride, 1,2,3,4-butanetetracarboxylic acid, cyclopentanetetracarboxylic dianhydride, phthalic anhydride, pyromellitic anhydride, trimellitic anhydride, benzophenonetetracarboxylic anhydride, ethylene glycol bis anhydrous trimellitate, and glycerin tris anhydrous trimellitate; and the like.

Furthermore, specific examples of the solvent having a high boiling point include N-methylformamide, N,N-dimethylformamide, N-methylformanilide, N-methylacetamide, N,N-dimethlyacetamide, N-methylpyrrolidone, dimethyl sulfoxide, benzyl ethyl ether, dihexyl ether, acetonyl acetone, isophorone, caproic acid, caprylic acid, 1-octanol, 1-nonanol, benzyl alcohol, benzyl acetate, ethyl benzoate, diethyl oxalate, diethyl maleate, y-butyrolactone, ethylene carbonate, propylene carbonate, phenyl cellosolve acetate, and the like.

The positive-type photosensitive resin composition may further contain a sensitizer in order to enhance the sensitivity.

### <Method of Preparing Photosensitive Resin Composition>

The photosensitive resin composition is prepared by mixing and stirring the above components with a common method. Devices which can be used to mix and stir the above components include a dissolver, a homogenizer, a 3-roll mill and the like. The resulting mixture obtained by uniformly mixing the above components may further be filtered with a mesh, a membrane filter or the like.

### <<Photosensitive Dry Film>>

A photosensitive dry film includes a base material film and a photosensitive resin layer which is formed on the surface of the base material film, and the photosensitive resin layer is formed of the photosensitive resin composition described above.

As the base material film, a film which has optical transparency is preferable. Specific examples thereof include a polyethylene terephthalate (PET) film, a polypropylene (PP) film, a polyethylene (PE) film and the like. A polyethylene terephthalate (PET) film is preferable because it is excellent in the balance of optical transparency and rupture strength.

The photosensitive resin composition described above is applied on the base material film so as to form the photosensitive resin layer, and thus the photosensitive dry film is manufactured. When the photosensitive resin layer is formed on the base material film, an applicator, a bar coater, a wire bar coater, a roll coater, a curtain flow coater or the like is used, and thus the photosensitive resin composition is applied and dried such that the thickness of the film after being dried on the base material film is preferably 0.5 μm or more and 300 μm or less, is more preferably 1 μm or more and 300 μm or less and is particularly preferably 3 μm or more and 100 μm or less.

The photosensitive dry film may further include a protective film on the photosensitive resin layer. Examples of the protective film include a polyethylene terephthalate (PET) film, a polypropylene (PP) film, polyethylene (PE) film and the like.

<<Method of Manufacturing Patterned Resist Film and Substrate with Template>>

A method of forming, with the photosensitive resin composition described above, a patterned resist film on a metal surface of a substrate having the metal surface is not particularly limited. The patterned resist film described above is suitably used as a template for forming a plated article. Preferred methods thereof include a patterned resist film which includes:

a stacking step of stacking the photosensitive resin layer formed of the photosensitive resin composition on the metal surface of the substrate having the metal surface;

an exposure step of applying an active ray or radiation to the photosensitive resin layer selectively in terms of position so as to expose the photosensitive resin layer; and

a development step of developing the photosensitive resin layer after being exposed.

A method of manufacturing a substrate with a template for forming a plated article is the same as the method of manufacturing the patterned resist film except that in the development step, the template for forming the plated article is produced by the development.

The substrate on which the photosensitive resin layer is stacked is not particularly limited, a conventionally known substrate can be used and examples thereof include a substrate for electronic parts, a substrate obtained by forming a predetermined wiring pattern thereon and the like. Although as the substrate, a substrate having a metal surface is used, as the type of metal forming the metal surface, copper, gold and aluminum are preferable, and copper is more preferable.

The photosensitive resin layer is stacked on the substrate, for example, as follows. Specifically, the liquid photosensitive resin composition is applied on the substrate, a solvent is removed by heating and thus the photosensitive resin layer having a desired film thickness is formed. The thickness of the photosensitive resin layer is not particularly limited as long as the resist pattern serving as the template can be formed so as to have the desired film thickness. Although the film thickness of the photosensitive resin layer is not particularly limited, the film thickness is preferably 0.5 μm or more, is more preferably 0.5 μm or more and 300 μm or less, is particularly preferably 1 μm or more and 150 μm or less and is most preferably 3 μm or more and 100 μm or less.

As a method of applying the photosensitive resin composition on the substrate, methods such as a spin coating method, a slit coating method, a roll coating method, a screen printing method and an applicator method can be used. Pre-baking is preferably performed on the photosensitive resin layer. Although the conditions for the pre-baking differ depending on the types of components in the photosensitive resin composition, the mixing ratio, the thickness of the coating film and the like, the conditions are that the pre-baking is performed normally at 70° C. or more and 200° C. or less and preferably at 80° C. or more and 150° C. or less for about 2 minutes or more and 120 minutes or less.

The photosensitive resin layer formed as described above is selectively irradiated (exposed) with an active ray or radiation, for example, an ultraviolet radiation or visible light with a wavelength of 300 nm or more and 500 nm or less through a mask having a predetermined pattern.

A low pressure mercury lamp, a high pressure mercury lamps, a super high pressure mercury lamp, a metal halide lamp, an argon gas laser or the like can be used as the light source of the radiation. Examples of the radiation include micro waves, infrared rays, visible light, ultraviolet rays, X-rays, y-rays, an electron beam, a proton beam, a neutron beam, an ion beam and the like. Although the radiation dose varies depending on the composition of the photosensitive resin composition, the film thickness of the photosensitive resin layer and the like, and for example, when an ultra high-pressure mercury lamp is used, the radiation dose is 100 mJ/cm² or more and 10000 mJ/cm² or less. Examples of the radiation include light rays which activate the acid generator (C) in order to generate an acid.

After the exposure, the diffusion of acid is promoted by heating the photosensitive resin layer using a known method to change the alkali solubility of the photosensitive resin layer at an exposed portion of the photosensitive resin film.

Then, the exposed photosensitive resin layer is developed according to a conventionally known method, and an insoluble part is dissolved and removed so as to form a template for forming the predetermined resist pattern or the plated article. Here, an alkaline aqueous solution is used as a developing solution.

As the developing solution, an aqueous solution of an alkali such as, for example, sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, dimethylethanolamine, triethanolamine, tetramethylammonium hydroxide, tetraethylammonium hydroxide, pyrrole, piperidine, 1,8-diazabicyclo[5.4.0]-7-undecene or 1,5-diazabicyclo[4.3.0]-5-nonane can be used. Also, an aqueous solution prepared by adding an adequate amount of a water-soluble organic solvent such as methanol or ethanol, or a surfactant to the aqueous solution of the alkali can be used as the developing solution.

The developing time may vary depending on the constituent of the photosensitive resin composition, the film thickness of the photosensitive resin layer, and the like. Usually, the developing time is 1 minute or more and 30 minutes or less. The method of the development may be any one of a liquid-filling method, a dipping method, a paddle method, a spray developing method, and the like.

After the development, the photosensitive resin layer is washed with running water for 30 seconds or more and 90 seconds or less, and is then dried with an air gun, an oven or the like. In this way, on the metal surface of the substrate having the metal surface, the resist pattern which is patterned so as to have the desired shape is formed. Moreover, in this way, on the metal surface of the substrate having the metal surface, the substrate with the template having the resist pattern serving as the template can be manufactured.

### <<Method of Manufacturing Plated Article>>

A conductor such as metal is embedded by plating into a non-resist part (part removed with the developing solution) in the template of the substrate with the template formed by the method described above, and thus it is possible to form plated articles like connection terminals such as a bump and a metal post. A plating processing method is not particularly limited, and various types of conventionally known methods can be adopted. As a plating liquid, in particular, a solder plating liquid, a copper plating liquid, a gold plating liquid and a nickel plating liquid are suitably used. Finally, the remaining template is removed with a separation liquid or the like according to a conventional method.

### Examples

Although the present invention will be described in more detail below with reference to Examples, the present invention is not limited to these Examples.

### Preparation Example 1

### (Synthesis of Resin (A))

91.8 g of methoxybutyl acetate was added to a three-necked flask having a cooling pipe and a nitrogen introducing pipe, and was heated to 80° C. A drop solution was separately prepared by dissolving, in 252 g of methoxybutyl acetate, 70.0 g of ethylcyclohexyl acrylate (ECHA), 10.0 g of methacrylic acid (MA), 14.0 g of n-butyl acrylate (n-BA), 46.0 g of dicyclopentanyl methacrylate (DCPMA), 60.0 g of tetrahydrofurfuryl acrylate (THFA) and 24.9 g of initiator V-601HP (made by FUJIFILM Wako Pure Chemical Corporation). The prepared drop solution was dropped into the three-necked flask over three hours. After the completion of the dropping, the three-necked flask was stirred while the temperature is being maintained at 80° C. Methanol was used to perform reprecipitation, and thus 101.3 g of a resin P1 was obtained. This resin was dissolved in methoxybutyl acetate, and thus a solution of the resin P1 having a solid component concentration of 70% was obtained. The mass average molecular weight of the resin P1 obtained was Mw 10600.

### Preparation Examples 2 to 8

Resins P2 to P8 listed in table 1 below were synthesized in the same manner as in preparation example 1 except that the composition of the monomer was changed as listed in table 1 below.

TABLE 1

| | | | | | | | | | Mass Average |
|---|---|---|---|---|---|---|---|---|---|
| | | Monomer Composition (Mass %) | | | | | | | Molecular |
| | Resin | ECHA | MA | n-BA | n-BMA | GBLA | DCPMA | THFA | Weight |
| Preparation | P1 | 35 | 5 | 7 | — | — | 23 | 30 | 10600 |
| Example1 | | | | | | | | | |
| Preparation | P2 | 35 | 5 | 7 | — | — | 23 | 30 | 7900 |
| Example2 | | | | | | | | | |
| Preparation | P3 | 35 | 5 | 7 | — | — | 23 | 30 | 40000 |
| Example3 | | | | | | | | | |
| Preparation | P4 | 33 | 10 | 7 | — | 18 | 22 | 10 | 20000 |
| Example4 | | | | | | | | | |
| Preparation | P5 | 33 | 10 | 7 | — | 18 | 22 | 10 | 9400 |
| Example5 | | | | | | | | | |
| Preparation | P6 | 33 | 10 | 7 | — | — | 22 | 28 | 10700 |
| Example6 | | | | | | | | | |
| Preparation | P7 | 33 | 10 | 7 | — | — | 22 | 28 | 8200 |
| Example7 | | | | | | | | | |
| Preparation | P8 | 33 | 10 | — | 7 | — | 22 | 28 | 6200 |
| Example8 | | | | | | | | | |

n-BMA: butyl methacrylate
GBLA: γ-butyrolactone methacrylate

### Examples 1 to 24 and Comparative Examples 1 to 12

In Examples and Comparative examples, as the polyfunctional vinyl ether monomer (B) ((B) component), VE1 to VE3 below were used.

VE1: 1,4-cyclohexane dimethanol divinyl ether
VE2: neopentyl glycol divinyl ether
VE3: trimethylolpropane trivinyl ether

In Examples and Comparative examples, as the acid generator (C) ((C) component) which generated an acid by application of an active ray or radiation, PAG1 to PAG4 below were used.

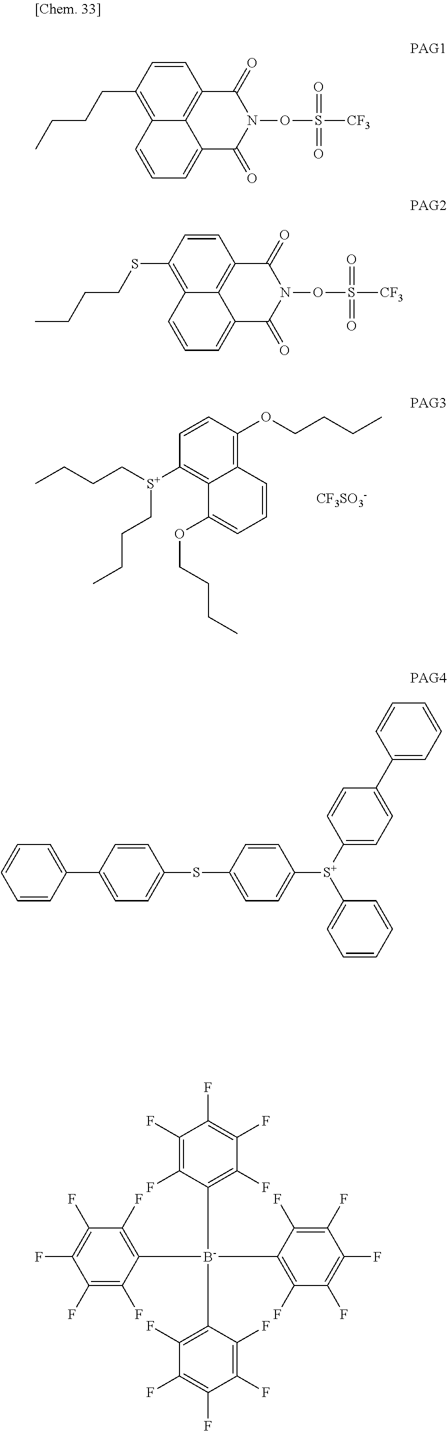

In Examples and Comparative examples, as the compound (D) ((D) component) including the phenolic hydroxyl group and/or the mercapto group, D1 to D5 below were used.

D1: hydroquinone monomethyl ether
D2: resorcinol
D3: 2-ethylhexyl 3-mercaptopropionate
D4: methoxybutyl 3-mercaptopropionate
D5: novolak resin

In Examples and Comparative examples, as the acid diffusion control agent (E) ((E) component), E1 to E4 below were used.

E1: tri-n-pentylamine
E2: tetrakis (1,2,2,6,6-pentamethyl-4-piperidyl) 1,2,3,4-butanetetracarboxylate
E3: 2,6-diphenylpyridine
E4: 2,4,6-triphenylpyridine

100 parts by mass of the resin (A) of each type listed in table 2, the polyfunctional vinyl ether monomer (B) of each type and amount listed in table 2, the acid generator (C) of each type and amount listed in table 2, the compound (D) of each type and amount listed in table 2, the acid diffusion control agent (E) of each type and amount listed in table 2 and 0.05 parts by mass of surfactant (BYK310 made by BYK-Chemie GmbH) were uniformly mixed and dissolved in 3-methoxybutyl acetate such that the solid content concentration thereof was 60% by mass, with the result that the photosensitive resin compositions of the Examples and Comparative examples were obtained. In Comparative example 10, a resin P9 which was a mixture of 40 parts by mass of the resin P1, 20 parts by mass of a copolymer of 60% by mass of p-hydroxystyrene, 15% by mass of styrene and 25% by mass of tert-butyl acrylate and 20 parts by mass of a m-cresol novolak resin was used as the resin (A) ((A) component). In Comparative example 12, a resin P10 which was a copolymer of 54% by mass of p-hydroxystyrene and 46% by mass of 4-(1-ethoxyethoxy) styrene was used as the resin (A) ((A) component).

The photosensitive resin compositions of the Examples and Comparative examples obtained were used, and thus crack resistance, plating resistance and storage stability were evaluated according to the following method. The results of these evaluations are described in table 2.

### <Crack Resistance Evaluation>

The photosensitive resin compositions of the Examples and Comparative examples were applied on a copper substrate having a diameter of 8 inches so as to form photosensitive resin layers whose film thickness was 55 μm. Then, the photosensitive resin layers were pre-baked at 140° C. for 5 minutes. After the prebaking, a mask of a square pattern having a diameter of 30 μm and an exposure device Prisma GHI (made by Ultratech, Inc.) were used so as to perform pattern exposure using g-h-i rays at such an exposure amount as to form a pattern (where the CD of the top of a resist pattern was 35 μm) having a predetermined size. Then, the substrate was placed on a hot plate, was exposed at 100° C. for 3 minutes and was heated (PEB). Thereafter, an operation of dropping a 2.38 weight percent aqueous solution of tetramethyl ammonium hydroxide (developing solution, NMD-3 made by Tokyo Ohka Kogyo Co., Ltd.) on the exposed photosensitive resin layers and then leaving them at 23° C. for 60 seconds was repeatedly performed four times in total. Thereafter, the surfaces of resist patterns were washed with running water, then nitrogen was blown and thus the resist patterns were obtained. The resist patterns were observed with a scanning electron microscope, and thus whether or not a crack occurs was observed. When a crack was observed, a determination of x was made whereas when no crack was observed, a determination of 0 was made.

### <Plating Resistance Evaluation>

The resist patterns formed in the crack resistance evaluation were immersed in a copper sulfate plating liquid at 28° C. for one hour, thereafter the CDs of the tops of the resist patterns were measured and when a variation in the CD of the top of the resist pattern after being immersed with respect to the CD of the top of the resist pattern before being immersed was ±5% or more, a determination of x was made whereas the variation was less than ±5%, a determination of 0 was made.

### <Storage Stability Test>

The photosensitive resin composition immediately after being prepared was left at room temperature for three days, thereafter the properties of the photosensitive resin composition were observed and thus the storage stability thereof was evaluated. When gelling was observed after the photosensitive resin composition was left for three days, a determination of x was made whereas when gelling was not observed, a determination of 0 was made.

TABLE 2

| | | (B) Component | (C) Component | (D) Component | (E) Component | | | |
|---|---|---|---|---|---|---|---|---|
| | (A) Component | Type/Parts | Type/Parts | Type/Parts | Type/Parts | Crack | Plating | Storage |
| | Type | by Mass | by Mass | by Mass | by Mass | Resistance | Resistance | Stability |
| Example1 | P1 | VE1/5 | PAG1/0.3 | D1/0.1 | E3/0.01 | ∘ | ∘ | ∘ |
| | | | | | E4/0.01 | | | |
| Example2 | P2 | VE1/5 | PAG1/0.3 | D1/0.1 | E3/0.01 | ∘ | ∘ | ∘ |
| | | | | | E4/0.01 | | | |
| Example3 | P3 | VE1/5 | PAG1/0.3 | D1/0.1 | E3/0.01 | ∘ | ∘ | ∘ |
| | | | | | E4/0.01 | | | |
| Example4 | P4 | VE1/5 | PAG1/0.3 | D1/0.1 | E3/0.01 | ∘ | ∘ | ∘ |
| | | | | | E4/0.01 | | | |
| Example5 | P5 | VE1/5 | PAG1/0.3 | D1/0.1 | E3/0.01 | ∘ | ∘ | ∘ |
| | | | | | E4/0.01 | | | |
| Example6 | P6 | VE1/5 | PAG1/0.3 | D1/0.1 | E3/0.01 | ∘ | ∘ | ∘ |
| | | | | | E4/0.01 | | | |
| Example7 | P7 | VE1/5 | PAG1/0.3 | D1/0.1 | E3/0.01 | ∘ | ∘ | ∘ |
| | | | | | E4/0.01 | | | |
| Example8 | P8 | VE1/5 | PAG1/0.3 | D1/0.1 | E3/0.01 | ∘ | ∘ | ∘ |
| | | | | | E4/0.01 | | | |
| Example9 | P8 | VE2/5 | PAG1/0.3 | D1/0.1 | E3/0.01 | ∘ | ∘ | ∘ |
| | | | | | E4/0.01 | | | |
| Example10 | P8 | VE3/5 | PAG1/0.3 | D1/0.1 | E3/0.01 | ∘ | ∘ | ∘ |
| | | | | | E4/0.01 | | | |
| Example11 | P8 | VE1/5 | PAG1/0.3 | D1/0.05 | E3/0.01 | ∘ | ∘ | ∘ |
| | | | | | E4/0.01 | | | |
| Example12 | P8 | VE1/5 | PAG1/0.3 | D1/1 | E3/0.01 | ∘ | ∘ | ∘ |
| | | | | | E4/0.01 | | | |
| Example13 | P8 | VE1/5 | PAG1/0.3 | D2/0.05 | E3/0.01 | ∘ | ∘ | ∘ |
| | | | | | E4/0.01 | | | |
| Example14 | P8 | VE1/5 | PAG1/0.3 | D3/0.05 | E3/0.01 | ∘ | ∘ | ∘ |
| | | | | | E4/0.01 | | | |
| Example15 | P8 | VE1/5 | PAG1/0.3 | D4/0.05 | E3/0.01 | ∘ | ∘ | ∘ |
| | | | | | E4/0.01 | | | |
| Example16 | P8 | VE1/5 | PAG1/0.3 | D5/5 | E3/0.01 | ∘ | ∘ | ∘ |
| | | | | | E4/0.01 | | | |
| Example17 | P8 | VE1/5 | PAG1/0.3 | D5/10 | E3/0.01 | ∘ | ∘ | ∘ |
| | | | | | E4/0.01 | | | |
| Example18 | P8 | VE1/10 | PAG1/0.3 | D1/0.05 | E3/0.01 | ∘ | ∘ | ∘ |
| | | | | | E4/0.01 | | | |
| Example19 | P8 | VE1/20 | PAG1/0.3 | D1/0.05 | E3/0.01 | ∘ | ∘ | ∘ |
| | | | | | E4/0.01 | | | |
| Example20 | P8 | VE1/30 | PAG1/0.3 | D1/0.05 | E3/0.01 | ∘ | ∘ | ∘ |
| | | | | | E4/0.01 | | | |
| Example21 | P8 | VE1/5 | PAG2/0.3 | D1/0.05 | E3/0.01 | ∘ | ∘ | ∘ |
| | | | | | E4/0.01 | | | |
| Example22 | P8 | VE1/5 | PAG3/1.5 | D1/0.05 | E1/0.01 | ∘ | ∘ | ∘ |
| | | | | | E2/0.01 | | | |
| Example23 | P8 | VE1/5 | PAG4/1.5 | D1/0.05 | E1/0.01 | ∘ | ∘ | ∘ |
| | | | | | E2/0.01 | | | |
| Example24 | P8 | VE1/5 | PAG1/0.1 | D1/0.05 | E3/0.01 | ∘ | ∘ | ∘ |
| | | | PAG3/1 | | E4/0.01 | | | |
| Comparative | P1 | —/0 | PAG1/0.3 | —/0 | E3/0.01 | ∘ | x | ∘ |
| Example1 | | | | | E4/0.01 | | | |
| Comparative | P2 | —/0 | PAG1/0.3 | —/0 | E3/0.01 | ∘ | x | ∘ |
| Example2 | | | | | E4/0.01 | | | |
| Comparative | P3 | —/0 | PAG1/0.3 | —/0 | E3/0.01 | ∘ | x | ∘ |
| Example3 | | | | | E4/0.01 | | | |
| Comparative | P4 | —/0 | PAG1/0.3 | —/0 | E3/0.01 | ∘ | x | ∘ |
| Example4 | | | | | E4/0.01 | | | |
| Comparative | P5 | —/0 | PAG1/0.3 | —/0 | E3/0.01 | ∘ | x | ∘ |
| Example5 | | | | | E4/0.01 | | | |
| Comparative | P6 | —/0 | PAG1/0.3 | —/0 | E3/0.01 | ∘ | x | ∘ |
| Example6 | | | | | E4/0.01 | | | |
| Comparative | P7 | —/0 | PAG1/0.3 | —/0 | E3/0.01 | ∘ | x | ∘ |
| Example7 | | | | | E4/0.01 | | | |
| Comparative | P8 | —/0 | PAG1/0.3 | —/0 | E3/0.01 | ∘ | x | ∘ |
| Example8 | | | | | E4/0.01 | | | |
| Comparative | P8 | VE1/5 | PAG1/0.3 | —/0 | E3/0.01 | ∘ | x | ∘ |
| Example9 | | | | | E4/0.01 | | | |
| Comparative | P9 | VE1/5 | PAG1/0.3 | —/0 | E3/0.01 | ∘ | ∘ | x |
| Example10 | | | | | E4/0.01 | | | |
| Comparative | P10 | VE1/5 | PAG1/0.3 | —/0 | E3/0.01 | ∘ | ∘ | x |
| Example11 | | | | | E4/0.01 | | | |
| Comparative | P10 | VE1/5 | PAG1/0.3 | D1/1 | E3/0.01 | ∘ | ∘ | x |
| Example12 | | | | | E4/0.01 | | | |

It was found from table 2 that when the photosensitive resin compositions of the Examples containing a specific amount of compound (D) including the phenolic hydroxyl group and/or the mercapto group together with the resin (A) including the (meth)acrylic polymer which included the carboxy group and the polyfunctional vinyl ether monomer (B) were used, a resist pattern was able to be formed whose shape was unlikely to be changed even when the resist pattern made contact with the plating liquid under plating conditions while the occurrence of a crack was being reduced, and that storage stability was provided in which thickening and gelling did not occur even in a certain degree of long-term storage at room temperature. On the other hand, it was found from the Comparative examples that when the photosensitive resin compositions did not include, as the resin (A), the (meth)acrylic polymer including the carboxy group, did not include the polyfunctional vinyl ether monomer (B) or did not include a specific amount of compound (D) including the phenolic hydroxyl group and/or the mercapto group, the photosensitive resin compositions in which the crack resistance, the plating resistance and the storage stability were all excellent were not obtained.

In Examples 8 and 17 and Comparative examples 8 and 10 each including the resin P8, the mass average molecular weights of the photosensitive resin layers prebaked in the crack resistance evaluation were measured, and consequently, it was found that the molecular weights of the photosensitive resin layers of Comparative examples 8 and 10 were substantially equal to the molecular weight of the resin P8, and that the molecular weights of the photosensitive resin layers of Examples 8 and 17 were higher than the molecular weight of the resin P8. In other words, it was found that in the photosensitive resin layers of Examples 8 and 17, cross-linking occurred by the polyfunctional vinyl ether monomer (B) of the resin (A).

What is claimed is:

1. A photosensitive resin composition comprising:
a resin (A) which does not include a compound (D) which comprises a phenolic hydroxyl group and/or a mercapto group;
a polyfunctional vinyl ether monomer (B); and
the compound (D),
wherein the resin (A) comprises a (meth)acrylic polymer comprising a carboxy group, and
a content of the compound (D) is 10 ppm by mass or more and 20% by mass or less with respect to a total mass of the resin (A).

2. The photosensitive resin composition according to claim 1, wherein the photosensitive resin composition is a positive type.

3. The photosensitive resin composition according to claim 1, further comprising an acid generator (C) which generates an acid upon exposure to an active ray or radiation, wherein the (meth)acrylic polymer is a resin whose solubility in alkali is increased by action of an acid.

4. The photosensitive resin composition according to claim 2, further comprising an acid diffusion control agent (E).

5. The photosensitive resin composition according to claim 1, wherein the photosensitive resin composition is used to form a template for formation of a plated article.

6. A photosensitive dry film comprising a base material film and a photosensitive resin layer formed on a surface of the base material film, wherein the photosensitive resin layer is formed of the photosensitive resin composition according to claim 1.

7. A method of manufacturing a photosensitive dry film, the method comprising applying, on a base material film, the photosensitive resin composition according to claim 1 so as to form a photosensitive resin layer.

8. A method of manufacturing a patterned resist film, the method comprising stacking, on a substrate having a metal surface, a photosensitive resin layer formed of the photosensitive resin composition according to claim 1;
exposing the photosensitive resin layer positionally selectively to an active ray or radiation; and
developing the photosensitive resin layer.

9. A method of manufacturing a substrate with a template, the method comprising stacking, on a substrate having a metal surface, a photosensitive resin layer formed of the photosensitive resin composition according to claim 1;
exposing the photosensitive resin layer to an active ray or radiation; and
developing the photosensitive resin layer so as to produce the template for formation of the plated article.

10. A method of manufacturing a plated article, the method comprising plating the substrate with the template manufactured by the method according to claim 9 so as to form the plated article within the template.
